(19) United States
(12) Patent Application Publication
(10) Pub. No.: US 2025/0299707 A1
(43) Pub. Date: Sep. 25, 2025

(54) SEMICONDUCTOR MEMORY DEVICE

(71) Applicant: Kioxia Corporation, Tokyo (JP)

(72) Inventors: Nobuaki OKADA, Kawasaki (JP); Hiroshi SHINOHARA, Yokosuka (JP)

(73) Assignee: Kioxia Corporation, Tokyo (JP)

(21) Appl. No.: 19/075,979

(22) Filed: Mar. 11, 2025

(30) Foreign Application Priority Data
Mar. 22, 2024 (JP) 2024-047340

(51) Int. Cl. G11C 5/06; G11C 16/04; H01L 23/00; H01L 25/18; H10B 41/10; H10B 41/27; H10B 41/40; H10B 43/10; H10B 43/27; H10B 43/40; H10B 80/00

(52) U.S. Cl. CPC G11C 5/063; G11C 16/0483; H01L 24/08; H01L 25/18; H10B 41/10; H10B 41/27; H10B 41/40; H10B 43/10; H10B 43/27; H10B 43/40; H10B 80/00; H01L 2224/08145

(57) ABSTRACT

A semiconductor memory device includes a semiconductor substrate, a plurality of transistors on the semiconductor substrate and arranged in a first and a second directions, a stacked body including a plurality of conductive layers arranged in a third direction, and a plurality of wiring layers disposed between the semiconductor substrate and the stacked body and connecting the conductive layers to the transistors. The wiring layers include a plurality of first wirings that connect the first conductive layers to the first transistors, and a plurality of second wirings that connect the second conductive layers to the second transistors. A first part of the first wirings extending in the first direction from the hook-up region to the first circuit region and a second part of the second wirings extending in the first direction from the hook-up region to the first circuit region are provided at positions different in the third direction.

### CROSS-REFERENCE TO RELATED APPLICATIONS

This application is based upon and claims the benefit of Japanese Patent Application No. 2024-047340, filed on Mar. 22, 2024, the entire contents of which are incorporated herein by reference.

### BACKGROUND

### Field

Embodiments described herein relate generally to a semiconductor memory device.

### Description of the Related Art

There has been known a semiconductor memory device that includes a substrate, a plurality of conductive layers stacked in a direction intersecting with a surface of this substrate, a semiconductor layer opposed to the plurality of conductive layers, and a gate insulating layer disposed between the conductive layers and the semiconductor layer. The gate insulating layer includes a memory portion that can store data, and the memory portion is, for example, an insulating electric charge accumulating layer of silicon nitride (SiN) or the like, or a conductive electric charge accumulating layer, such as a floating gate.

### BRIEF DESCRIPTION OF THE DRAWINGS

FIG. 1 is a schematic block diagram illustrating a configuration of a memory die MD according to a first embodiment;

FIG. 2 is a schematic circuit diagram illustrating a configuration of a part of the memory die MD;

FIG. 3 is a schematic circuit diagram illustrating configurations of a voltage generation circuit VG, a driver circuit DRV, and a row decoder RD;

FIG. 4 is a schematic circuit diagram illustrating a configuration of a part of a peripheral circuit PC;

FIG. 5 is a schematic exploded perspective view illustrating an exemplary configuration of the memory die MD;

FIG. 6 is a schematic bottom view illustrating an exemplary configuration of a chip C_{M};

FIG. 7 is a schematic cross-sectional view illustrating a configuration of a part of the memory die MD;

FIG. 8 is a schematic cross-sectional view illustrating a configuration of a part of the memory die MD;

FIG. 9 is a schematic bottom view illustrating a configuration of a part of the chip C_{M};

FIG. 10 is a schematic cross-sectional view illustrating a configuration of a part of the chip C_{M};

FIG. 11 is a schematic plan view illustrating an exemplary configuration of hook-up regions R_{HU};

FIG. 12 is a schematic plan view illustrating an exemplary configuration of a chip Cₚ;

FIG. 13 is a schematic enlarged view of a part indicated by A in FIG. 12;

FIG. 14 is a schematic plan view illustrating a control circuit SYN and passing wirings TW;

FIG. 15 is a schematic plan view illustrating an exemplary configuration of word line switches WLSW;

FIG. 16 is a schematic cross-sectional view illustrating paths between conductive layers 110 and the word line switch WLSW and a select gate line switch SGSW;

FIG. 17 is a schematic cross-sectional view illustrating structures of the word line switches WLSW, connecting portions, and via-contact electrodes;

FIG. 18 is a schematic plan view illustrating positions of bonding electrodes P_{I2} in the hook-up region R_{HU};

FIG. 19 is a schematic plan view illustrating positions of wirings CGI and connecting portions d42 disposed in a wiring layer D4;

FIG. 20 is a schematic plan view illustrating an example of a wiring pattern in a wiring layer D3;

FIG. 21 is a schematic plan view illustrating an example of a wiring pattern in a wiring layer D2;

FIG. 22 is a schematic plan view illustrating an example of a wiring pattern in a wiring layer D1;

FIG. 23 is a schematic plan view illustrating an example of a wiring pattern in a wiring layer D0;

FIG. 24 is an enlarged plan view of a region of a part of FIG. 23;

FIG. 25 is a plan view illustrating a modification of the wiring layer D0 illustrated in FIG. 24;

FIG. 26 is a plan view illustrating still another example of the wiring layer D1;

FIG. 27 is a plan view illustrating still another example of the wiring layer D1;

FIG. 28 is a schematic plan view of hook-up wirings W1 disposed at a first row RO1 of a wiring layer D1 of a comparative example;

FIG. 29A and FIG. 29B are schematic plan views of hook-up wirings W1 and W2 disposed at a first row RO1 of the wiring layers D1 and D2 of the first embodiment;

FIG. 30 is a schematic plan view illustrating positions of connecting portions d32 to d02 of wiring layers D3 to D0 according to a second embodiment;

FIG. 31 is a schematic plan view illustrating positions of connecting portions d32 to d02 of wiring layers D3 to D0 according to a first modification of the second embodiment;

FIG. 32 is a schematic plan view illustrating positions of connecting portions d32 to d02 of wiring layers D3 to D0 according to a second modification of the second embodiment;

FIG. 33 is a schematic plan view illustrating an exemplary configuration of a semiconductor substrate 500 according to a third embodiment;

FIG. 34 is a schematic plan view illustrating an exemplary configuration of a word line switch WLSW according to a fourth embodiment;

FIG. 35 is a schematic plan view illustrating an exemplary wiring pattern in a wiring layer D2;

FIG. 36 is a schematic plan view illustrating an exemplary wiring pattern in a wiring layer D1;

FIG. 37 is a schematic plan view illustrating an exemplary wiring pattern in a wiring layer D0;

FIG. 38 is a schematic plan view illustrating an exemplary configuration of a word line switch WLSW according to a fifth embodiment;

FIG. 39A, FIG. 39B, and FIG. 39C are schematic plan views illustrating wiring patterns of hook-up wirings W2, W1, W0 disposed at a first row RO1;

FIG. 40 is a diagram illustrating a schematic configuration of a semiconductor memory device according to a sixth embodiment;

FIG. 41 is a diagram illustrating a schematic configuration of the semiconductor memory device according to the sixth embodiment;

FIG. 42 is a schematic cross-sectional view illustrating a configuration of a part of a semiconductor memory device according to a seventh embodiment;

FIG. 43 is a schematic plan view illustrating an exemplary arrangement of via-contact electrodes CC and an exemplary arrangement of connecting portions dn2 and word line switches WLSW in a wiring layer corresponding thereto in a semiconductor memory device according to an eighth embodiment;

FIG. 44 is a schematic plan view illustrating an exemplary assignment of word line WL numbers to the via-contact electrodes CC and the word line switches WLSW;

FIG. 45 is a schematic plan view illustrating an exemplary arrangement of via-contact electrodes CC and an exemplary arrangement of connecting portions dn2 and word line switches WLSW in a wiring layer corresponding thereto in a semiconductor memory device according to a ninth embodiment;

FIG. 46 is a schematic plan view illustrating an exemplary assignment of word line WL numbers to the via-contact electrodes CC and the word line switches WLSW;

FIG. 47 is a schematic plan view illustrating an exemplary arrangement of via-contact electrodes CC and an exemplary arrangement of connecting portions dn2 and word line switches WLSW in a wiring layer corresponding thereto in a semiconductor memory device according to a tenth embodiment;

FIG. 48 is a schematic plan view illustrating an exemplary assignment of word line WL numbers to the via-contact electrodes CC and the word line switches WLSW;

FIG. 49 is a schematic plan view illustrating an exemplary arrangement of via-contact electrodes CC and an exemplary arrangement of connecting portions dn2 and word line switches WLSW in a wiring layer corresponding thereto in a semiconductor memory device according to an eleventh embodiment; and

FIG. 50 is a schematic plan view illustrating an exemplary assignment of word line WL numbers to the via-contact electrodes CC and the word line switches WLSW.

### DETAILED DESCRIPTION

A semiconductor memory device according to one embodiment comprises a semiconductor substrate, a plurality of transistors disposed on a surface on one side of the semiconductor substrate and arranged in a first direction and a second direction intersecting with the first direction, a stacked body disposed at the one side in a third direction intersecting with the first direction and the second direction with respect to the semiconductor substrate and including a plurality of conductive layers arranged in the third direction, and a plurality of wiring layers disposed between the semiconductor substrate and the stacked body and connecting the plurality of conductive layers to the plurality of transistors. The semiconductor memory device includes a first circuit region in which the plurality of transistors are arranged when viewed in the third direction and a hook-up region overlapping with the first circuit region when viewed in the third direction and being smaller than the first circuit region in width in the first direction. The stacked body includes a first stacked structure and a second stacked structure arranged in the second direction. The first stacked structure includes a plurality of first conductive layers arranged in the third direction. The second stacked structure includes a plurality of second conductive layers arranged in the third direction. The plurality of transistors include a plurality of first transistors and a plurality of second transistors arranged in the first direction. The plurality of wiring layers include a plurality of first wirings that connect the plurality of first conductive layers to the plurality of first transistors, and a plurality of second wirings that connect the plurality of second conductive layers to the plurality of second transistors. A first part of the plurality of first wirings extending in the first direction from the hook-up region to a region outside the hook-up region in the first circuit region and a second part of the plurality of second wirings extending in the first direction from the hook-up region to the region outside the hook-up region in the first circuit region are provided at positions different in the third direction.

Next, the semiconductor memory devices according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to a “semiconductor memory device”, it may mean a memory die and may mean a memory system including a controller die, such as a memory chip, a memory card, and a Solid State Drive (SSD). Further, it may mean a configuration including a host computer, such as a smartphone, a tablet terminal, and a personal computer.

In this specification, when it is referred that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in an OFF state, the first transistor is “electrically connected” to the third transistor.

In this specification, when it is referred that the first configuration “is connected between” the second configuration and a third configuration, it may mean that the first configuration, the second configuration, and the third configuration are connected in series and the second configuration is connected to the third configuration via the first configuration.

In this specification, when it is referred that a circuit or the like “electrically conducts” two wirings or the like, it may mean, for example, that this circuit or the like includes a transistor or the like, this transistor or the like is disposed in a current path between the two wirings, and this transistor or the like enters an ON state.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may each correspond to any of the X-direction, the Y-direction, and the Z-direction and need not correspond to these directions.

Expressions such as “above” and “below” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion at the substrate side of this configuration. An upper surface and an upper end of a certain configuration mean a surface and an end portion at a side opposite to the substrate of this configuration. A surface intersecting with the X-direction or the Y-direction is referred to as a side surface and the like.

In this specification, when referring to a “width”, a “length”, a “thickness”, or the like of a configuration, a member, or the like in a predetermined direction, this may mean a width, a length, a thickness, or the like in a cross-sectional surface or the like observed with a Scanning electron microscopy (SEM), a Transmission electron microscopy (TEM), or the like.

In this specification, when referring to a “wiring”, this may include a wiring, a via-contact electrode, a connecting portion for connecting a wiring to a via-contact electrode, a bonding electrode, or the like.

### First Embodiment

### [Circuit Configuration of Memory Die MD]

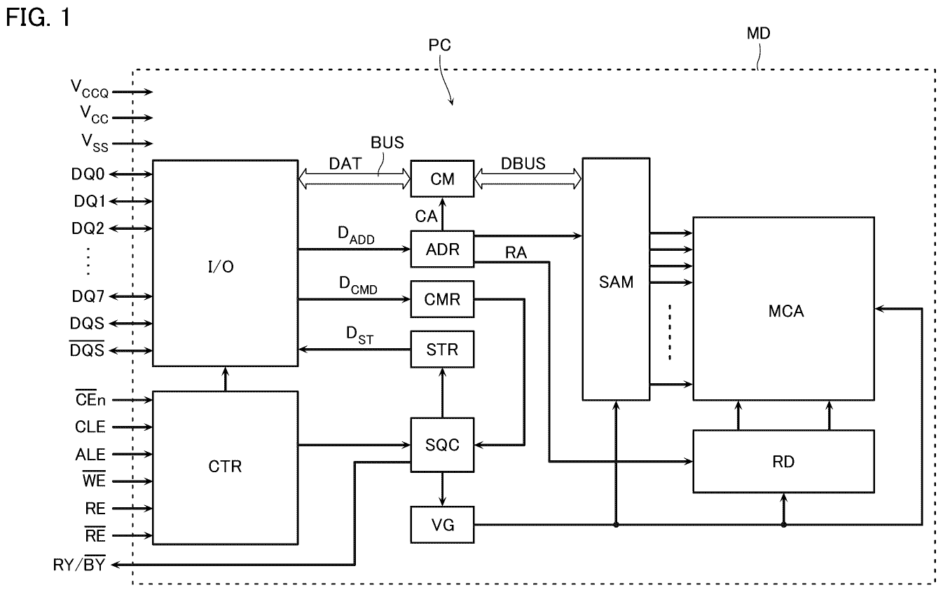

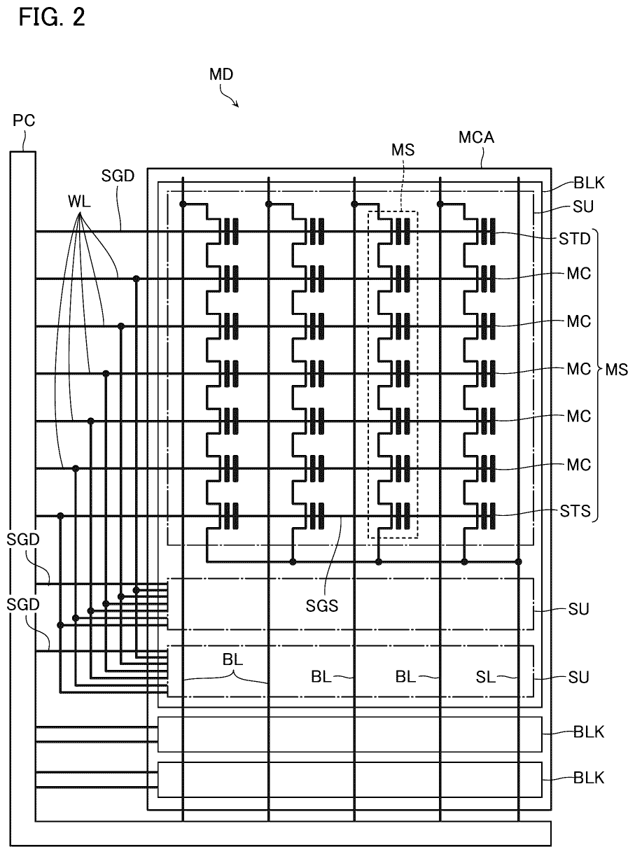

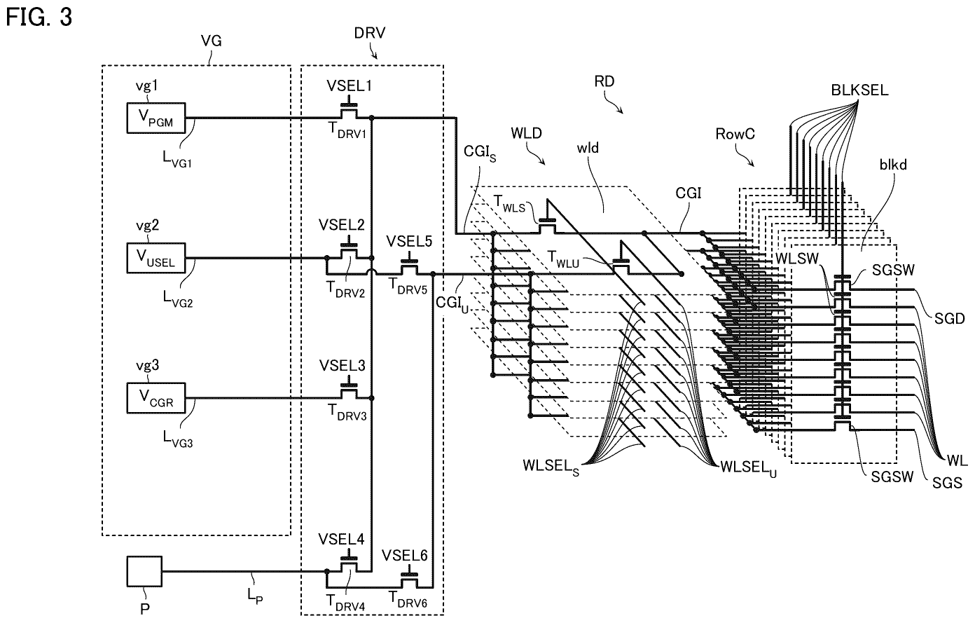

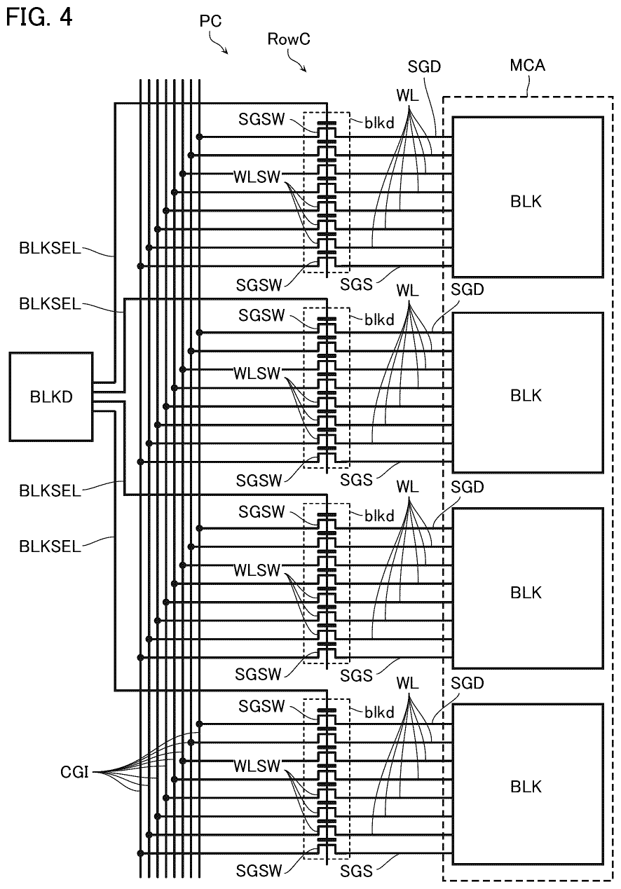

FIG. 1 is a schematic block diagram illustrating a configuration of a memory die MD according to a first embodiment. FIG. 2 is a schematic circuit diagram illustrating a configuration of a part of the memory die MD. FIG. 3 is a schematic circuit diagram illustrating configurations of a voltage generation circuit VG, a driver circuit DRV, and a row decoder RD. FIG. 4 is a schematic block diagram illustrating configurations of a row control circuit RowC and a block decoder BLKD.

Note that FIG. 1 illustrates, for example, a plurality of control terminals. These plurality of control terminals are expressed as control terminals corresponding to high active signals (positive logic signals) in some cases. The plurality of control terminals are expressed as control terminals corresponding to low active signals (negative logic signals) in some cases. The plurality of control terminals are expressed as control terminals corresponding to both of the high active signals and the low active signals in some cases. In FIG. 1, reference numerals of the control terminals corresponding to the low active signals include overlines (overbars). In this specification, a reference numeral of the control terminal corresponding to the low active signal includes a slash (“/”). Note that the description in FIG. 1 is an example, and the specific aspect is appropriately adjustable. For example, a part of or all of the high active signals can be changed to the low active signals, or a part of or all of the low active signals can be changed to the high active signals.

As illustrated in FIG. 1, the memory die MD includes a memory cell array MCA and a peripheral circuit PC. The peripheral circuit PC includes the voltage generation circuit VG, the row decoder RD, a sense amplifier module SAM, and a sequencer SQC. The peripheral circuit PC includes a cache memory CM, an address register ADR, a command register CMR, and a status register STR. The peripheral circuit PC includes an input/output control circuit I/O and a logic circuit CTR.

### [Circuit Configuration of Memory Cell Array MCA]

As illustrated in FIG. 2, the memory cell array MCA includes a plurality of memory blocks BLK. Each of these plurality of memory blocks BLK includes a plurality of string units SU. Each of these plurality of string units SU includes a plurality of memory strings MS. Each of these plurality of memory strings MS has one end connected to the peripheral circuit PC via a bit line BL. Each of these plurality of memory strings MS has the other end connected to the peripheral circuit PC via a common source line SL.

The memory string MS includes a drain-side select transistor STD, a plurality of memory cells MC (memory transistors), and a source-side select transistor STS. The drain-side select transistor STD, the plurality of memory cells MC, and the source-side select transistor STS are connected in series between the bit line BL and the source line SL. Hereinafter, the drain-side select transistor STD and the source-side select transistor STS may be simply referred to as select transistors (STD, STS).

The memory cell MC is a field-effect type transistor. The memory cell MC includes a semiconductor layer, a gate insulating film, and a gate electrode. The semiconductor layer functions as a channel region. The gate insulating film includes an electric charge accumulating film. The memory cell MC has a threshold voltage that changes according to an electric charge amount in the electric charge accumulating film. The memory cell MC stores the data of one bit or a plurality of bits. Respective word lines WL are connected to the gate electrodes of the plurality of memory cells MC corresponding to one memory string MS. Each of these word lines WL is connected to all of the memory strings MS in one memory block BLK in common.

The select transistors (STD, STS) are field-effect type transistors. The select transistors (STD, STS) include a semiconductor layer, a gate insulating film, and a gate electrode. The semiconductor layer functions as a channel region. The gate insulating film may include an electric charge accumulating layer. The select gate lines (SGD, SGS) are connected to the respective gate electrodes of the select transistors (STD, STS). One drain-side select gate line SGD is connected to all of the memory strings MS in one string unit SU in common. One source-side select gate line SGS is connected to all of the memory strings MS in one memory block BLK in common. The respective drain-side select gate line SGD and source-side select gate line SGS may be referred to as select gate lines SG.

### [Circuit Configuration of Voltage Generation Circuit VG]

For example, as illustrated in FIG. 3, the voltage generation circuit VG (FIG. 1) includes a plurality of voltage generation units vg1 to vg3. The voltage generation units vg1 to vg3 generate voltages of predetermined magnitudes and output them via voltage supply lines LVG in a read operation, a write operation, and an erase operation. For example, the voltage generation unit vg1 outputs a program voltage in the write operation. The voltage generation unit vg2 outputs a read pass voltage in the read operation. The voltage generation unit vg2 outputs a write pass voltage in the write operation. The voltage generation unit vg3 outputs a read voltage in the read operation. The voltage generation unit vg3 outputs a verify voltage in the write operation. For example, the voltage generation units vg1 to vg3 may be a step-up circuit, such as a charge pump circuit, or may be a step-down circuit, such as a regulator. These step-down circuit and step-up circuit are each connected to a voltage supply line Lₚ. The voltage supply line Lₚ is applied with a power supply voltage V_{CC} or a ground voltage V_{SS} (FIG. 1). These voltage supply lines Lₚ are, for example, connected to pad electrodes P. The operating voltage output from the voltage generation circuit VG is appropriately adjusted in accordance with a control signal from the sequencer SQC.

The voltage generation circuit VG (FIG. 1) described with reference to FIG. 3 has a configuration that generates the program voltage, the read pass voltage, the write pass voltage, the read voltage, and the verify voltage applied to the word lines WL via a wiring CGI. However, not only the operating voltages applied to the word lines WL, the voltage generation circuit VG can generate a plurality of patterns of operating voltages applied to the bit line BL, the source line SL, and the select gate lines (SGD, SGS) at the read operation, the write operation, and the erase operation on the memory cell array MCA and output them to a plurality of voltage supply lines. These operating voltages are appropriately adjusted in accordance with the control signal from the sequencer SQC.

### [Circuit Configuration of Row Decoder RD]

For example, as illustrated in FIG. 3, the row decoder RD includes a row control circuit RowC, a word line decoder WLD, the driver circuit DRV, and an address decoder (not illustrated). For example, as illustrated in FIG. 4, the row control circuit RowC includes a plurality of block decoder units blkd and the block decoder BLKD.

The plurality of block decoder units blkd correspond to the plurality of memory blocks BLK in the memory cell array MCA. The block decoder unit blkd includes the plurality of word line switches WLSW and a plurality of select gate line switches SGSW. The plurality of word line switches WLSW correspond to the plurality of word lines WL in the memory block BLK. The plurality of select gate line switches SGSW correspond to the drain-side select gate line SGD and the source-side select gate line SGS in the memory block BLK.

The word line switch WLSW and the select gate line switch SGSW are, for example, field-effect type NMOS transistors. The word line switch WLSW has a drain electrode connected to the word line WL. The select gate line switches SGSW have drain electrodes connected to the drain-side select gate line SGD and the source-side select gate line SGS. The word line switch WLSW and the select gate line switch SGSW have source electrodes connected to the wirings CGI. The wiring CGI is connected to all of the block decoder units blkd in the row control circuit RowC. The word line switches WLSW and the select gate line switches SGSW have gate electrodes connected to a signal line BLKSEL. A plurality of the signal lines BLKSEL are disposed corresponding to all of the block decoder units blkd. Additionally, the signal line BLKSEL is connected to all of the word line switches WLSW and the select gate line switches SGSW in the block decoder unit blkd.

The block decoder BLKD decodes the block address at, for example, the read operation and the write operation. In the read operation, the write operation, or the like, for example, one signal line BLKSEL corresponding to the block address in the address register ADR (FIG. 1) enters an “H” state and the other signal lines BLKSEL enter an “L” state. For example, a predetermined driving voltage having a positive magnitude is applied to one signal line BLKSEL and ground voltages V_{SS} and the like are applied to the other signal lines BLKSEL. Accordingly, all of the word lines WL and the select gate line SG in one memory block BLK corresponding to this block address are electrically conductive to all of the wirings CGI. Additionally, all of the word lines WL and the select gate lines SG in the other memory blocks BLK enter a floating state.

The word line decoder WLD includes a plurality of word line decode units wld. The plurality of word line decode units wld correspond to the plurality of memory cells MC in the memory string MS. In the example of FIG. 3, the word line decode unit wld includes two transistors T_{WLS}, T_{WLU}. The transistors T_{WLS}, T_{WLU} are, for example, field-effect type NMOS transistors. The transistors T_{WLS}, T_{WLU} have drain electrodes connected to the wiring CGI. The transistor T_{WLS} has a source electrode connected to a wiring CGIs. The transistor T_{WLU} has a source electrode connected to a wiring CGI_{U}. The transistor T_{WLS} has a gate electrode connected to a signal line WLSEL_{S}. The transistor T_{WLU} has a gate electrode connected to a signal line WLSEL_{U}. The plurality of signal lines WLSEL_{S} are disposed corresponding to one transistors T_{WLS} included in all of the word line decode units wld. The plurality of signal lines WLSEL_{U} are disposed corresponding to the other transistors T_{WLU} included in all of the word line decode units wld.

In the read operation, the write operation, and the like, for example, the signal line WLSEL_{S} corresponding to one word line decode unit wld corresponding to a page address in the address register ADR (FIG. 1) enters the “H” state and the signal line WLSEL_{U} corresponding to this enters the “L” state. Further, the signal lines WLSEL_{S} corresponding to other word line decode units wld enter the “L” state and the signal lines WLSEL_{U} corresponding to these enter the “H” state. To the wiring CGIs, a voltage corresponding to the selected word line WL is applied. To the wirings CGI_{U}, voltages corresponding to the unselected word lines WL are applied. Thus, the voltage corresponding to the selected word line WL is applied to one word line WL corresponding to the page address. Additionally, the voltages corresponding to the unselected word lines WL are applied to the other word lines WL.

The driver circuit DRV, for example, includes six transistors T_{DRV1} to T_{DRV6}. The transistors T_{DRV1} to T_{DRV6} are, for example, field-effect type NMOS transistors. The transistors T_{DRV1} to T_{DRV4} have drain electrodes connected to the wiring CGIs. The transistors T_{DRV5}, T_{DRV6} have drain electrodes connected to the wiring CGI_{U}. The transistor T_{DRV1} has a source electrode connected to an output terminal of the voltage generation unit vg1 via a voltage supply line L_{VG1}. The transistors T_{DRV2}, T_{DRV5} have source electrodes connected to an output terminal of the voltage generation unit vg2 via a voltage supply line L_{VG2}. The transistor T_{DRV3} has a source electrode connected to an output terminal of the voltage generation unit vg3 via a voltage supply line L_{VG3}. The transistors T_{DRV4}, T_{DRV6} have source electrodes connected to a pad electrode P via the voltage supply line L_{P}. The transistors T_{DRV1} to T_{DRV6} have gate electrodes to which signal lines VSEL1 to VSEL6 are connected, respectively.

In the read operation, the write operation, and the like, for example, one of the plurality of signal lines VSEL1 to VSEL4 corresponding to the wiring CGIs enters the “H” state and the others enter the “L” state. Additionally, one of the two signal lines VSEL5, VSEL6 corresponding to the wiring CGI enters the “H” state and the other enters the “L” state.

The address decoder (not illustrated), for example, sequentially refers to a row address RA of the address register ADR (FIG. 1) in accordance with the control signal from the sequencer SQC (FIG. 1). The row address RA includes the above-described block address and page address. The address decoder controls the voltages of the signal lines BLKSEL, WLSEL_{S}, WLSEL to the “H” state or the “L” state.

In the example of FIG. 3, in the row decoder RD, one block decoder unit blkd is disposed for one memory block BLK. However, this configuration is appropriately changeable. For example, one block decoder unit blkd may be disposed for two or more of the memory blocks BLK.

### [Circuit Configuration of Sense Amplifier Module SAM]

The sense amplifier module SAM (FIG. 1) detects the ON state/OFF state of the memory cell MC and acquires data indicative of the state of this memory cell MC. This operation is referred to as a sense operation in some cases. The sense amplifier module SAM includes a plurality of sense amplifier units. The plurality of sense amplifier units correspond to the plurality of bit lines BL. Each of the plurality of sense amplifier units includes a sense amplifier circuit and a latch circuit.

### [Circuit Configuration of Cache Memory CM]

The cache memory CM (FIG. 1) includes a plurality of latch circuits. The plurality of latch circuits are connected to the latch circuits in the sense amplifier modules SAM via a wiring DBUS. Data DAT included in these plurality of latch circuits are sequentially transferred to the sense amplifier module SAM or the input/output control circuit I/O.

To the cache memory CM, a decode circuit and a switch circuit (not illustrated) are connected. The decode circuit decodes a column address CA latched in the address register ADR. The switch circuit causes the latch circuit corresponding to the column address CA to electrically conduct with a bus BUS (FIG. 1) according to an output signal from a decode circuit.

### [Circuit Configuration of Sequencer SQC]

The sequencer SQC (FIG. 1) outputs an internal control signal to the row decoder RD, the sense amplifier module SAM, and the voltage generation circuit VG in accordance with command data DeMD latched in the command register CMR. The sequencer SQC outputs status data Dsr indicating its own state to the status register STR as appropriate.

The sequencer SQC generates a ready/busy signal and outputs it to a terminal RY//BY. In a period while the terminal RY//BY is in an “L” state (busy period), access to the memory die MD is basically inhibited. In a period while the terminal RY//BY is in an “H” state (ready period), access to the memory die MD is permitted.

### [Circuit Configuration of Input/Output Control Circuit I/O]

The input/output control circuit I/O includes data signal input/output terminals DQ0 to DQ7, toggle signal input/output terminals DOS, /DQS, a plurality of input circuits, a plurality of output circuits, a shift register, and a buffer circuit. The plurality of input circuits, the plurality of output circuits, the shift register, and the buffer circuit are each connected to a terminal to which a power supply voltage Voce and the ground voltage V_{SS} are applied.

The data input via the data signal input/output terminals DQ0 to DQ7 are output from the buffer circuit to the cache memory CM, the address register ADR, or the command register CMR according to the internal control signal from the logic circuit CTR. The data output via the data signal input/output terminals DQ0 to DQ7 are input to the buffer circuit from the cache memory CM or the status register STR according to the internal control signal from the logic circuit CTR.

The plurality of input circuits include, for example, comparators connected to any of the data signal input/output terminals DQ0 to DQ7 or both of the toggle signal input/output terminals DQS, /DQS. The plurality of output circuits include, for example, Off Chip Driver (OCD) circuits connected to any of the data signal input/output terminals DQ0 to DQ7 or any of the toggle signal input/output terminals DQS, /DQS.

### [Circuit Configuration of Logic Circuit CTR]

The logic circuit CTR (FIG. 1) receives an external control signal from the controller die CD via external control terminals /CEn, CLE, ALE, /WE, RE, or /RE and outputs the internal control signal to the input/output control circuit I/O according to the external control signal.

### [Structure of Memory Die MD]

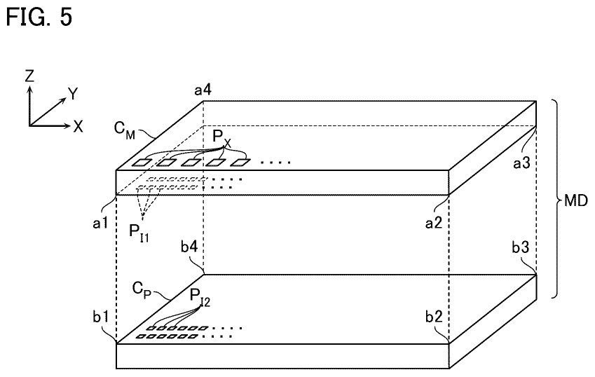

FIG. 5 is a schematic exploded perspective view illustrating an exemplary configuration of the semiconductor memory device according to the first embodiment. As illustrated in FIG. 5, the memory die MD includes a chip C_{M} at the memory cell array MCA side and a chip Cₚ at the peripheral circuit PC side.

On the upper surface of the chip C_{M}, a plurality of external pad electrodes P_{X} connectable to bonding wires (not illustrated) are disposed. Additionally, a plurality of bonding electrodes P_{I1} are disposed on the lower surface of the chip C_{M}. A plurality of bonding electrodes P_{I2} are disposed on the upper surface of the chip C_{P}. Hereinafter, regarding the chip C_{M}, a surface on which the plurality of bonding electrodes P_{I1} are disposed is referred to as a front surface and a surface on which the plurality of external pad electrodes P_{X} are disposed is referred to as a back surface. Additionally, regarding the chip C_{P}, a surface on which the plurality of bonding electrodes P_{I2} are disposed is referred to as a front surface and a surface on the side opposite to the front surface is referred to as a back surface. In the example illustrated in the drawing, the front surface of the chip C_{P} is disposed above the back surface of the chip C_{P} and the back surface of the chip C_{M} is disposed above the front surface of the chip C_{M}.

In the chip C_{M} and the chip C_{P}, the front surface of the chip C_{M} is disposed to be opposed to the front surface of the chip C_{P}. The respective plurality of bonding electrodes P_{I1} are disposed corresponding to the plurality of bonding electrodes P_{I2} and are disposed at positions where the plurality of bonding electrodes P_{I1} can be bonded to the plurality of bonding electrodes P_{I2}. The bonding electrode P_{I1} and the bonding electrode P_{I2} function as bonding electrodes to bond the chip C_{M} and the chip C_{P} together for electrical continuity.

In the example of FIG. 5, corner portions a1, a2, a3, a4 of the chip C_{M} correspond to corner portions b1, b2, b3, b4 of the chip C_{P}, respectively.

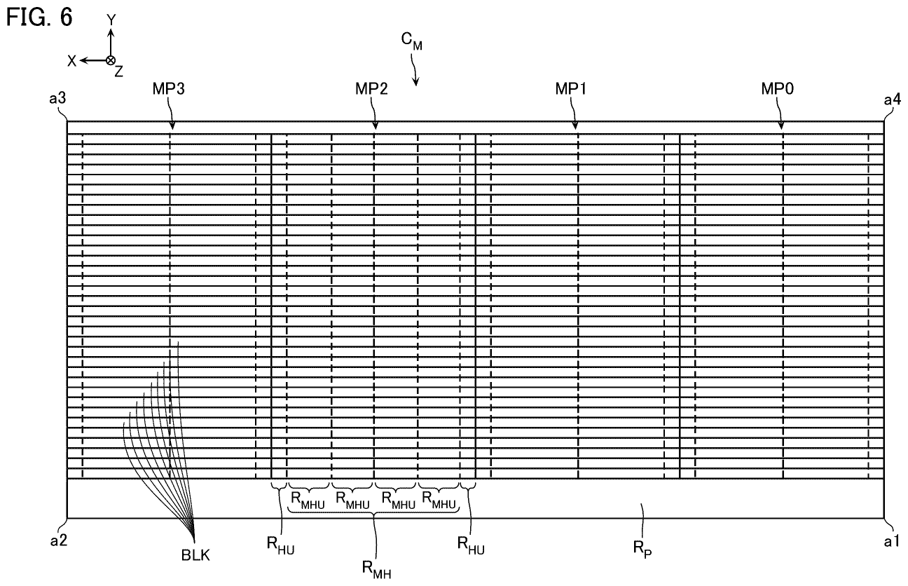

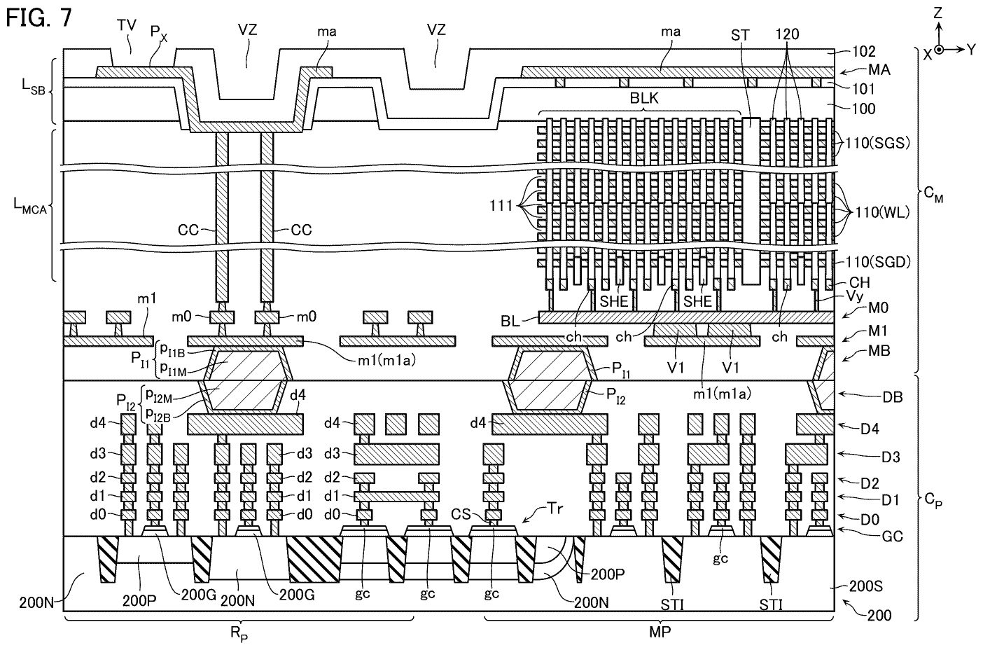

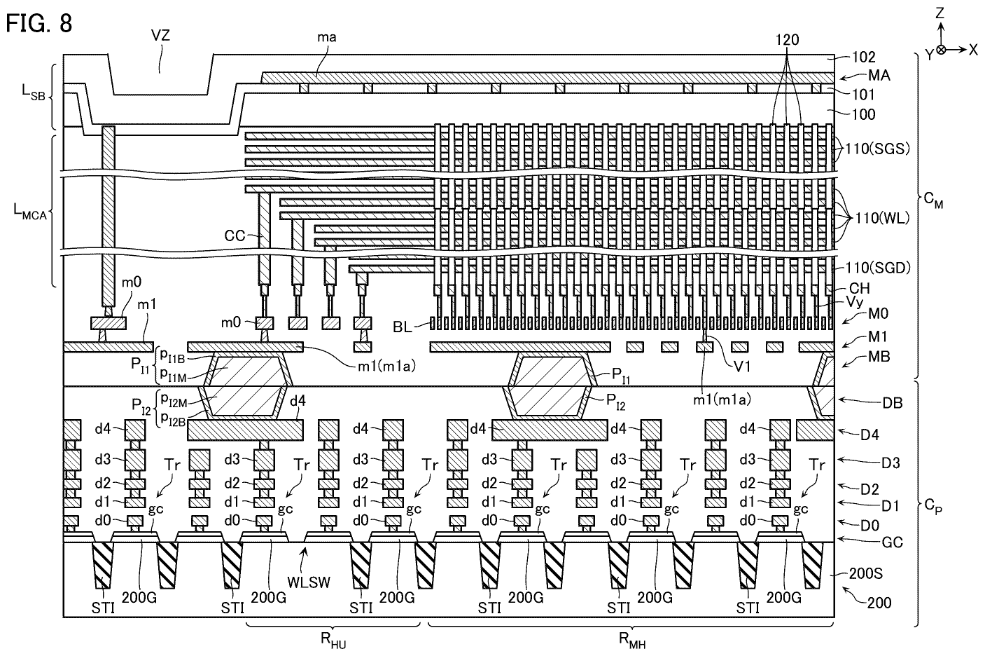

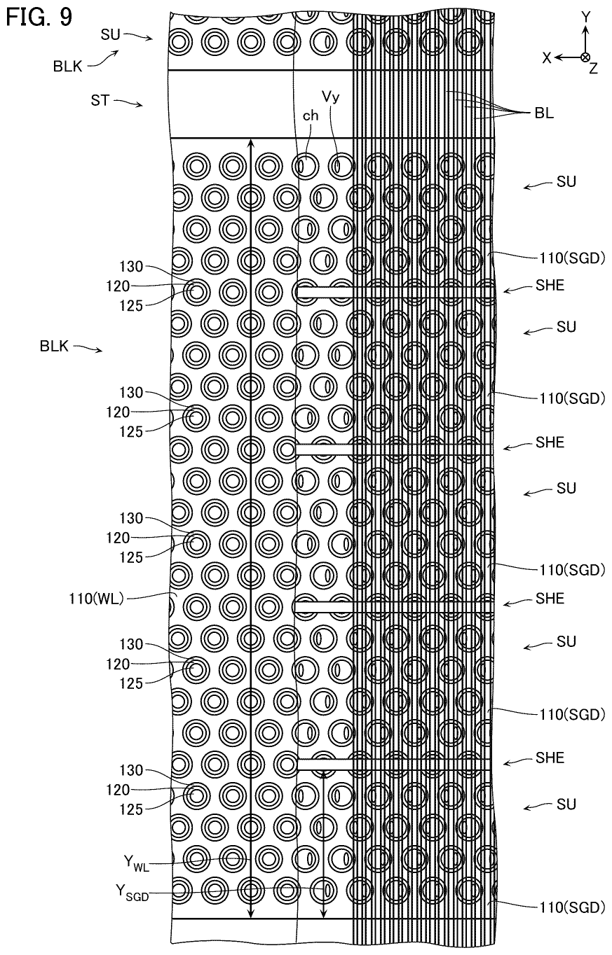

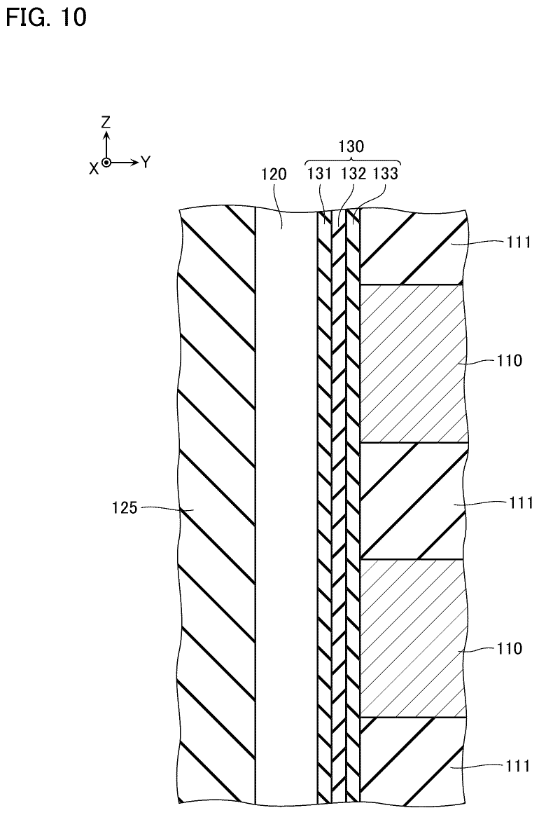

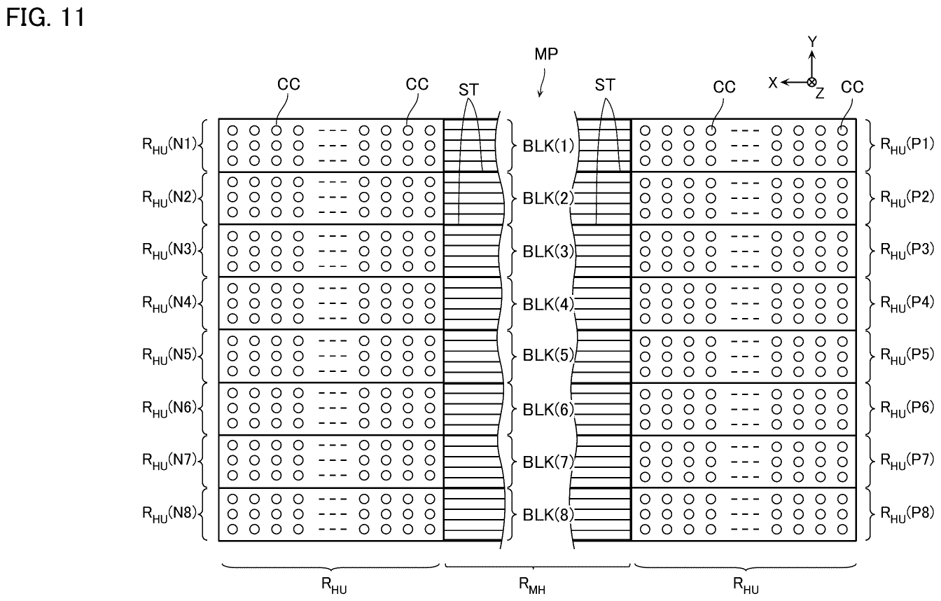

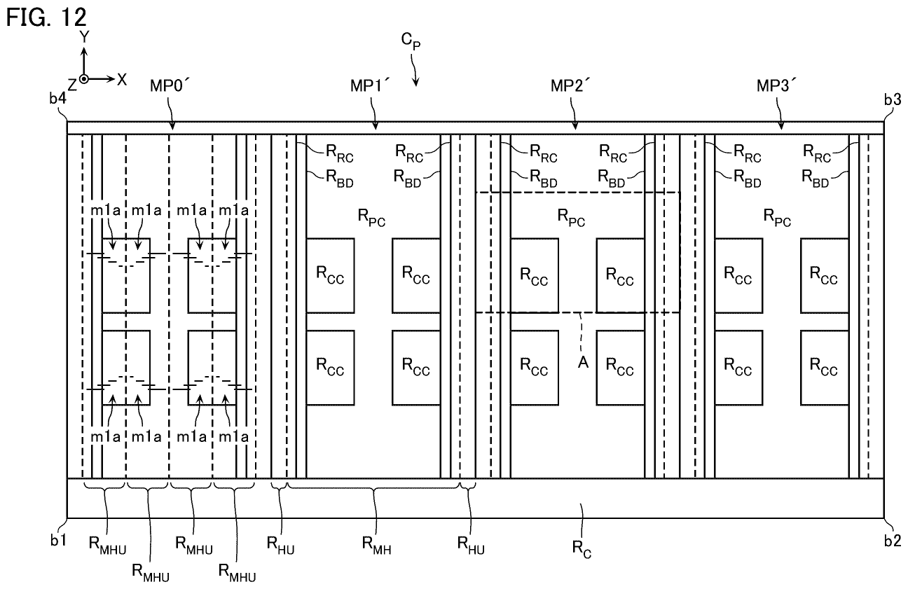

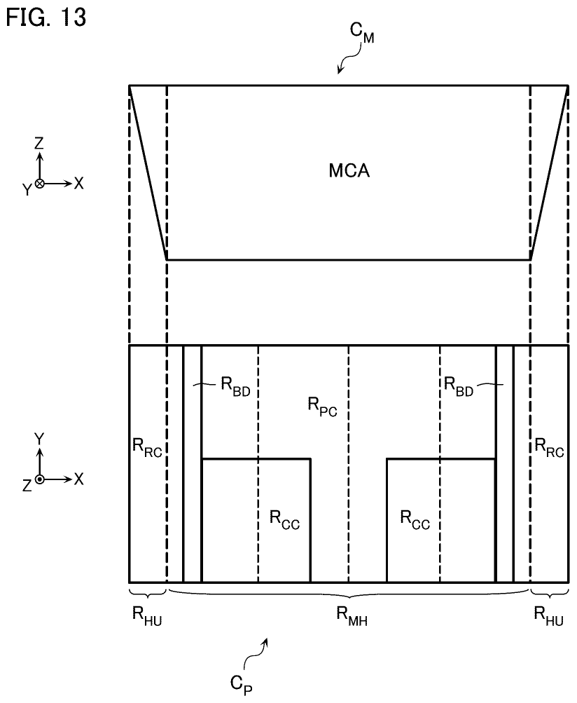

FIG. 6 is a schematic bottom view illustrating an exemplary configuration of the chip C_{M}. FIG. 6 omits a part of a configuration, such as the bonding electrodes P_{I1}. FIG. 7 and FIG. 8 are schematic cross-sectional views illustrating configurations of parts of the memory die MD. FIG. 9 is a schematic bottom view illustrating a configuration of a part of the chip C_{M}. FIG. 9 illustrates the X-Y cross-sectional surface of the position of the word line WL in the left side region and illustrates the X-Y cross-sectional surface of the position of the drain-side select gate line SGD in the right side region. In the right side region of FIG. 9, to represent connection parts of semiconductor layers 120 and the bit lines BL, via-contact electrodes ch, Vy and the bit lines BL are also illustrated. In the left side region of FIG. 9 as well, the via-contact electrodes ch, Vy and the bit lines BL are disposed. FIG. 10 is a schematic cross-sectional view illustrating a configuration of a part of the chip C_{M}. While FIG. 10 illustrates the Y-Z cross-sectional surface, a structure similar to FIG. 10 is observed when a cross-sectional surface other than the Y-Z cross-sectional surface (for example, the X-Z cross-sectional surface) along the central axis of the semiconductor layer 120 is observed. FIG. 11 is a schematic plan view illustrating an exemplary configuration of hook-up regions R_{HU}. FIG. 12 is a schematic plan view illustrating an exemplary configuration of the chip C_{P}. FIG. 12 omits a part of a configuration, such as the bonding electrodes P_{I2}. FIG. 13 is a schematic enlarged view of a part indicated by A in FIG. 12. FIG. 13 also illustrates the configuration of the chip C_{M} (the part of the X-Z cross-sectional surface) corresponding to the configuration of the chip C_{P} (a part of the X-Y plane indicated by A in FIG. 12).

### [Structure of Chip C_{M}]

In the example of FIG. 6, the chip C_{M} includes four memory planes MP0 to MP3 arranged in the X-direction. Note that each of the four memory planes MP0 to MP3 is simply referred to as a memory plane MP in some cases. Each of these four memory planes MP0 to MP3 includes the plurality of memory blocks BLK arranged in the Y-direction. In the example of FIG. 6, each of these four memory planes MP0 to MP3 includes the hook-up regions R_{HU} disposed at both end portions in the X-direction and a memory hole region R_{MH} (memory region) disposed between them. Further, in the example of FIG. 6, the memory hole region R_{MH} is divided into four regions R_{MHU} in the X-direction. All of the widths in the X-direction of these four regions R_{MHU} may be the same or need not be the same. The chip C_{M} includes a peripheral region R_{P} disposed at one end side in the Y-direction with respect to the four memory planes MP0 to MP3.

Note that in the example illustrated in the drawing, the hook-up regions R_{HU} are disposed at both end portions in the X-direction of the memory plane MP. However, the configuration is merely an example, and a specific configuration is appropriately adjustable. For example, the hook-up region R_{HU} may be disposed at one end portion in the X-direction, not both end portions in the X-direction of the memory plane MP. Alternatively, the hook-up region R_{HU} may be disposed at the center position or a position near the center in the X-direction of the memory plane MP.

For example, as illustrated in FIG. 7, the chip C_{M} includes a substrate layer L_{SB}, a memory cell array layer IMCA disposed below the substrate layer L_{SB}, a via-contact electrode layer CH disposed below the memory cell array layer L_{MCA}, a plurality of wiring layers M0, M1 disposed below the via-contact electrode layer CH, and a chip bonding electrode layer MB disposed below the wiring layers M0, M1.

[Structure of Substrate Layer L_{SB} of Chip C_{M}]

For example, as illustrated in FIG. 7, the substrate layer L_{SB} includes a conductive layer 100 disposed on an upper surface of the memory cell array layer L_{MCA}, an insulating layer 101 disposed on an upper surface of the conductive layer 100, a back side wiring layer MA disposed on an upper surface of the insulating layer 101, and an insulating layer 102 disposed on an upper surface of the back side wiring layer MA.

The conductive layer 100, for example, may contain a semiconductor layer of silicon (Si) or the like into which N-type impurities, such as phosphorus (P), or P-type impurities, such as boron (B), are implanted, may contain a metal, such as tungsten (W), or may contain silicide, such as tungsten silicide (WSi).

The conductive layer 100 functions as a part of the source line SL (FIG. 1). The four conductive layers 100 are disposed corresponding to the four memory planes MP0 to MP3 (FIG. 6). The memory plane MP have end portions in the X-direction and Y-direction where regions VZ that do not include the conductive layer 100 are disposed.

The insulating layer 101 contains, for example, silicon oxide (SiO₂).

The back side wiring layer MA includes a plurality of wirings ma. These plurality of wirings ma may contain, for example, aluminum (Al).

A part of the plurality of wirings ma functions as a part of the source line SL (FIG. 2). The four wirings ma are disposed corresponding to the four memory planes MP0 to MP3 (FIG. 6). Each of the wirings ma is electrically connected to the conductive layer 100.

A part of the plurality of wirings ma functions as the external pad electrodes P_{X}. These wirings ma are disposed in the peripheral region R_{P}. These wirings ma are connected to via-contact electrodes CC in the memory cell array layer L_{MCA} in the regions VZ not including the conductive layer 100. A part of the wirings ma is exposed to the outside of the memory die MD via an opening TV provided in the insulating layer 102.

The insulating layer 102 is, for example, a passivation layer made of an insulating material, such as polyimide.

[Structure of Memory Cell Array Layer L_{MCA} of Chip C_{M} in Memory Hole Region R_{MH}]

As described with reference to FIG. 6, in the memory cell array layer L_{MCA}, the plurality of memory blocks BLK arranged in the Y-direction are disposed. As illustrated in FIG. 7, between the two memory blocks BLK adjacent in the Y-direction, an inter-block insulating layer ST of silicon oxide (SiO₂) or the like is disposed. A plurality of stacked structures including a plurality of conductive layers 110 arranged in the Z-direction are arranged in the Y-direction, and correspond to the plurality of memory blocks BLK.

For example, as illustrated in FIG. 7, the memory block BLK includes a plurality of conductive layers 110 arranged in the Z-direction and a plurality of semiconductor layers 120 extending in the Z-direction. Additionally, as illustrated in FIG. 10, respective gate insulating films 130 are disposed between the plurality of conductive layers 110 and the plurality of semiconductor layers 120.

The conductive layer 110 has an approximately plate shape extending in the X-direction. The conductive layer 110 may include, for example, a stacked film of a barrier conductive film of titanium nitride (TiN) or the like and a metal film of tungsten (W), molybdenum (Mo), or the like. The conductive layer 110 may contain, for example, polycrystalline silicon containing impurities, such as phosphorus (P) or boron (B). Between the plurality of conductive layers 110 arranged in the Z-direction, an interlayer insulating layer 111 of silicon oxide (SiO₂) or the like is disposed.

Among the plurality of conductive layers 110, one or a plurality of conductive layers 110 positioned on the uppermost layer function as a gate electrode of the source-side select transistor STS (FIG. 2) and the source-side select gate line SGS (see FIG. 7). These plurality of conductive layers 110 are electrically independent in every memory block BLK.

Additionally, a plurality of conductive layers 110 positioned below this conductive layer 110 function as gate electrodes of the memory cells MC (FIG. 2) and the word lines WL. Each of the plurality of conductive layers 110 is electrically independent in every memory block BLK.

One or a plurality of conductive layers 110 positioned below the conductive layers 110 function as a gate electrode of the drain-side select transistor STD and the drain-side select gate line SGD. For example, as illustrated in FIG. 9, a width Y_{SGD} in the Y-direction of these plurality of conductive layers 110 is smaller than a width Y_{WL} in the Y-direction of the conductive layers 110 that function as the word lines WL. Between two conductive layers 110 adjacent in the Y-direction, an inter-string unit insulating layer SHE of silicon oxide (SiO₂) or the like is disposed.

For example, as illustrated in FIG. 9, the semiconductor layers 120 are arranged in a predetermined pattern in the X-direction and the Y-direction. The respective semiconductor layers 120 function as the channel regions of the plurality of memory cells MC and the select transistors (STD, STS) included in one memory string MS (FIG. 2). The semiconductor layer 120 contains, for example, polycrystalline silicon (Si). The semiconductor layer 120 has an approximately cylindrical shape and includes an insulating layer 125 of silicon oxide or the like in the center portion. The outer peripheral surfaces of the semiconductor layers 120 are each surrounded by the plurality of conductive layers 110 and opposed to the plurality of conductive layers 110.

Additionally, on the upper end of the semiconductor layer 120, an impurity region (not illustrated) is disposed. This impurity region is connected to the conductive layer 100 (see FIG. 7). This impurity region, for example, contains N-type impurities, such as phosphorus (P), or P-type impurities, such as boron (B).

On the lower end of the semiconductor layer 120, an impurity region (not illustrated) is disposed. This impurity region is connected to the bit line BL via a via-contact electrode ch and a via-contact electrode Vy. This impurity region, for example, contains N-type impurities, such as phosphorus (P).

For example, as illustrated in FIG. 9, the gate insulating film 130 has an approximately cylindrical shape covering the outer peripheral surface of the semiconductor layer 120. For example, as illustrated in FIG. 10, the gate insulating film 130 includes a tunnel insulating film 131, an electric charge accumulating film 132, and a block insulating film 133, which are stacked between the semiconductor layer 120 and the conductive layers 110. The tunnel insulating film 131 and the block insulating film 133 contain, for example, silicon oxide (SiO₂) or silicon oxynitride (SiON). The electric charge accumulating film 132 includes, for example, a film that can accumulate an electric charge of silicon nitride (SiN) or the like. The tunnel insulating film 131, the electric charge accumulating film 132, and the block insulating film 133 have an approximately cylindrical shape, and extend in the Z-direction along the outer peripheral surface of the semiconductor layer 120 excluding a contact portion of the semiconductor layer 120 with the conductive layer 100.

Note that FIG. 10 illustrates an example of the gate insulating film 130 including the electric charge accumulating film 132 of silicon nitride or the like. However, the gate insulating film 130, for example, may include a floating gate of polycrystalline silicon or the like containing N-type or P-type impurities.

[Structure of Memory Cell Array Layer L_{MCA} of Chip C_{M} in Hook-Up Region R_{HU}]

As illustrated in FIG. 8, the hook-up region R_{HU} includes a plurality of via-contact electrodes CC. Each of these plurality of via-contact electrodes CC extends in the Z-direction and has an upper end connected to the conductive layer 110 (WL, SGD, SGS).

As illustrated in FIG. 11, the hook-up regions R_{HU} are disposed on an X-direction negative side and an X-direction positive side of the memory plane MP, and the memory hole region R_{MH} is disposed between the two hook-up regions R_{HU}. In the memory hole region R_{MH}, the first to eighth memory blocks counted from the Y-direction positive side are assumed to be memory blocks BLK (1) to BLK (8). The hook-up region R_{HU} at the X-direction negative side is divided into hook-up regions R_{HU} (N1) to R_{HU} (N8) corresponding to the memory blocks BLK (1) to BLK (8). The hook-up region R_{HU} at the X-direction positive side is divided into hook-up regions R_{HU} (P1) to R_{HU} (P8) corresponding to the memory blocks BLK (1) to BLK (8).

In each of the hook-up regions R_{HU} (N1) to R_{HU} (N8) and R_{HU} (P1) to R_{HU} (P8), a plurality of rows of the three via-contact electrodes CC arranged in the Y-direction are arranged in the X-direction.

The plurality of via-contact electrodes CC in the hook-up regions R_{HU} (N1) to R_{HU} (N8) are connected to a half of the conductive layers 110 of the memory blocks BLK (1) to BLK (8), respectively. The plurality of via-contact electrodes CC in the hook-up regions R_{HU} (P1) to R_{HU} (P8) are connected to the other half of the conductive layers 110 of the memory blocks BLK (1) to BLK (8), respectively.

[Structure of Memory Cell Array Layer L_{MCA} of Chip C_{M} in Peripheral Region R_{P}]

For example, as illustrated in FIG. 7, the peripheral region R_{P} includes the plurality of via-contact electrodes CC corresponding to the external pad electrode P_{X}. These plurality of via-contact electrodes CC have upper ends connected to the external pad electrode P_{X}.

### [Structure of Via-Contact Electrode Layer CH]

As illustrated in FIG. 7 to FIG. 9, the via-contact electrode layer CH includes the plurality of via-contact electrodes ch as a plurality of wirings. For example, the plurality of via-contact electrodes ch are electrically connected to at least one of the configuration in the memory cell array layer L_{MCA} and the configuration in the chip C_{P}.

These plurality of via-contact electrodes ch may include, for example, a stacked film of a barrier conductive film of titanium nitride (TiN) or the like and a metal film of tungsten (W) or the like. The via-contact electrodes ch are disposed corresponding to the plurality of semiconductor layers 120 and connected to lower ends of the plurality of semiconductor layers 120.

### [Structure of Wiring Layers M0, M1 of Chip C_{M}]

A plurality of wirings included in the wiring layers M0, M1 are, for example, electrically connected to at least one of the configuration in the memory cell array layer L_{MCA} and the configuration in the chip C_{P}.

For example, as illustrated in FIG. 7, the wiring layer M0 includes a plurality of wirings m0. These plurality of wirings m0 may include, for example, a stacked film of a barrier conductive film, which is made of titanium nitride (TiN), tantalum nitride (TaN), a stacked film of tantalum nitride (TaN) and tantalum (Ta), or the like, and a metal film of copper (Cu) or the like. Note that a part of the plurality of wirings m0 function as the bit lines BL. As illustrated in FIG. 9, the bit lines BL, for example, are arranged in the X-direction and extend in the Y-direction.

For example, as illustrated in FIG. 7, the wiring layer M1 includes a plurality of wirings m1. These plurality of wirings m1 may include, for example, a stacked film of a barrier conductive film of titanium nitride (TiN) or the like and a metal film of tungsten (W) or the like. A wiring pattern in the wiring layer M1 is described later.

### [Structure of Chip Bonding Electrode Layer MB]

The plurality of wirings included in the chip bonding electrode layer MB are, for example, electrically connected to at least one of the configuration in the memory cell array layer L_{MCA} and the configuration in the chip C_{P}.

The chip bonding electrode layer MB includes the plurality of bonding electrodes P_{I1} (bonding pads). These plurality of bonding electrodes P_{I1} may include, for example, a stacked film of a barrier conductive film p_{I1B}, which is made of titanium nitride (TiN), tantalum nitride (TaN), a stacked film of tantalum nitride (TaN) and tantalum (Ta), or the like, and a metal film prim of copper (Cu) or the like.

### [Structure of Chip C_{P}]

For example, as illustrated in FIG. 12, the chip C_{P} includes regions MP0′ to MP3′ arranged in the X-direction and overlapping with the four memory planes MP0 to MP3. Row control circuit regions R_{RC} are disposed at both end portions in the X-direction of each of these four regions MP0′ to MP3′. Additionally, between these two row control circuit regions R_{RC}, two block decoder regions R_{BD} arranged in the X-direction are disposed. Additionally, between these two block decoder regions R_{BD}, a peripheral circuit region R_{PC} is disposed. The peripheral circuit region R_{PC} includes four column control circuit regions R_{CC} arranged in the X-direction and the Y-direction. Although the illustration is omitted, a circuit is also disposed in another region of the peripheral circuit region R_{PC}. A circuit region R_{C} is disposed in a region of the chip C_{P} opposed to the peripheral region R_{P} (FIG. 6) of the chip C_{M}.

The row control circuit region R_{RC} includes the plurality of block decoder units blkd described with reference to FIG. 3 and FIG. 4. That is, the row control circuit region R_{RC} includes the plurality of word line switches WLSW and the plurality of select gate line switches SGSW constituting the plurality of block decoder units blkd. The block decoder region R_{BD} includes the block decoder BLKD described with reference to FIG. 4. The column control circuit region R_{CC} includes the sense amplifier module SAM described with reference to FIG. 1. The circuit region R_{C} includes an input/output circuit (not illustrated). This input/output circuit is connected to the external pad electrodes P_{X} via the via-contact electrodes CC and the like described with reference to FIG. 7 and the like.

FIG. 12 and FIG. 13 illustrate the regions overlapping with the hook-up regions R_{HU} (FIG. 6) when viewed in the Z-direction by the dotted lines. In the examples of FIG. 12 and FIG. 13, parts of the row control circuit regions R_{RC} are disposed in the regions overlapping with the hook-up regions R_{HU} (FIG. 6) when viewed in the Z-direction. Parts of the row control circuit regions R_{RC} are disposed in the regions overlapping with the memory hole regions R_{MH} (FIG. 6) when viewed in the Z-direction. In the examples of FIG. 12 and FIG. 13, the width in the X-direction of the row control circuit region R_{RC} is larger than the width in the X-direction of the hook-up region R_{HU} (FIG. 6). Thus, the plurality of word line switches WLSW and the select gate line switches of the row control circuit region R_{RC} are disposed at the positions overlapping with the parts of the hook-up regions R_{HU} and memory hole regions R_{MH} when viewed in the Z-direction.

In the example of FIG. 12, the center positions in the X-direction of the column control circuit regions R_{CC} match the boundary between the first and second regions R_{MHU} counted from the X-direction negative side or the boundary between the third and fourth regions R_{MHU} counted from the X-direction negative side. Note that the center positions in the X-direction of the column control circuit regions R_{CC} need not match the boundary between the first and second regions R_{MHU} counted from the X-direction negative side and the boundary between the third and fourth regions R_{MHU} counted from the X-direction negative side.

For example, as illustrated in FIG. 7, the chip C_{P} includes a semiconductor substrate 200, an electrode layer GC disposed above the semiconductor substrate 200, wiring layers D0, D1, D2, D3, D4 disposed above the electrode layer GC, and a chip bonding electrode layer DB disposed above the wiring layers D0, D1, D2, D3, D4.

### [Structure of Semiconductor Substrate 200 of Chip C_{P}]

For example, as illustrated in FIG. 7 and FIG. 8, the semiconductor substrate 200 contains P-type silicon (Si) containing P-type impurities, such as boron (B). On the surface of the semiconductor substrate 200, for example, N-type well regions 200N containing N-type impurities, such as phosphorus (P), P-type well regions 200P containing P-type impurities, such as boron (B), a semiconductor substrate region 200S in which the N-type well region 200N or the P-type well region 200P is not disposed, and insulating regions STI are disposed. A part of the P-type well region 200P is disposed in the semiconductor substrate region 200S, and a part of the P-type well region 200P is disposed in the N-type well region 200N. The respective N-type well regions 200N, P-type well regions 200P disposed in the N-type well region 200N and the semiconductor substrate region 200S, and semiconductor substrate region 200S function as parts of a plurality of transistors Tr, a plurality of capacitors, and the like constituting the peripheral circuit PC. Note that a part of the plurality of transistors Tr function as the word line switches WLSW and the select gate line switches SGSW.

### [Structure of Electrode Layer GC of Chip C_{P}]

As illustrated in FIG. 7, the electrode layer GC is disposed on an upper surface of the semiconductor substrate 200 via an insulating layer 200G. The electrode layer GC includes a plurality of electrodes gc opposed to the surface of the semiconductor substrate 200. Each region of the semiconductor substrate 200 and each of the plurality of electrodes gc included in the electrode layer GC are connected to the via-contact electrode CS.

The respective N-type well regions 200N, P-type well regions 200P disposed in the N-type well region 200N and the semiconductor substrate region 200S, and semiconductor substrate region 200S of the semiconductor substrate 200 function as channel regions of the plurality of transistors Tr, one electrodes of the plurality of capacitors, and the like constituting the peripheral circuit PC.

The respective plurality of electrodes gc included in the electrode layer GC function as gate electrodes of the plurality of transistors Tr, the other electrodes of the plurality of capacitors, and the like constituting the peripheral circuit PC.

The via-contact electrode CS extends in the Z-direction and has a lower end connected to the semiconductor substrate 200 or the upper surface of the electrode gc. An impurity region containing N-type impurities or P-type impurities is disposed in a connection part of the via-contact electrode CS and the semiconductor substrate 200. The via-contact electrode CS may include, for example, a stacked film of a barrier conductive film of titanium nitride (TiN) or the like and a metal film of tungsten (W) or the like.

### [Structure of Wiring Layers D0, D1, D2, D3, D4 of Chip C_{P}]

For example, as illustrated in FIG. 7, the plurality of connecting portions and the plurality of wirings included in the wiring layers D0, D1, D2, D3, D4 are, for example, electrically connected to at least one of the configuration in the memory cell array layer L_{MCA} and the configuration in the chip C_{P}.

The wiring layers D0, D1, D2 includes a plurality of connecting portions d0, d1, d2, respectively, and a plurality of wirings (for example, hook-up wirings W0, W1, W2, passing wirings TW2, and shield wirings s2 described later). These plurality of connecting portion d0, d1, d2 and the plurality of wirings may include, for example, a stacked film of a barrier conductive film of titanium nitride (TiN) or the like and a metal film of tungsten (W) or the like.

The wiring layers D3, D4 include a plurality of connecting portions d3, d4, respectively and a plurality of wirings (for example, hook-up wirings W3, passing wirings TW3, shield wirings s3, and the wirings CGI described later). These plurality of connecting portion d3, d4 and plurality of wirings may include, for example, a stacked film of a barrier conductive film, which is made of titanium nitride (TiN), tantalum nitride (TaN), a stacked film of tantalum nitride (TaN) and tantalum (Ta), or the like, and a metal film of copper (Cu) or the like.

The configurations of the connecting portions d0, d1, d2, d3, d4 and the plurality of wirings in the wiring layers D0, D1, D2, D3, D4 are described later.

### [Structure of Chip Bonding Electrode Layer DB]

The plurality of wirings included in the chip bonding electrode layer DB are, for example, electrically connected to at least one of the configuration in the memory cell array layer L_{MCA} and the configuration in the chip C_{P}.

The chip bonding electrode layer DB includes the plurality of bonding electrodes P_{I2}. These plurality of bonding electrodes P_{I2} may include, for example, a stacked film of a barrier conductive film p_{I2B}, which is made of titanium nitride (TiN), tantalum nitride (TaN), a stacked film of tantalum nitride (TaN) and tantalum (Ta), or the like, and a metal film p_{I2M} of copper (Cu) or the like.

When the metal films p_{I1M}, p_{I2M} of copper (Cu) or the like are used for the bonding electrode P_{I1} and the bonding electrode P_{I2}, the metal film prim and the metal film p_{I2M} are integrated, and confirmation of the mutual boundary is difficult. However, the bonding structure can be confirmed by distortion of the shape of bonding the bonding electrode P_{I1} and the bonding electrode P_{I2} due to the positional displacement of the bonding and the positional displacement (generation of discontinuous portions in side surfaces) of the barrier conductive films p_{I1B}, p_{I2B}. Additionally, when the bonding electrode P_{I1} and the bonding electrode P_{I2} are formed by damascene method, the respective side surfaces have a tapered shape. In view of this, in the shape of the cross-sectional surface along the Z-direction in the part where the bonding electrode P_{I1} and the bonding electrode P_{I2} are bonded, the sidewall does not have a linear shape, but a non-rectangular shape. Additionally, when the bonding electrode P_{I1} and the bonding electrode P_{I2} are bonded, a structure of covering the bottom surface, the side surface, and the upper surface of each Cu forming them by a barrier metal is formed. In contrast to this, in a general wiring layer using Cu, an insulating layer (for example, SiN or SiCN) having an oxidation reduction function of Cu is disposed on the upper surface of Cu, and a barrier metal is not disposed. In view of this, even when the positional displacement of the bonding does not occur, distinction with a general wiring layer is possible.

### [Wiring Pattern in Wiring Layer M1]

As described with reference to FIG. 4 and the like, the word line switch WLSW is connected to each of the word lines WL. The select gate line switch SGSW is connected to each of the select gate lines SG. Here, since there may be a case where a comparatively large voltage is applied to the word line WL and the select gate line SG, high breakdown voltage transistors are used for the word line switch WLSW and the select gate line switch SGSW. Here, the high breakdown voltage transistor becomes comparatively large in some cases. In terms of this, the area of the row control circuit region R_{RC} described with reference to FIG. 12 becomes comparatively large in some cases.

Here, when the area of the row control circuit region R_{RC} is larger than the area of the hook-up region R_{HU}, it is considered that a part of the row control circuit regions R_{RC} are disposed in the regions overlapping with the hook-up regions R_{HU} when viewed in the Z-direction and the remaining parts are disposed in the regions not overlapping with the memory hole regions R_{MH} when viewed in the Z-direction. However, in this case, the area of the entire regions MP′ increases, and the circuit area of the memory die MD increases in some cases.

Therefore, in this embodiment, as described with reference to FIG. 12 and FIG. 13, a part of the row control circuit regions R_{RC} are disposed in the regions overlapping with the hook-up regions R_{HU} when viewed in the Z-direction and the remaining parts are disposed in the regions overlapping with the memory hole regions R_{MH} When viewed in the Z-direction.

When such a structure is employed, when viewed in the Z-direction, a part of the bit lines BL are disposed at the positions overlapping with the row control circuit regions R_{RC} and the block decoder regions R_{BD}, not the column control circuit regions R_{CC}.

Therefore, in this embodiment, wirings m1a extending in the X-direction are disposed in the wiring layer M1, and a part of the bit lines BL and the configurations in the column control circuit regions R_{CC} are electrically connected via these wirings m1a. With this configuration, the increase in the circuit area of the memory die MD in association with the increase in the area of the row control circuit region R_{RC} is reduced, and the semiconductor memory device that allows high integration can be provided.

Note that the area of the row control circuit region R_{RC} may be the same as the area of the hook-up region R_{HU} and may be smaller than the area of the hook-up region R_{HU}. This eliminates the need for disposing the wirings m1a in the wiring layer M1 to electrically connect a part of the bit lines BL and the configurations in the column control circuit regions R_{CC}.

### [Control Circuit SYN and Passing Wiring TW]

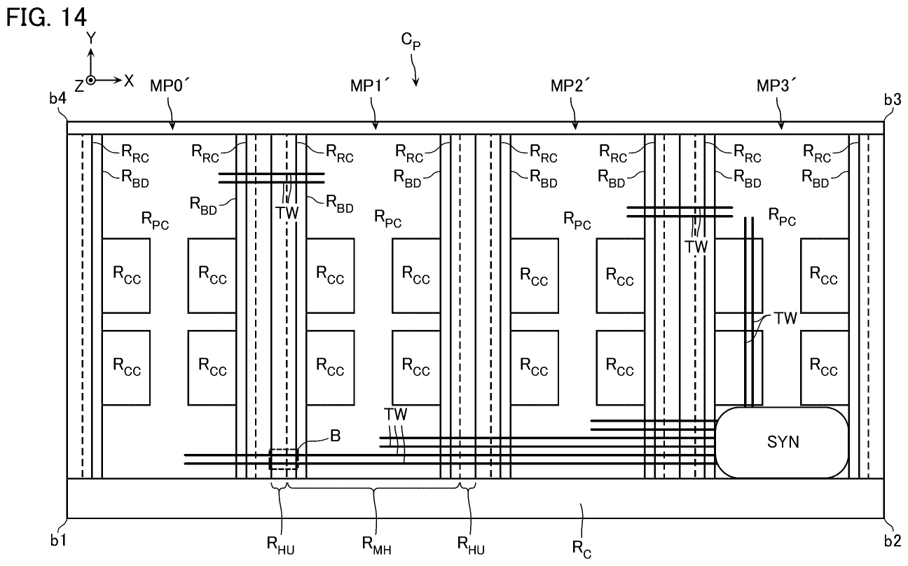

FIG. 14 is a schematic plan view illustrating the control circuit SYN and the passing wirings TW. In FIG. 14, the same reference numerals are given to the configurations same as the configurations of FIG. 12, and the overlapping explanation is omitted.

The control circuit SYN is a module that outputs the control signals of various kinds of the peripheral circuits PC in the chip C_{P} based on input signals. The control circuit SYN includes the sequencer SQC or the like described with reference to FIG. 1 in some cases. Additionally, the control signal output from the control circuit SYN includes a voltage control signal (input to a charge pump circuit, a regulator, and the like), an address signal, and the like in some cases. In the example of FIG. 14, the control circuit SYN is disposed in a region at the Y-direction negative side in the peripheral circuit region R_{PC} in the region MP3′. Note that the control circuit SYN may be disposed at a position different from the position illustrated in FIG. 14.

The plurality of passing wirings TW connect between the peripheral circuits PC in the plurality of regions MP′. As illustrated in FIG. 14, the plurality of passing wirings TW extending in the X-direction and the Y-direction are disposed across the plurality of regions MP′. The plurality of passing wirings TW transmit various kinds of signals including the control signal. A part of the plurality of passing wirings TW are connected to the control circuit SYN and transmit the control signals from the control circuit SYN. These plurality of passing wirings TW are, for example, formed in the wiring layers D2, D3, D4 in the chip C_{P}.

As illustrated in FIG. 14, the plurality of passing wirings TW disposed across the plurality of regions MP′ pass through above the row control circuit regions R_{RC} and the block decoder regions R_{BD} in the semiconductor substrate 200.

### [Structures of Word Line Switch WLSW and Select Gate Line Switch SGSW]

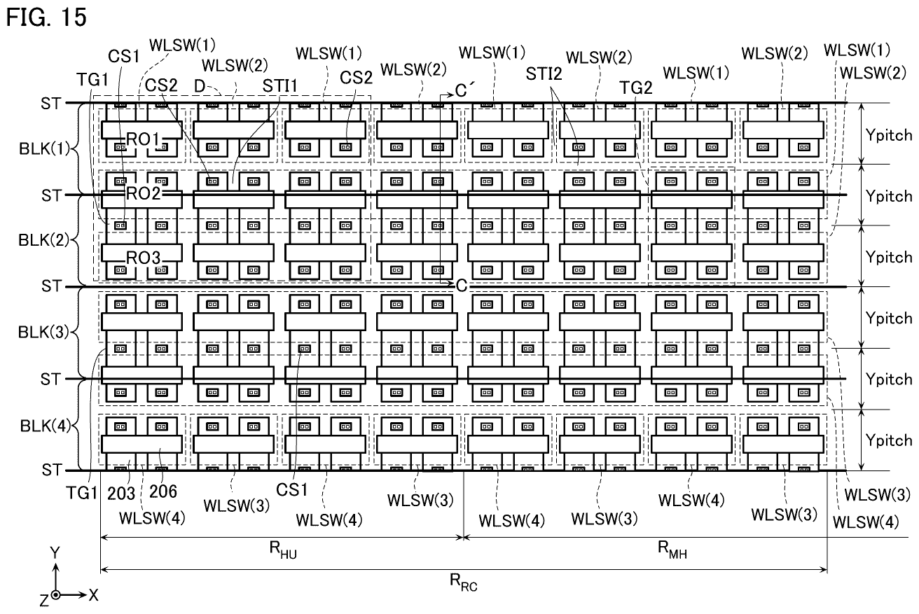

FIG. 15 is a schematic plan view illustrating an exemplary configuration of the word line switches WLSW. Note that FIG. 15, for example, corresponds to the part indicated by B in FIG. 14. For ease of explanation, FIG. 15 illustrates an example in which the number of the word line switches WLSW (that is, the number of the word lines WL) in one memory block BLK is 24. However, the number of the word line switches WLSW is not limited to this number.

FIG. 15 illustrates the two word line switches WLSW (transistors) having a common source region. Hereinafter, the two word line switches WLSW (transistors) are referred to as a “transistor group TG1”.

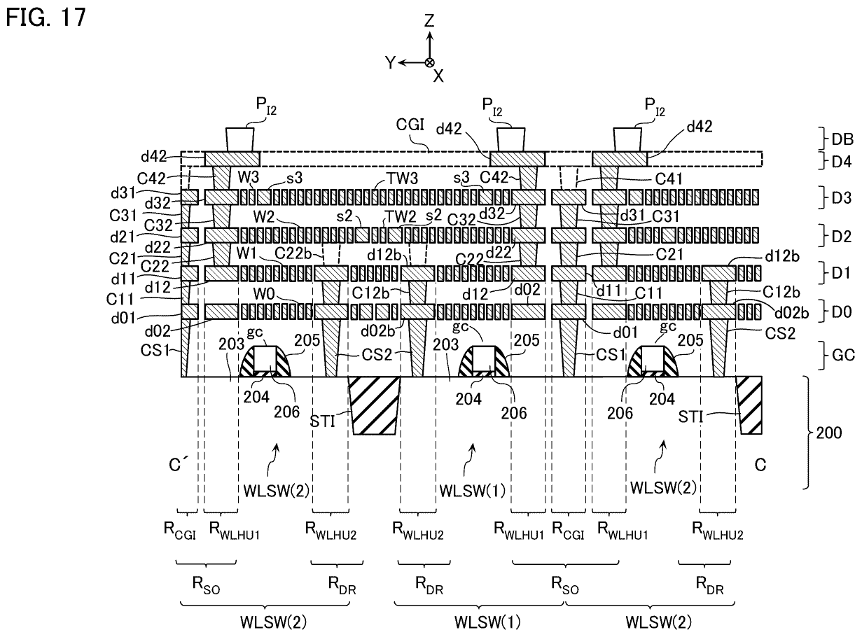

As illustrated in FIG. 15, the transistor group TG1 includes a semiconductor region (diffusion region) 203 extending in the Y-direction. The semiconductor regions 203 are arranged in the Y-direction and arranged in the X-direction. Additionally, at both end portions in the Y-direction of the semiconductor region 203, respective via-contact electrodes CS2 functioning as drain terminals of the word line switches WLSW are disposed. Additionally, between these via-contact electrodes CS2, via-contact electrodes CS1 functioning as common source terminals of the two word line switches WLSW are disposed. Additionally, between the via-contact electrode CS2 functioning as the drain terminal and the via-contact electrode CS1 functioning as the source terminal, a gate insulating layer 204 (see FIG. 17) and a gate electrode 206 are each disposed.

In this embodiment, a pitch Ypitch in the Y-direction of the word line switches WLSW is smaller than a pitch in the Y-direction of the memory blocks BLK. More specifically, a ratio of the pitch in the Y-direction between the word line switch WLSW and the memory block BLK is 2:3. That is, a length in the Y-direction of three word line switches WLSW arranged in the Y-direction is equal to a length in the Y-direction of two memory blocks BLK arranged in the Y-direction. Hereinafter, such an arrangement pattern of the word line switch WLSW is denoted as “3Tr/2BLK” in some cases.

In this embodiment, as illustrated in FIG. 15, when the four memory blocks BLK (1), BLK (2), BLK (3), and BLK (4) arranged in the Y-direction are focused on, a position between a pair of transistor groups TG1 arranged at the center in the Y-direction corresponds to a position of an inter-block insulating layer ST at the center. Positions apart from the inter-block insulating layer ST at the center on both sides in the Y-direction by ¾ of a length in the Y-direction of the transistor group TG1 correspond to positions of other inter-block insulating layers ST. Respective center positions in the Y-direction of transistor groups TG1 adjacent to the pair of transistor groups TG1 at the center on both sides in the Y-direction correspond to positions of still other inter-block insulating layers ST.

In this embodiment, a plurality of sets of three word line switches WLSW arranged in the Y-direction are arranged in the X-direction corresponding to two memory blocks BLK adjacent in the Y-direction. In the plurality of word line switches WLSW arranged in the X-direction, one row includes word line switches WLSW of one memory block BLK, one of the other rows includes word line switches WLSW of the other memory block BLK, and the other row includes alternately arranged word line switches WLSW of the two memory blocks BLK.

For example, in a case of memory blocks BLK (1), BLK (2) adjacent in the Y-direction illustrated in FIG. 15, word line switches WLSW (1) are connected to a word line WL (1) of the memory block BLK (1), and word line switches WLSW (2) are connected to a word line WL (2) of the memory block BLK (2). In a first row RO1, a plurality of the word line switches WLSW (1) and a plurality of word line switches WLSW (2) are alternately arranged in the X-direction two by two. In a second row RO2, a plurality of the word line switches WLSW (1) are arranged in the X-direction. In a third row RO3, a plurality of the word line switches WLSW (2) are arranged in the X-direction.

In the first row RO1, two word line switches WLSW (1) adjacent in the X-direction are connected by a common gate electrode 206, thereby constituting one transistor group TG2. Further, in the first row RO1, two word line switches WLSW (2) adjacent in the X-direction are connected by a common gate electrode 206, thereby constituting one transistor group TG2. Then, the transistor group TG2 including the word line switches WLSW (1) and the transistor group TG2 including the word line switches WLSW (2) are alternately arranged in the X-direction. Also, in the second row RO2 and the third row RO3, for the consistency of the pattern with the first row RO1, two word line switches WLSW (1) and two word line switches WLSW (2) are each connected by a common gate electrode 206, thereby constituting one transistor group TG2. Note that the word line switches WLSW (1) in the second row RO2 and the word line switches WLSW (2) in the third row RO3 may be each connected to a single gate electrode 206 continuous in the X-direction.

Between the semiconductor regions 203 constituting the word line switches WLSW included in the same transistor group TG2, an insulating region STI1 that insulates the semiconductor regions 203 from one another is disposed. Between the semiconductor regions 203 constituting the word line switches WLSW included in the different transistor groups TG2, an insulating region STI2 that insulates the semiconductor regions 203 of the different transistor groups TG2 from one another is disposed. The insulating region STI2 insulates the word line switches WLSW for different memory blocks BLK from one another in some cases. Therefore, a width in the X-direction of the insulating region STI2 is larger than a width in the X-direction of the insulating region STI1. A width in the Y-direction of the insulating region STI2 is larger than a width in the X-direction of the insulating region STI1.

An arrangement pattern of the word line switch WLSW in the memory blocks BLK (3), BLK (4) is line symmetry to the arrangement pattern of the word line switch WLSW of the memory blocks BLK (1), BLK (2) with respect to the center of the inter-block insulating layer ST between the memory blocks BLK (2) and BLK (3).

While FIG. 15 illustrates the structure of the word line switch WLSW, the structure of the select gate line switch SGSW may be similar to the structure of the word line switch WLSW.

[Path between Conductive Layer 110 and Word Line Switch WLSW, Select Gate Line Switch SGSW]

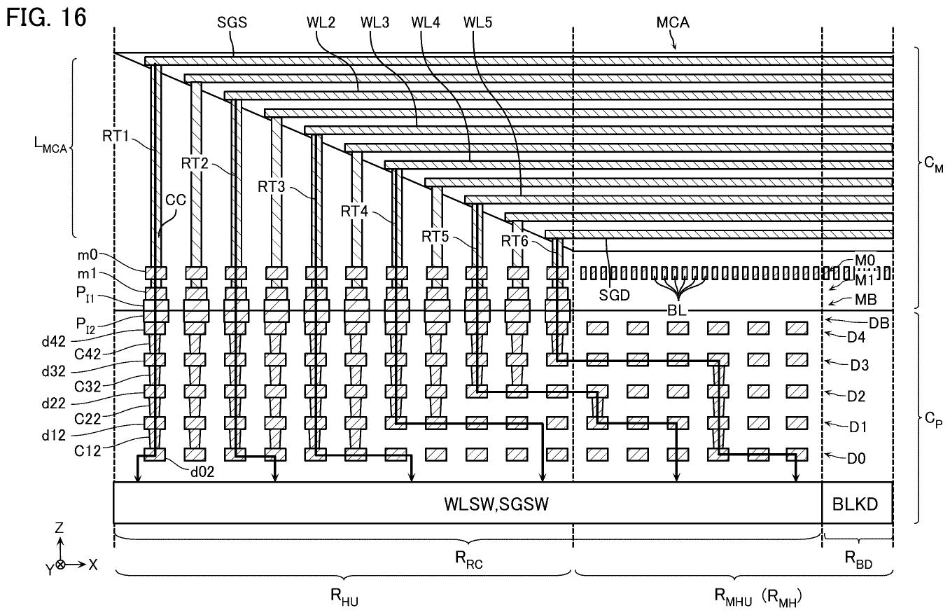

FIG. 16 is a diagram schematically illustrating wiring paths from the conductive layers 110 of the memory cell array MCA to the word line switch WLSG and the select gate line switch SGSW. As illustrated in FIG. 16, the word lines WL and the select gate lines SG (SGD, SGS) in the memory cell array layer L_{MCA} of the chip C_{M} are electrically connected to the via-contact electrodes CS2 that function as the drain terminals of the word line switch WLSW and the select gate line switch SGSW via the via-contact electrodes CC, the bonding electrodes P_{I1}, P_{I2}, connecting portions d42 of the wiring layer D4, via-contact electrodes C42, connecting portions d32 of the wiring layer D3, via-contact electrodes C32, connecting portions d22 of the wiring layer D2, via-contact electrodes C22, connecting portions d12 of the wiring layer D1, via-contact electrodes C12, and connecting portions d02 of the wiring layer D0. Note that FIG. 16 omits the via-contact electrode layer CH. Paths from the word lines WL and the select gate lines SG to the word line switch WLSW and the select gate line switch SGSW as described above are referred to as paths RT in FIG. 16.

As illustrated in FIG. 16, the source-side select gate line SGS as the uppermost layer in the memory cell array layer L_{MCA} is connected to the select gate line switch SGSW at the end portion at the X-direction negative side (this select gate line switch SGSW is denoted as SGSW1) in the row control circuit region R_{RC} via a path RT1. A word line WL2 below the source-side select gate line SGS is connected to the word line switch WLSW at the X-direction positive side with respect to the select gate line switch SGSW1 (this word line switch WLSW is denoted as WLSW2) via a path RT2. A word line WL3 below the word line WL2 is connected to the word line switch WLSW at the X-direction positive side with respect to the word line switch WLSW2 (this word line switch WLSW is denoted as WLSW3) via a path RT3.

Although not illustrated in FIG. 16, in the above-described paths RT1, RT2, RT3, the connecting portions d02 and connecting portions d02b of the wiring layer D0 are connected with the hook-up wirings (the hook-up wirings W0 described later), and the connecting portions d02b are connected to the via-contact electrodes CS2.

A word line WL4 below the word line WL3 is connected to the word line switch WLSW at the X-direction positive side with respect to the word line switch WLSW3 (this word line switch WLSW is denoted as WLSW4) via a path RT4.

Although not illustrated in FIG. 16, in the above-described path RT4, the connecting portions d12 and connecting portions d12b of the wiring layer D1 are connected with the hook-up wiring (the hook-up wiring W1 described later), the connecting portion d12b is connected to the connecting portion d02b via the via-contact electrode C12b, and the connecting portion d02b is connected to the via-contact electrode CS2.

A word line WL5 below the word line WL4 is connected to the word line switch WLSW at the X-direction positive side with respect to the word line switch WLSW4 (this word line switch WLSW is denoted as WLSW5) via a path RT5.

Although not illustrated in FIG. 16, in the above-described path RT5, one connecting portion d22 of the wiring layer D2 and another connecting portion d22 at the position at the X-direction positive side with respect to the one connecting portion d22 are connected with the hook-up wiring (the hook-up wiring W2 described later). The connecting portion d22 is connected to the connecting portion d12 via the via-contact electrode C22, the connecting portion d12 and the connecting portion d12b are connected with the hook-up wiring (the hook-up wiring W1 described later), the connecting portion d12b is connected to the connecting portion d02b via the via-contact electrode C12b, and the connecting portion d02b is connected to the via-contact electrode CS2.

The drain-side select gate line SGD below the word line WL5 is connected to a select gate line switch SGSW6 at the X-direction positive side with respect to the word line switch WLSW5 via a path RT6.

Although not illustrated in FIG. 16, in the above-described path RT6, one connecting portion d32 of the wiring layer D3 and another connecting portion d32 at the position at the X-direction positive side with respect to the one connecting portion d32 are connected with the hook-up wiring (the hook-up wiring W3 described later). The connecting portion d32 is connected to the connecting portion d22 via the via-contact electrode C32, the connecting portion d22 is connected to the connecting portion d12 via the via-contact electrode C22, and the connecting portion d12 is connected to the connecting portion d02 via the via-contact electrode C12. The connecting portion d02 and the connecting portion d02b are connected with the hook-up wiring (the hook-up wiring W0 described later), and the connecting portion d02b is connected to the via-contact electrode CS2.

As illustrated in FIG. 16, the respective plurality of connecting portions d42, d32, d22, d12, d02 are formed to be spaced in the X-direction and the Y-direction regardless of whether they are connected to the via-contact electrodes and the wirings or not. The connecting portions d42, d32, d22, d12, d02 unconnected to the via-contact electrodes and the wirings are dummy connecting portions not constituting the electrical connection paths. The respective plurality of connecting portions d12b, d02b illustrated in FIG. 16 are formed to be spaced in the X-direction and the Y-direction regardless of whether they are connected to the via-contact electrodes and the wirings or not. The connecting portions d12b, d02b unconnected to the via-contact electrodes and the wirings are dummy connecting portions not constituting electrical connection paths. However, the dummy connecting portion need not be formed.

Additionally, the plurality of bonding electrodes P_{I1}, P_{I2} connected to the word lines WL and the select gate lines SG via the via-contact electrodes CC are disposed in the hook-up region R_{HU}. The number of these plurality of bonding electrodes P_{I1}, P_{I2} is determined according to the number of the word lines WL and the select gate lines SG. Among the plurality of bonding electrodes P_{I1}, P_{I2}, the dummy bonding electrodes P_{I1}, P_{I2} unconnected to the word lines WL and the select gate lines SG may be disposed.

Note that in FIG. 16, the select gate line switch SGSW1, the word line switches WLSW2, WLSW3, WLSW4, WLSW5, and the select gate line switch SGSW6 are disposed in the order at the X-direction positive side. However, the disposition of the select gate line switches SGSW1, 6 and the word line switches WLSW2, WLSW3, WLSW4, WLSW5 are one example and is not limited to the disposition illustrated in FIG. 16.

In the paths RT1 to RT6 in FIG. 16, the paths at the X-direction positive side (such as the paths RT5, RT6) electrically connect the connecting portions using the hook-up wirings of the upper wiring layers compared with the paths at the X-direction negative side (such as the paths RT1, RT2). However, such paths RT1 to RT6 are one example and are not limited to the paths illustrated in FIG. 16.

For example, in the above-described path RT5, one connecting portion d22 of the wiring layer D2 and another connecting portion d22 at the position at the X-direction positive side with respect to the one connecting portion d22 are connected with the hook-up wiring (the hook-up wiring W2 described later). The connecting portion d22 is connected to the connecting portion d12 of the wiring layer D1 via the via-contact electrode C22, and the connecting portion d12 is connected to the connecting portion d02 of the wiring layer D0 via the via-contact electrode C12. The connecting portion d02 and the connecting portion d02b may be connected with the hook-up wiring (the hook-up wiring W0 described later), and the connecting portion d02b may be connected to the via-contact electrode CS2.

For example, in the above-described path RT6, one connecting portion d32 of the wiring layer D3 and another connecting portion d32 at the position at the X-direction positive side with respect to the one connecting portion d32 are connected with the hook-up wiring (the hook-up wiring W3 described later). The connecting portion d32 is connected to the connecting portion d22 via the via-contact electrode C32, the connecting portion d22 is connected to the connecting portion d12 via the via-contact electrode C22, and the connecting portion d12 is connected to the connecting portion d02 via the via-contact electrode C12. The connecting portion d02 and the connecting portion d02b may be connected with the hook-up wiring (the hook-up wiring W0 described later), and the connecting portion d02b may be connected to the via-contact electrode CS2.

For example, in the above-described path RT6, the connecting portion d22 of the wiring layer D2 is connected to the connecting portion d12 via the via-contact electrode C22, the connecting portion d12 and the connecting portion d12b are connected with the hook-up wiring (the hook-up wiring W1 described later), and the connecting portion d12b is connected to the connecting portion d02b via the via-contact electrode C12. The connecting portion d02b may be connected to the via-contact electrode CS2.

The bit lines BL disposed at the wiring layer M0 below the drain-side select gate line SGD in the memory hole region R_{MH} are connected to the semiconductor layers 120 formed at the memory holes and the sense amplifier module SAM included in the column control circuit region R_{CC}. As illustrated in FIG. 16, the region including these bit lines BL overlaps with a part of the row control circuit region R_{RC} when viewed in the Z-direction.

FIG. 17 is a schematic cross-sectional view illustrating structures of the word line switches WLSW, connecting portions, and via-contact electrodes. FIG. 17 is a cross-sectional view taken along the line C-C′ illustrated in FIG. 15 including the wiring layers D4 to D0 of the upper layer of FIG. 15 when viewed along the arrow direction.

As illustrated in FIG. 17, in the semiconductor substrate 200, the semiconductor region 203 constituting the three word line switches WLSW (2), WLSW (1), WLSW (2) is formed from a Y-direction positive side to a Y-direction negative side. The three electrodes gc extending in the X-direction are disposed on the upper surfaces of the semiconductor regions 203. The electrode gc includes a gate insulating layer 204 disposed on the upper surface of the semiconductor region 203, the gate electrode 206 disposed on the upper surface of the gate insulating layer 204, and gate insulating films 205 disposed on both side surfaces in the Y-direction of the gate insulating layer 204 and the gate electrode 206.

The gate insulating layer 204, for example, may contain at least one of silicon oxide (SiO₂) and silicon nitride (SiN) or may include an insulating metal oxide film of aluminum oxide (AlO), hafnium oxide (HfO), or the like. The gate electrode 206, for example, may contain a metal, such as polycrystalline silicon (Si) containing N-type or P-type impurities and tungsten (W), silicide, such as nickel silicide (NiSi), nickel platinum silicide (NiPtSi), cobalt silicide (CoSi), and tungsten silicide (WSi), a stacked film combining two or more among these, or the like. The gate insulating film 205, for example, may contain at least one of silicon oxide (SiO₂) and silicon nitride (SiN).

A source region R_{SO} of the semiconductor region 203 is a region between the two electrodes gc having the semiconductor region 203 in common. Drain regions R_{DR} Of the semiconductor region 203 are regions between the insulating regions STI disposed between the semiconductor regions 203 and the respective electrodes gc.

Via-contact electrodes C41, C31, C21, C11, CS1 and the connecting portions d31, d21, d11, d01 are via-contact electrodes and connecting portions for connecting the wiring CGI and the source region R_{SO} of the semiconductor region 203. The via-contact electrodes C41, C31, C21, C11, CS1 and the connecting portions d31, d21, d11, d01 for connecting the wiring CGI are disposed in a first region R_{CGI} overlapping with the region that goes across the plurality of source regions R_{SO} arranged in the X-direction when viewed in the Z-direction.

As illustrated in FIG. 17, the wiring CGI extends in the Y-direction in the wiring layer D4. The via-contact electrode C41 has an upper end connected to the wiring CGI and a lower end connected to the connecting portion d31 of the wiring layer D3. In FIG. 17, since the positions in the X-direction of the wiring CGI and the via-contact electrode C41 are displaced from the connecting portion d31, the via-contact electrode C31, and the like, the wiring CGI and the via-contact electrode C41 are indicated by the dotted lines. The via-contact electrode C31 has an upper end connected to the connecting portion d31 and a lower end connected to the connecting portion d21 of the wiring layer D2. The via-contact electrode C21 has an upper end connected to the connecting portion d21 and a lower end connected to the connecting portion d11 of the wiring layer D1. The via-contact electrode C11 has an upper end connected to the connecting portion d11 and a lower end connected to the connecting portion d01 of the wiring layer D0. The via-contact electrode CS1 has an upper end connected to the connecting portion d01 and a lower end connected to the source region R_{SO} of the semiconductor region 203.

Thus, the via-contact electrodes C41, C31, C21, C11, CS1 and the connecting portions d31, d21, d11, d01 are connected immediately below or approximately immediately below from the wiring CGI to the source region R_{SO} of the semiconductor region 203.

Via-contact electrodes C42, C32, C22 (C22b), C12 (C12b), CS2 and the connecting portions d42, d32, d22 (d22b (not illustrated)), d12 (d12b), d02 (d02b) are via-contact electrodes and connecting portions for connecting the bonding electrodes P_{I2} and the drain regions R_{DR} of the semiconductor region 203. The via-contact electrodes C42, C32, C22, C12 and the connecting portions d42, d32, d22, d12, d02 for connecting the bonding electrodes P_{I2} are disposed in a pair of second regions R_{WLHU1} at the proximity of the first region R_{CGI} overlapping with the source region R_{SO} of the semiconductor region 203 when viewed in the Z-direction. The second regions R_{WLHU1} are regions close to the first region R_{CGI} on both sides in the Y-direction. Although not illustrated, the second regions R_{WLHU1} may be regions close to the first region R_{CGI} on both sides in the X-direction. In the example of FIG. 17, the via-contact electrode C12 is not disposed. FIG. 16 and the like illustrate the via-contact electrode C12. The via-contact electrodes C12b, CS2 and the connecting portions d12b, d02b for connecting the bonding electrodes P_{I2} are disposed in a third region R_{WLHU2} overlapping with a pair of drain regions R_{DR} of the semiconductor region 203 when viewed in the Z-direction.

In the wiring layer D0, between the connecting portion d02 and the connecting portion d02b, the hook-up wirings W0 connecting both connecting portions are disposed. In the wiring layer D1, between the connecting portion d12 and the connecting portion d12b, the hook-up wirings W1 connecting both connecting portions are disposed. In the wiring layer D2, between the connecting portion d22 and the connecting portion d22b (not illustrated), the hook-up wirings W2 each connecting the connecting portion d22 to the connecting portion d22b are disposed. Between the connecting portion d22b and the connecting portion d22b, a pair of shield wirings s2 is disposed. Between the shield wirings s2, passing wirings TW2 are disposed. In the wiring layer D3, between the connecting portion d32 and the connecting portion d32, a pair of shield wirings s3 is disposed. Between the shield wirings s3, passing wirings TW3 are disposed. Between the shield wiring s3 and the connecting portion d32 and between the shield wiring s2 and the connecting portion d22b, hook-up wirings W3 connecting the connecting portion d32 to the connecting portion d32 and hook-up wirings W2 connecting the connecting portion d22 to the connecting portion d22b may be disposed, respectively.

As illustrated in FIG. 17, the bonding electrode P_{I2} of the chip bonding electrode layer DB is connected to the connecting portion d42 of the wiring layer D4. In FIG. 17, while the positions in the X-direction of the bonding electrode P_{I2} and the connecting portion d42 and the like are matched, the positions in the X-direction may be displaced. The via-contact electrode C42 has an upper end connected to the connecting portion d42 and a lower end connected to the connecting portion d32 of the wiring layer D3. The via-contact electrode C32 has an upper end connected to the connecting portion d32 and a lower end connected to the connecting portion d22 of the wiring layer D2. The via-contact electrode C22 has an upper end connected to the connecting portion d22 and a lower end connected to the connecting portion d12 of the wiring layer D1. The connecting portion d12 and the connecting portion d12b of the wiring layer D1 are connected by the hook-up wirings W1 in FIG. 17. The via-contact electrode C12b has an upper end connected to the connecting portion d12b and a lower end connected to the connecting portion d02b of the wiring layer D0. The via-contact electrode CS2 has an upper end connected to the connecting portion d02b and a lower end connected to the drain region R_{DR} of the semiconductor region 203.

In FIG. 17, the connecting portion d12 and the connecting portion d12b of the wiring layer D1 are connected by the hook-up wirings W1. In this case, the via-contact electrode C12 is not disposed. The connecting portion d02 of the wiring layer D0 is a dummy connecting portion (wiring) not electrically connected to the connecting portion d12 of the wiring layer D1. That is, the connecting portion d02 is electrically insulated and floating. From the aspect of lithography, the dummy connecting portion d02 is formed in the wiring layer D0. Additionally, to reduce a risk of short circuit with an adjacent wiring caused by an influence from dust, the connecting portion d02 is unconnected to the connecting portion d12. However, there may be a case where the connecting portion d02 and the connecting portion d02b of the wiring layer D0 are connected by the hook-up wirings W0. In this case, the via-contact electrode C12 is disposed, but the via-contact electrode C12b is not disposed. In this case as well, since the via-contact electrode C12b is not disposed, the connecting portion d12b of the wiring layer D1 is a dummy connecting portion (wiring) not electrically connected to the connecting portion d02b of the wiring layer D0. That is, in this case, the connecting portion d12b is electrically insulated and becomes floating.

Thus, using the via-contact electrodes and the connecting portions disposed in the second regions R_{WLHU1} and the via-contact electrodes and the connecting portions disposed in the third regions R_{WLHU2}, the bonding electrodes P_{I2} and the drain regions R_{DR} of the semiconductor region 203 are connected. In this case, the connecting portions d12 of the second regions R_{WLHU1} and the connecting portions d12b of the third regions R_{WLHU2} are connected by the hook-up wirings W1 of the wiring layer D1. Alternatively, the connecting portions d02 of the second regions R_{WLHU1} and the connecting portions d02b of the third regions R_{WLHU2} are connected by the hook-up wirings W0 of the wiring layer D0.

Note that in FIG. 17, the connecting portion d42 of the wiring layer D4 corresponds to the connecting portion d4 in FIG. 7 and FIG. 8. The connecting portions d31, d32 of the wiring layer D3 correspond to the connecting portions d3 in FIG. 7 and FIG. 8. The connecting portions d21, d22 (d22b) of the wiring layer D2 correspond to the connecting portions d2 in FIG. 7 and FIG. 8. The connecting portions d11, d12 (d12b) of the wiring layer D1 correspond to the connecting portions d1 in FIG. 7 and FIG. 8. The connecting portions d01, d02 (d02b) of the wiring layer D0 correspond to the connecting portions do in FIG. 7 and FIG. 8.

### [Position of Bonding Electrode P_{I2} in Chip Bonding Electrode Layer DB]

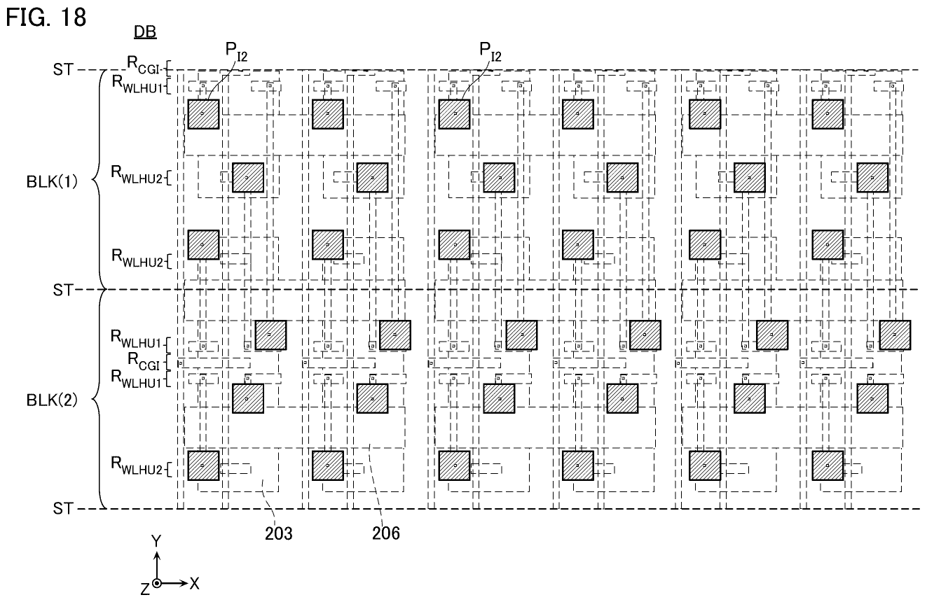

FIG. 18 is a schematic plan view illustrating the positions of the bonding electrodes P_{I2} in the hook-up region R_{HU}. FIG. 18 indicates the semiconductor regions 203 and the gate electrodes 206 by the dotted lines. FIG. 18 illustrates the hook-up region R_{HU} at the X-direction negative side in the region MP′ (the upper region corresponding to the region indicated by D in FIG. 15).

As illustrated in FIG. 18, a plurality of the bonding electrodes P_{I2} are arranged in the X-direction and the Y-direction at predetermined intervals. The arrangement pattern of the bonding electrode P_{I2} may be an arrangement in the X-direction and the Y-direction at regular intervals, or may be an unequally spaced arrangement in consideration of drawing of connecting wirings with the via-contact electrodes CC. In this example, three bonding electrodes P_{I2} are assigned per width in the X-direction of one word line switch WLSW and per width in the Y-direction of one memory block BLK. Three bonding electrode P_{I2} are disposed at positions different in the Y-direction.

### [Positions of Wiring CGI and Connecting Portion d42 in Wiring Layer D4]

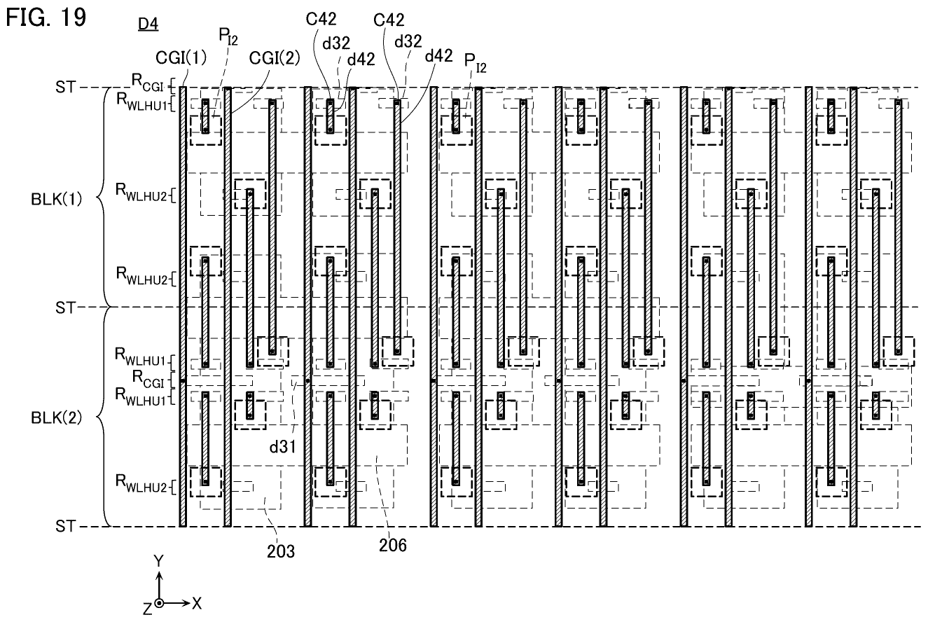

FIG. 19 is a schematic plan view illustrating the positions of the wiring CGI and the connecting portion d42 disposed at the wiring layer D4. FIG. 19 indicates the semiconductor regions 203 and the gate electrodes 206 by the dotted lines. FIG. 19 indicates the positions of the bonding electrodes P_{I2} illustrated in FIG. 18 by the dotted lines. FIG. 19 illustrates the hook-up region R_{HU} at the X-direction negative side in the region MP′ (the upper region corresponding to the region indicated by D in FIG. 15).

As illustrated in FIG. 19, two wirings CGI extending in the Y-direction are arranged for one word line switch WLSW. In the two wirings CGI, the wiring at the X-direction negative side is referred to as a wiring CGI (1), and the wiring at the X-direction positive side is referred to as a wiring CGI (2). At a space between the wirings CGI (1), CGI (2), one or two connecting portions d42 extending in the Y-direction are disposed. The connecting portion d42 has one end portion disposed immediately below the bonding electrode P_{I2}, and the other end portion connected to the connecting portion d32 disposed in the second region R_{WLHU1} of the wiring layer D3 via the via-contact electrode C42.

[Positions of Connecting Portions d31, d32 of Wiring Layer D3 and Wiring Pattern in Wiring Layer D3]

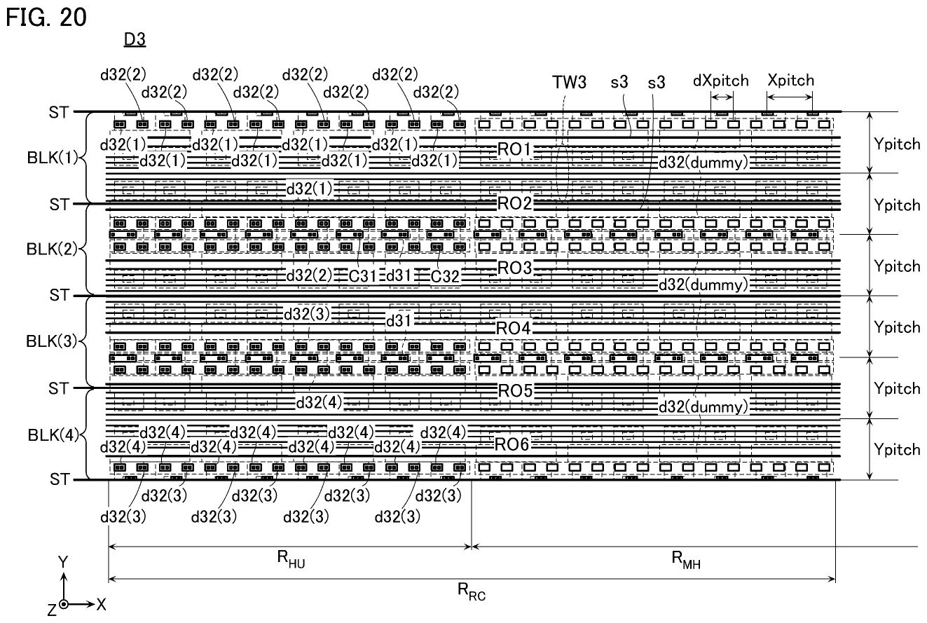

FIG. 20 is a schematic plan view illustrating an example of a wiring pattern in the wiring layer D3. FIG. 20 indicates the semiconductor regions 203 and the gate electrodes 206 by the dotted lines. In FIG. 20, among the connecting portions d31, d32, the connecting portions d31, d32 with notations of the via-contact electrodes C31, C32 indicate that the via-contact electrodes C31, C32 are connected to lower sides thereof, and the connecting portions d31, d32 without notations of the via-contact electrodes C31, C32 indicate that the via-contact electrodes C31, C32 are not connected to lower sides thereof. In FIG. 20, a pitch in the X-direction of the word line switches WLSW is denoted as Xpitch and a pitch in the Y-direction of the word line switches WLSW is denoted as Ypitch. FIG. 20 illustrates a region corresponding to the region illustrated in FIG. 15.

As illustrated in FIG. 20, one connecting portion d31 is disposed per pitch Xpitch in the X-direction of one word line switch WLSW, and the connecting portions d31 are arranged in the X-direction. That is, the connecting portions d31 are arranged at regular intervals or predetermined intervals at every Xpitch. The connecting portion d31 is disposed in the first region R_{CGI} overlapping with the source region R_{SO} of the semiconductor region 203. The connecting portion d31 is connected to the wiring CGI via the via-contact electrode C41.

Two connecting portions d32 are disposed to be arranged in the X-direction per pitch Xpitch in the X-direction of one word line switch WLSW. That is, the connecting portions d32 are arranged at regular intervals or predetermined intervals, such as a pitch dXpitch that is ½ of the Xpitch, by two at every Xpitch. The connecting portions d32 are disposed in the second regions R_{WLHU1} disposed on both sides in the Y-direction with respect to the first region R_{CGI}.

The 16 connecting portions d32 disposed in the hook-up region R_{HU} are active connecting portions connected to the via-contact electrodes CC at the memory cell array MCA side, and are referred to as “word line hook-up pads” in some cases. Among these connecting portions d32, connecting portions d32 (1) are connected to the hook-up wirings W0 to W3 of the memory block BLK (1), connecting portions d32 (2) are connected to the hook-up wirings W0 to W3 of the memory block BLK (2), connecting portions d32 (3) are connected to the hook-up wirings W0 to W3 of the memory block BLK (3), and connecting portions d32 (4) are connected to the hook-up wirings W0 to W3 of the memory block BLK (4). The connecting portion d32 is connected to the connecting portion d42 via the via-contact electrode C42, connected to the connecting portion d22 via the via-contact electrode C32, or not connected anywhere. The connecting portions d32 (1), d32 (2) of the first row RO1 in the region of the memory block BLK (1) are alternately disposed in the X-direction one by one. The connecting portions d32 (3), d32 (4) of a sixth row RO6 in the region of the memory block BLK (4) are alternately disposed in the X-direction one by one. The connecting portions d32 (1) in the second row RO2 and the connecting portions d32 (2) in the third row RO3 disposed in the region of the memory block BLK (2) are each arranged consecutively in the X-direction. The connecting portions d32 (3) in a fourth row RO4 and the connecting portions d32 (4) of a fifth row RO5 disposed in the region of the memory block BLK (3) are each arranged consecutively in the X-direction. In this embodiment, in FIG. 18 and FIG. 19, the bonding electrode P_{I2}, the connecting portion d42, and the wirings CGI (1), CGI (2) are disposed in a repeating pattern in a unit of the width in the X-direction of the word line switch WLSW. However, the bonding electrode P_{I2}, the connecting portion d42, and the wirings CGI (1), CGI (2) may be disposed in a line symmetry pattern (mirror pattern) in a unit of the width in the X-direction of the word line switch WLSW. In this case, the connecting portions d32 (1), d32 (2) of the first row RO1 in the region of the memory block BLK (1) are arranged, for example, in the order of d32 (1), d32 (2), d32 (2), d32 (1), d32 (1), d32 (2), d32 (2), . . . .

The 16 connecting portions d32 (dummy) disposed in the row control circuit region R_{RC} at an outside (X-direction positive side) of the hook-up region R_{HU} are dummy connecting portions in a floating state not connected anywhere. However, these connecting portions d32 (dummy) may be connected to the via-contact electrodes C42 in the lower layer thereof. Note that the connecting portions d22, d12, d02 disposed in the lower side in the Z-direction of the connecting portions d32 (dummy) are also dummies.

As illustrated in FIG. 20, a pair of the shield wirings s3 extending in the X-direction is disposed between the connecting portions d32 (1), d32 (2) of the first row RO1 in the region of the memory block BLK (1) and the connecting portions d32 (1) of the second row RO2 in a boundary region of the memory blocks BLK (1), BLK (2), between the connecting portions d32 (2) of the third row RO3 in the region of the memory block BLK (2) and the connecting portions d32 (3) of the fourth row RO4 in the region of the memory block BLK (3), and between the connecting portions d32 (4) of the fifth row RO5 in a boundary region of the memory blocks BLK (3), BLK (4) and the connecting portions d32 (3), d32 (4) of the sixth row RO6 in the region of the memory block BLK (4). Between the pair of the shield wirings s3, a plurality of the passing wirings TW3 are disposed. The plurality of passing wirings TW3 extend in the X-direction, and are arranged in the Y-direction.

Although omitted in FIG. 20, a plurality of the hook-up wirings W3 may be disposed between the plurality of connecting portions d32 and the shield wiring s3. The plurality of hook-up wirings W3 extend in the X-direction, and are arranged in the Y-direction. The hook-up wiring W3 connects one connecting portion d32 to another connecting portion d32 at a position different in the X-direction from that of the one connecting portion d32. For example, the hook-up wiring W3 connects one connecting portion d32 to another connecting portion d32 at a position in the X-direction positive side with respect to the one connecting portion d32.

The connecting portion d32 is connected to the connecting portion d42 of the wiring layer D4 via the via-contact electrode C42, connected to the connecting portion d22 of the wiring layer D2 via the via-contact electrode C32, or not connected to any of them depending on the wiring pattern.

The wiring pattern formed in the region corresponding to the memory blocks BLK (1), BLK (2) and the wiring pattern formed in the region corresponding to the memory blocks BLK (3), BLK (4) are line-symmetrical with respect to a line corresponding to the inter-block insulating layer ST at the center in the Y-direction in the drawing.

While the wiring region in which the passing wiring TW3 is disposed is provided in the example of FIG. 20, the wiring region is not necessarily disposed. In this case, the wiring region of the hook-up wiring W3 can be enlarged by the area of the omitted wiring region.

The shield wiring s3 is a wiring for shielding the hook-up wiring W3 from the passing wiring TW3. In the read operation, the write operation, the erase operation, and the like, while a high voltage, such as a read pass voltage V_{READ}, a write voltage V_{PGM}, and an erase voltage V_{ERA}, iS applied to the hook-up wiring W3, a comparatively low voltage at around from the ground voltage V_{SS} to the power supply voltage V_{CC} is applied to most of the passing wirings TW3. In the wiring adjacent to the wiring to which a high voltage has been applied, the voltage easily increases unintentionally due to a capacitive coupling. To reduce the voltage fluctuation of the passing wiring TW3, the shield wiring s3 is disposed between a wiring region Rw3 and a passing wiring region Rrw3, and shields the hook-up wiring W3 from the passing wiring TW3. For example, the ground voltage V_{SS} is applied to the shield wiring s3. However, a voltage V_{DD} generated by the voltage generation circuit VG may be applied to the shield wiring s3. In this case, the voltage V_{DD} may be used as a power supply voltage of a predetermined wiring.

[Positions of Connecting Portions d21, d22 of Wiring Layer D2 and Wiring Pattern in Wiring Layer D2]

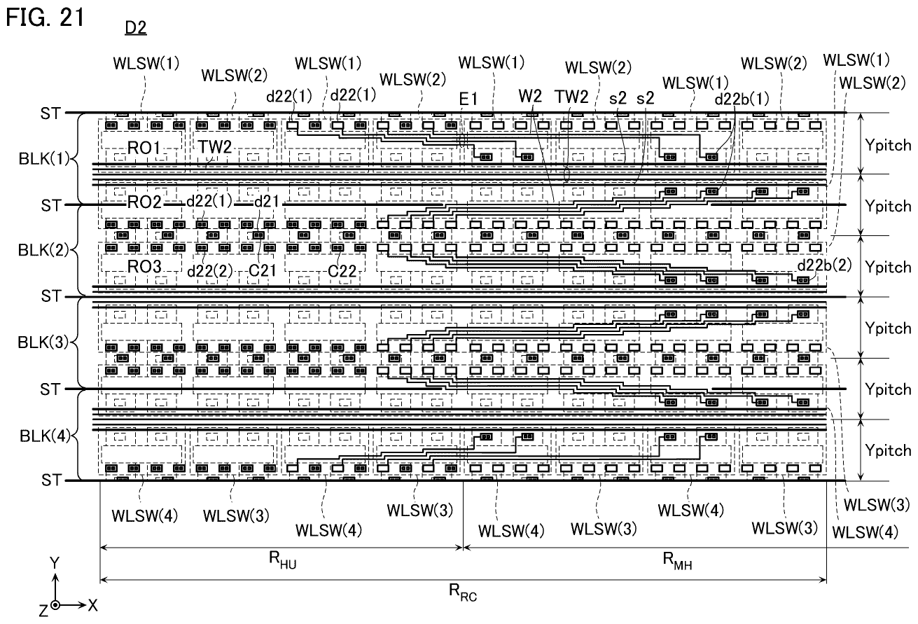

FIG. 21 is a schematic plan view illustrating an example of a wiring pattern in the wiring layer D2. In FIG. 21, among the connecting portions d21, d22, d22b, the connecting portions d21, d22, d22b with notations of the via-contact electrodes C21, C22 indicate that the via-contact electrodes C21, C22 are connected to lower sides thereof, and the connecting portions d21, d22, d22b without notations of the via-contact electrodes C21, C22 indicate that the via-contact electrodes C21, C22 are not connected to lower sides thereof. In FIG. 21, a pitch in the Y-direction of the word line switches WLSW is denoted as Ypitch. FIG. 21 illustrates a region corresponding to the region illustrated in FIG. 15.

As illustrated in FIG. 21, among the 32 connecting portions d22 disposed at the first row RO1 in the region of the memory block BLK (1), the 16 connecting portions d22 disposed on the X-direction positive side are dummy connecting portions d22 disposed on the lower side in the Z-direction of the dummy connecting portions d32 (dummy) of the wiring layer D3. The other 16 connecting portions d22 (1), d22 (2) disposed in the hook-up region R_{HU} are connected to the connecting portions d32 (1), d32 (2) disposed at the first row RO1 in the region of the memory block BLK (1) of the wiring layer D3 via the via-contact electrodes C32, and are alternately disposed in the X-direction. A part of these 16 connecting portions d22 (1), d22 (2), in this example, the four connecting portions d22 (1) of 9-th, 11-th, 13-th, and 15-th ones counted from the X-direction negative side are connected to one ends of the hook-up wirings W2. The other ends of the hook-up wirings W2 are connected to the connecting portions d22b (1) disposed in the drain regions R_{DR} of the four word line switches WLSW (1) of 9-th, 10-th, 13-th, 14-th ones counted from the X-direction negative side among the 16 word line switches WLSW (1), WLSW (2) disposed on the Y-direction positive side in the region of the memory block BLK (1). The hook-up wiring W2 includes a part extending from the connecting portion d22 (1) to the Y-direction negative side, a part extending in the X-direction, a part extending in the Y-direction negative side toward the connecting portion d22b (1), and the like, thus being formed, for example, in a staircase pattern. The hook-up wirings W2 include a first part E1 densest in the Y-direction at a part overlapping with the row control circuit region R_{RC} at an end portion on the X-direction positive side of the hook-up region R_{HU}, that is, a boundary portion between the hook-up region R_{HU} and the memory hole region R_{MH} (boundary portion between the hook-up region R_{HU} and a region of the row control circuit region R_{RC} excluding the hook-up region R_{HU}).

Among the 32 connecting portions d22 disposed at the second row RO2 in the boundary region between the memory blocks BLK (1) and BLK (2), the 16 connecting portions d22 disposed on the X-direction positive side are dummy connecting portions d22 disposed on the lower side in the Z-direction of the dummy connecting portions d32 (dummy) of the wiring layer D3. The other 16 connecting portions d22 (1) disposed in the hook-up region R_{HU} are connected to the connecting portions d32 (1) disposed at the second row RO2 in the boundary region between the memory blocks BLK (1) and BLK (2) of the wiring layer D3 via the via-contact electrodes C32. A part of these 16 connecting portions d22 (1), in this example, the four connecting portions d22 (1) of 13-th to 16-th ones counted from the X-direction negative side are connected to one ends of the hook-up wirings W2. The other ends of the hook-up wirings W2 are connected to the connecting portions d22b (1) disposed in the drain regions R_{DR} of the four word line switches WLSW (1) of 13-th to 16-th ones counted from the X-direction negative side among the 16 word line switches WLSW (1) disposed at the second row RO2 in the boundary region between the memory blocks BLK (1) and BLK (2). The hook-up wiring W2 includes a part extending from the connecting portion d22 (1) to the Y-direction positive side, a part extending in the X-direction, a part extending in the Y-direction positive side toward the connecting portion d22b (1), and the like, thus being formed, for example, in a staircase pattern.

Among the 32 connecting portions d22 disposed at the third row RO3 in the region of the memory block BLK (2), the 16 connecting portions d22 disposed on the X-direction positive side are dummy connecting portions d22 disposed on the lower side in the Z-direction of the dummy connecting portions d32 (dummy) of the wiring layer D3. The other 16 connecting portions d22 (2) disposed in the hook-up region R_{HU} are connected to the connecting portions d32 (2) disposed at the third row RO3 in the region of the memory block BLK (2) of the wiring layer D3 via the via-contact electrodes C32. A part of these 16 connecting portions d22 (2), in this example, the four connecting portions d22 (2) of 13-th to 16-th ones counted from the X-direction negative side are connected to one ends of the hook-up wirings W2. The other ends of the hook-up wirings W2 are connected to the connecting portions d22b (2) disposed in the drain regions R_{DR} of the four word line switches WLSW (2) of 13-th to 16-th ones counted from the X-direction negative side among the 16 word line switches WLSW (2) disposed on the Y-direction negative side in the region of the memory block BLK (2). The hook-up wiring W2 includes a part extending from the connecting portion d22 (2) to the Y-direction negative side, a part extending in the X-direction, a part extending in the Y-direction negative side toward the connecting portion d22b (2), and the like, thus being formed, for example, in a staircase pattern.

As illustrated in FIG. 21, at each of the wiring spaces in the side where the hook-up wirings W2 are not disposed between the connecting portions d22b in the respective rows, a pair of the shield wirings s2 extending in the X-direction is disposed. Between the pair of shield wirings s2, a plurality of the passing wirings TW2 are disposed. The plurality of passing wirings TW2 extend in the X-direction, and are arranged in the Y-direction.

The wiring pattern formed in the region corresponding to the memory blocks BLK (1), BLK (2) and the wiring pattern formed in the region corresponding to the memory blocks BLK (3), BLK (4) are line-symmetrical with respect to a line corresponding to the inter-block insulating layer ST at the center in the Y-direction in the drawing.

[Positions of Connecting Portions d11, d12, d12b of Wiring Layer D1 and Wiring Pattern in Wiring Layer D1]

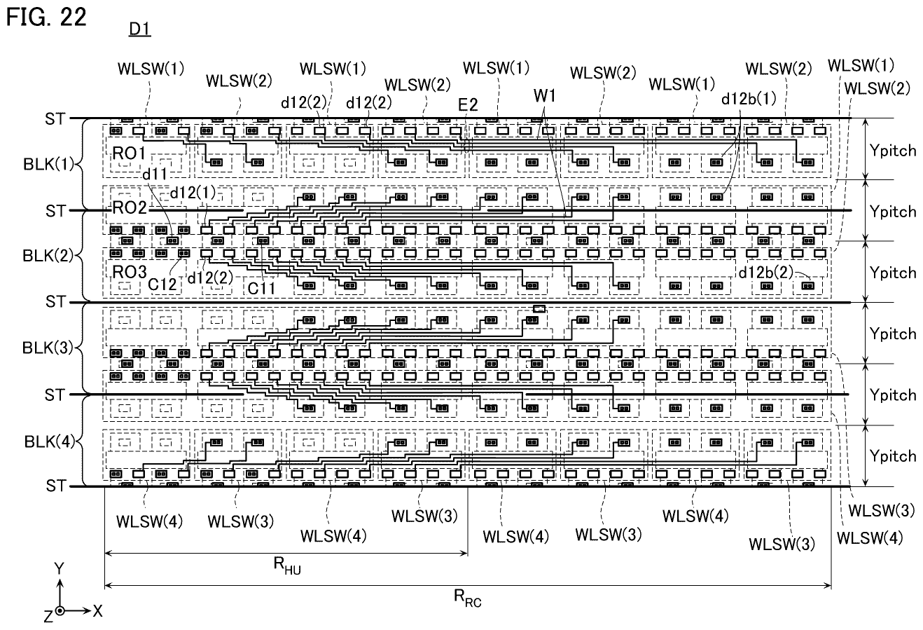

FIG. 22 is a schematic plan view illustrating an example of a wiring pattern in the wiring layer D1. In FIG. 22, among the connecting portions d11, d12, d12b, the connecting portions d11, d12, d12b with notations of the via-contact electrodes C11, C12 indicate that the via-contact electrodes C11, C12 are connected to lower sides thereof, and the connecting portions d11, d12, d12b without notations of the via-contact electrodes C11, C12 indicate that the via-contact electrodes C11, C12 are not connected to lower sides thereof. In FIG. 22, a pitch in the Y-direction of the word line switches WLSW is denoted as Ypitch. FIG. 22 illustrates a region corresponding to the region illustrated in FIG. 15.

As illustrated in FIG. 22, among the 32 connecting portions d12 disposed at the first row RO1 in the region of the memory block BLK (1), the 16 connecting portions d12 disposed on the X-direction positive side are dummy connecting portions d12 disposed on the lower side in the Z-direction of the dummy connecting portions d32 (dummy) of the wiring layer D3. Among the other 16 connecting portions d12 (1), d12 (2) disposed in the hook-up region R_{HU}, the connecting portions d12 (1) overlapping with the connecting portions d22 (1), which are 9-th, 11-th, 13-th, and 15-th ones counted from the X-direction negative side and already connected to the hook-up wirings W2 in the wiring layer D2, in the Z-direction are dummies not connected anywhere. The remaining 12 connecting portions d12 (1), d12 (2) are connected to the connecting portions d22 (1), d22 (2) disposed at the first row RO1 in the region of the memory block BLK (1) of the wiring layer D2 via the via-contact electrodes C22, and are alternately disposed in the X-direction. In this wiring layer D1, among the 16 connecting portions d12 (1), d12 (2), the even-numbered 8 connecting portions d12 (2) in the 2nd to 16-th ones counted from the X-direction negative side, that is, all the connecting portions d12 (2) disposed at this row are connected to one ends of the hook-up wirings W1. The other ends of the hook-up wirings W1 are connected to the connecting portions d12b (2) disposed in the drain regions R_{DR} of all of the 8 word line switches WLSW (2) of 3rd, 4-th, 7-th, 8-th, 11-th, 12-th, 15-th, and 16-th ones counted from the X-direction negative side among the 16 word line switches WLSW (1), WLSW (2) disposed at the first row RO1 in the region of the memory block BLK (1). The hook-up wiring W1 includes a part extending from the connecting portion d12 (2) to the Y-direction negative side, a part extending in the X-direction, a part extending in the Y-direction negative side toward the connecting portion d12b (2), and the like, thus being formed, for example, in a staircase pattern. The hook-up wirings W1 include a second part E2 densest in the Y-direction at a part overlapping with the row control circuit region R_{RC} at an end portion on the X-direction positive side of the hook-up region R_{HU}, that is, a boundary portion between the hook-up region R_{HU} and the memory hole region R_{MH}.

Among the 32 connecting portions d12 disposed at the second row RO2 in the boundary region between the memory blocks BLK (1) and BLK (2), the 16 connecting portions d12 disposed on the X-direction positive side are dummy connecting portions d12 disposed at the lower side in the Z-direction of the dummy connecting portions d32 (dummy) of the wiring layer D3. Among the other 16 connecting portions d12 (1) disposed in the hook-up region R_{HU}, the connecting portions d12 (1) overlapping with the connecting portions d22 (1), which are 13-th to 16-th ones counted from the X-direction positive side and already connected to the hook-up wirings W2 in the wiring layer D2, in the Z-direction are dummies not connected anywhere. The remaining 12 connecting portions d12 (1) are connected to the connecting portions d22 (1) disposed at the second row RO2 of the wiring layer D2 via the via-contact electrodes C22. A part of these 12 connecting portions d12 (1), in this example, the 8 connecting portions d12 (1) of 5-th to 12-th ones counted from the X-direction negative side are connected to one ends of the hook-up wirings W1. The other ends of the hook-up wirings W1 are connected to the connecting portions d12b (1) disposed in the drain regions R_{DR} of the 5-th to 12-th word line switches WLSW (1) counted from the X-direction negative side disposed at the second row RO2 in the Y-direction in the region of the memory block BLK (1). The hook-up wiring W1 includes a part extending from the connecting portion d12 (1) to the Y-direction positive side, a part extending in the X-direction, a part extending in the Y-direction positive side toward the connecting portion d12b (1), and the like, thus being formed, for example, in a staircase pattern.

Among the 32 connecting portions d12 disposed at the third row RO3 in the region of the memory block BLK (2), the 16 connecting portions d12 disposed on the X-direction positive side are dummy connecting portions d12 disposed at the lower side in the Z-direction of the dummy connecting portions d32 (dummy) of the wiring layer D3. Among the other 16 connecting portions d12 (2) disposed in the hook-up region Rwu, the connecting portions d12 (2) overlapping with the connecting portions d22 (2), which are 13-th to 16-th ones counted from the X-direction positive side and already connected to the hook-up wirings W2 in the wiring layer D2, in the Z-direction are dummies not connected anywhere. The remaining 12 connecting portions d12 (2) are connected to the connecting portions d22 (2) disposed at the third row RO3 in the region of the memory block BLK (2) of the wiring layer D2 via the via-contact electrodes C22. A part of these 12 connecting portions d12 (2), in this example, the 8 connecting portions d12 (2) of 5-th to 12-th ones counted from the X-direction negative side are connected to one ends of the hook-up wirings W1. The other ends of the hook-up wirings W1 are connected to the connecting portions d12b (2) disposed in the drain regions R_{DR} of the 5-th to 12-th word line switches WLSW (2) counted from the X-direction negative side disposed at the third row RO3 in the region of the memory block BLK (2). The hook-up wiring W1 includes a part extending from the connecting portion d12 (2) to the Y-direction negative side, a part extending in the X-direction, a part extending in the Y-direction negative side toward the connecting portion d12b (2), and the like, thus being formed, for example, in a staircase pattern.

The wiring pattern formed in the region corresponding to the memory blocks BLK (1), BLK (2) and the wiring pattern formed in the region corresponding to the memory blocks BLK (3), BLK (4) are line-symmetrical with respect to a line corresponding to the inter-block insulating layer ST at the center in the Y-direction in the drawing.

[Positions of Connecting Portions d01, d02, d02b of Wiring Layer D0 and Wiring Pattern in Wiring Layer D0]

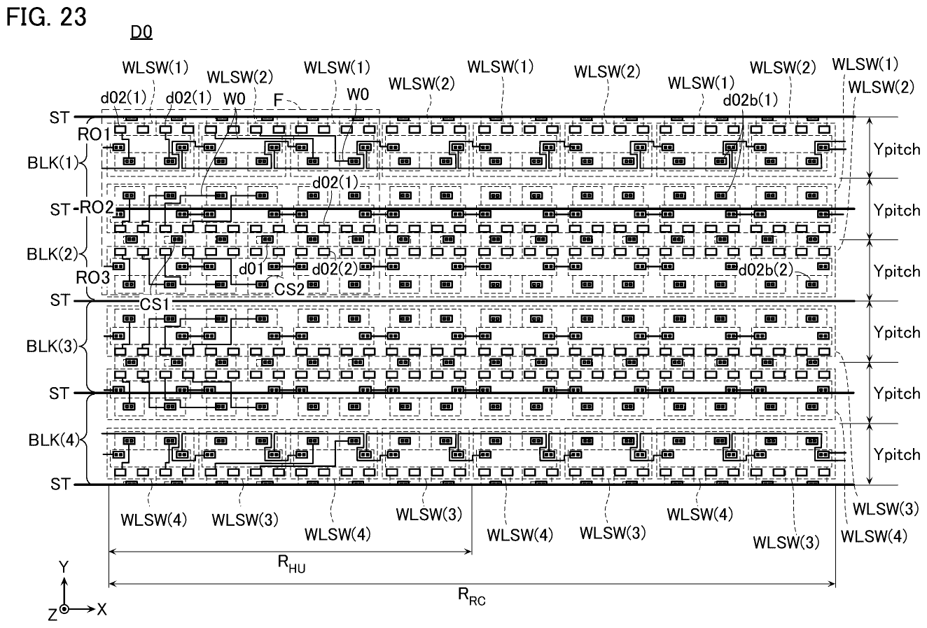

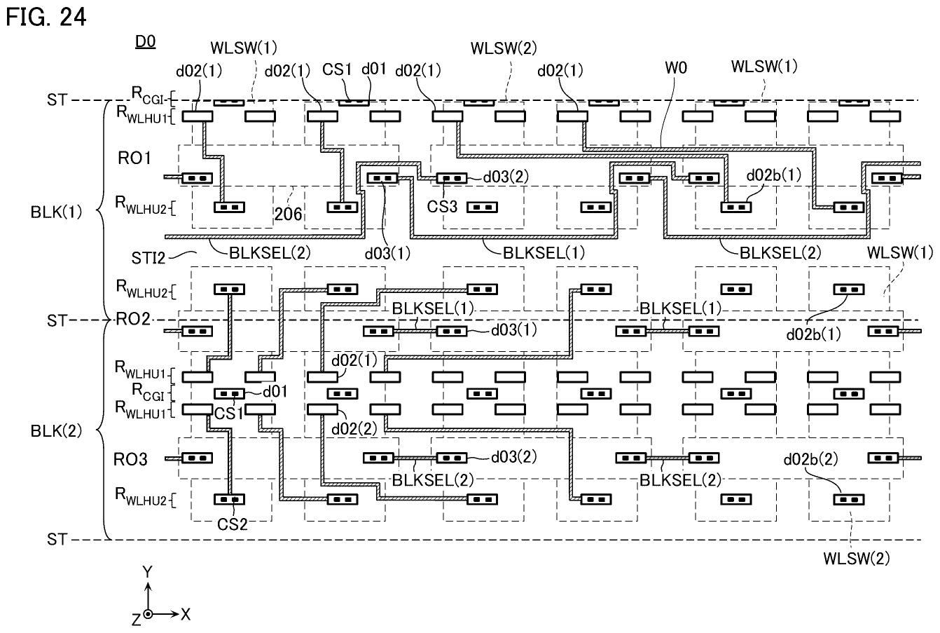

FIG. 23 is a schematic plan view illustrating an example of a wiring pattern in the wiring layer D0. FIG. 24 is an enlarged plan view of a region indicated by F in FIG. 23. In FIG. 23 and FIG. 24, among the connecting portions d01, d02b, d03, the connecting portions d01, d02b, d03 with notations of the via-contact electrodes CS1, CS2, CS3 indicate that the via-contact electrodes CS1, CS2, CS3 are connected to lower sides thereof, and the connecting portions d01, d02b without notations of the via-contact electrodes CS1, CS2 indicate that the via-contact electrodes CS1, CS2 are not connected to lower sides thereof. In FIG. 23, a pitch in the Y-direction of the word line switches WLSW is denoted as Ypitch. FIG. 23 illustrates a region corresponding to the region illustrated in FIG. 15.

As illustrated in FIG. 23 and FIG. 24, among the 32 connecting portions d02 disposed at the first row RO1 in the region of the memory block BLK (1), the 16 connecting portions d02 disposed on the X-direction positive side are dummy connecting portions d02 disposed at the lower side in the Z-direction of the dummy connecting portions d32 (dummy) of the wiring layer D3. Among the other 16 connecting portions d02 (1), d02 (2) disposed in the hook-up region R_{HU}, the connecting portions d02 (1), d02 (2) overlapping with the 9-th, 11-th, 13-th, and 15-th connecting portions d22 (1) counted from the X-direction negative side and the even-numbered connecting portion d12 (2) already connected to the hook-up wirings W2, W1 in the wiring layers D2, D1 in the Z-direction are dummies not connected anywhere. The remaining 1st, 3rd, 5-th, and 7-th connecting portions d02 (1) are connected to the connecting portions d12 (1) disposed at the first row RO1 of the wiring layer D1 via the via-contact electrodes C12, and are disposed in the X-direction. In this wiring layer D0, the remaining four connecting portions d02 (1) are connected to one ends of the hook-up wirings W0. The other ends of the hook-up wirings W0 are connected to the connecting portions d02b (1) disposed in the drain regions R_{DR} of the 1st, 2nd, 5-th, and 6-th word line switches WLSW (1) from the X-direction negative side among the 16 word line switches WLSW (1), WLSW (2) disposed at the first row RO1 in the region of the memory block BLK (1). The hook-up wiring W0 includes a part extending from the connecting portion d02 (1) to the Y-direction negative side, a part extending in the X-direction, a part extending in the Y-direction negative side toward the connecting portion d02b (1), and the like, thus being formed, for example, in a staircase pattern.

Among the 32 connecting portions d02 disposed at the second row RO2 in the boundary region between the memory blocks BLK (1) and BLK (2), the 16 connecting portions d02 disposed on the X-direction positive side are dummy connecting portions d02 disposed at the lower side in the Z-direction of the dummy connecting portions d32 (dummy) of the wiring layer D3. Among the other 16 connecting portions d02 (1) disposed in the hook-up region R_{HU}, the connecting portions d02 (1) overlapping with the connecting portions d22 (1), which are 13-th to 16-th ones counted from the X-direction negative side and already connected to the hook-up wirings W2 in the wiring layer D2, in the Z-direction are dummies not connected anywhere. Further, the connecting portions d02 (1) overlapping with the connecting portions d12 (1), which are 5-th to 12-th ones counted from the X-direction negative side and already connected to the hook-up wirings W1 in the wiring layer D1, in the Z-direction are dummies not connected anywhere. The remaining 1st to 4-th connecting portions d02 (1) are connected to the connecting portions d12 (1) disposed at the second row RO2 of the wiring layer D1 via the via-contact electrodes C12. These four connecting portions d02 (1) are connected to one ends of the hook-up wirings W0. The other ends of the hook-up wirings W0 are connected to the connecting portions d02b (1) disposed in the drain regions R_{DR} of the 1st to 4-th word line switches WLSW (1) counted from the X-direction negative side disposed at the second row RO2 in the region of the memory block BLK (1). The hook-up wiring W0 includes a part extending from the connecting portion d02 (1) to the Y-direction positive side, a part extending in the X-direction, a part extending in the Y-direction positive side toward the connecting portion d02b (1), and the like, thus being formed, for example, in a staircase pattern.

Among the 32 connecting portions d02 disposed at the third row RO3 in the region of the memory block BLK (2), the 16 connecting portions d02 disposed on the X-direction positive side are dummy connecting portions d02 disposed at the lower side in the Z-direction of the dummy connecting portions d32 (dummy) of the wiring layer D3. Among the other 16 connecting portions d02 (2) disposed in the hook-up region R_{HU}, the connecting portions d02 (2) overlapping with the connecting portions d22 (2), which are 13-th to 16-th ones counted from the X-direction negative side and already connected to the hook-up wirings W2 in the wiring layer D2, in the Z-direction are dummies not connected anywhere. Further, the connecting portions d02 (2) overlapping with the connecting portions d12 (2), which are 5-th to 12-th ones counted from the X-direction negative side and already connected to the hook-up wirings W1 in the wiring layer D1, in the Z-direction are dummies not connected anywhere. The remaining four connecting portions d02 (2) are connected to the connecting portions d12 (2) disposed at the third row RO3 of the wiring layer D1 via the via-contact electrodes C12. These four connecting portions d02 (2) are connected to one ends of the hook-up wirings W0. The other ends of the hook-up wirings W0 are connected to the connecting portions d02 (2) disposed in the drain regions R_{DR} of the 1st to 4-th word line switches WLSW (2) counted from the X-direction negative side disposed at the third row RO3 in the region of the memory block BLK (2). The hook-up wiring W0 includes a part extending from the connecting portion d02 (2) to the Y-direction negative side, a part extending in the X-direction, a part extending in the Y-direction negative side toward the connecting portion d02b (2), and the like, thus being formed, for example, in a staircase pattern.

As illustrated in FIG. 23 and FIG. 24, all of the connecting portions d01 are connected to the source regions R_{SO} of the word line switches WLSW (1) to WLSW (4) via the via-contact electrodes CS1. All of the connecting portions d02b are connected to the drain regions R_{DR} of the word line switches WLSW (1) to WLSW (4) via the via-contact electrodes CS2.

In the first row RO1 of the wiring layer D0, a pair of the word line switches WLSW (1) and a pair of the word line switches WLSW (2) are alternately arranged in the X-direction two by two. Therefore, as illustrated in FIG. 24, a signal line BLKSEL (1) that connects the gate electrodes 206 of the word line switches WLSW (1) alternate in the X-direction to one another, and the connecting portion d03 (1) and the via-contact electrode CS3 that connect the signal line BLKSEL (1) to the gate electrode 206 of the word line switch WLSW (1) are disposed. Further, a signal line BLKSEL (2) that connects the gate electrodes 206 of the word line switches WLSW (2) alternate in the X-direction to one another, and the connecting portion d03 (2) and the via-contact electrode CS3 that connect the signal line BLKSEL (2) to the gate electrode 206 of the word line switch WLSW (2) are disposed. Both of the signal lines BLKSEL (1), BLKSEL (2) are wired to detour to the insulating region STI2 side of the word line switches WLSW (1), WLSW (2) to surround the word line switches WLSW (1), WLSW (2) in the Y-direction negative side. The signal lines BLKSEL (1), BLKSEL (2) are open in the Y-direction positive side, and the wiring space of the hook-up wiring W0 is ensured.

In the second row RO2 of the wiring layer D0, pairs of the word line switches WLSW (1) are arranged consecutively in the X-direction. Therefore, a signal line BLKSEL (1) that connects the gate electrodes 206 of the word line switches WLSW (1) adjacent in the X-direction to one another, and the connecting portion d03 (1) and the via-contact electrode CS3 that connect the signal line BLKSEL (1) to the gate electrode 206 of the word line switch WLSW (1) are disposed. Note that all of the word line switches WLSW (1) in the second row RO2 may be connected by a single gate electrode 206 extending in the X-direction.

In the third row RO3 of the wiring layer D0, pairs of the word line switches WLSW (2) are arranged consecutively in the X-direction. Therefore, a signal line BLKSEL (2) that connects the gate electrodes 206 of the word line switches WLSW (2) adjacent in the X-direction to one another, and the connecting portion d03 (2) and the via-contact electrode CS3 that connect the signal line BLKSEL (2) to the gate electrode 206 of the word line switch WLSW (2) are disposed. Note that all of the word line switches WLSW (2) in the third row RO3 may be connected by a single gate electrode 206 extending in the X-direction.

The wiring pattern formed in the region corresponding to the memory blocks BLK (1), BLK (2) and the wiring pattern formed in the region corresponding to the memory blocks BLK (3), BLK (4) are line-symmetrical with respect to a line corresponding to the inter-block insulating layer ST at the center in the Y-direction in the drawing.

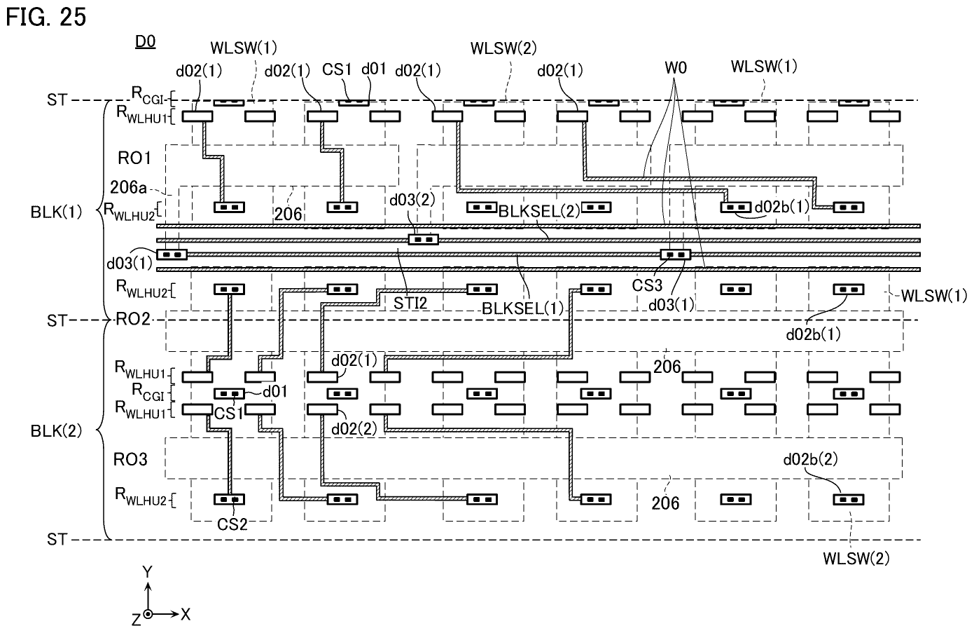

FIG. 25 is a plan view illustrating a modification of the wiring layer D0 illustrated in FIG. 24. In this modification, a signal line BLKSEL (1) and a signal line BLKSEL (2) extending in the X-direction are arranged in the Y-direction in the insulating region STI2 between the first row RO1 and the second row RO2 of the wiring layer D0. In the first row RO1 of the wiring layer D0, the gate electrode 206 of the word line switch WLSW (1) and the gate electrode 206 of the word line switch WLSW (2) alternately arranged in the X-direction include wiring portions 206a extending in the Y-direction toward the signal lines BLKSEL (1) and BLKSEL (2) at one end in the X-direction. The wiring portion 206a of the gate electrode 206 of the word line switch WLSW (1) extends to the signal line BLKSEL (1), and is connected to the signal line BLKSEL (1) via the connecting portion d03 (1) and the via-contact electrode CS3. The wiring portion 206a of the gate electrode 206 of the word line switch WLSW (2) extends to the signal line BLKSEL (2), and is connected to the signal line BLKSEL (2) via the connecting portion d03 (2) and the via-contact electrode CS3.

In the second row RO2 and the third row RO3 of the wiring layer D0, the gate electrode 206 is continuous in the X-direction, and the signal line BLKSEL (1) or the signal line BLKSEL (2) is not used. Other configurations are similar to the configurations illustrated in FIG. 24.

With the wiring layer D0 of this modification, the pattern of the signal lines BLKSEL (1) and BLKSEL (2) is more simplified than that in the wiring layer D0 illustrated in FIG. 24. This allows widening the region in which the hook-up wiring W0 can be disposed, and the larger number of the hook-up wirings W0 can be disposed. The hook-up wirings W0 are, for example, disposed to be adjacent to the signal line BLKSEL (1) and the signal line BLKSEL (2) in the Y-direction, and extend in the X-direction.

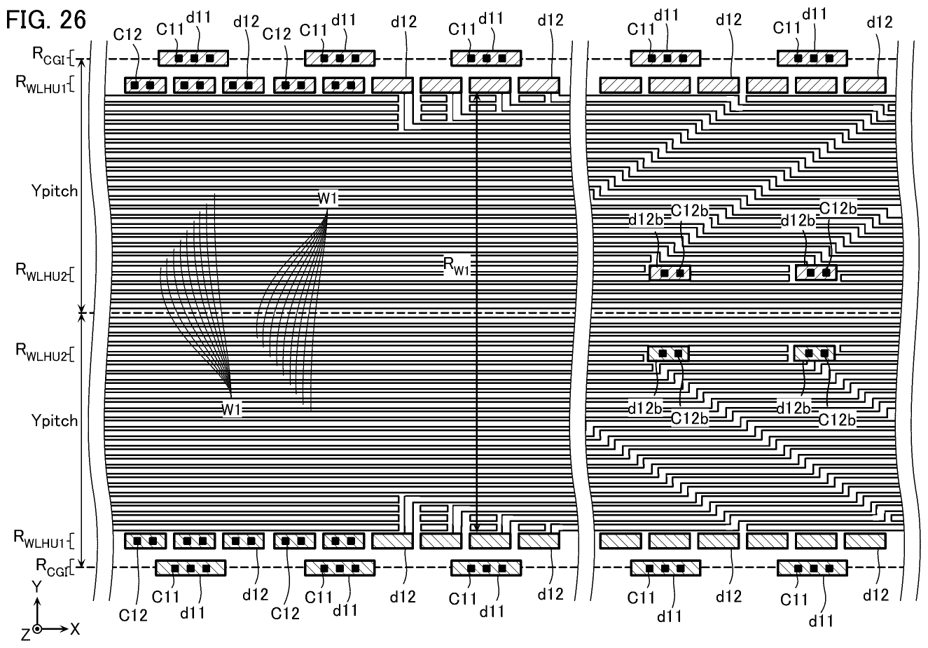

FIG. 26 is a plan view illustrating still another example of the wiring layer D1. It is preferred that in the wiring regions where the hook-up wirings W0, W1, W2 are formed, the hook-up wirings W0 to W3 are formed at approximately constant pitches in the exposure of photolithography and the like. When a plurality of wiring layers are formed, Chemical Mechanical Polishing (CMP) is performed. It is preferred that when CMP is performed, arrangement densities of the wiring layers DO to D3 are uniform. Therefore, as exemplified by the wiring layer D1 in FIG. 26, to dispose the hook-up wirings W0 to W3 (only the hook-up wirings W1 are illustrated) to be approximately constant in the wiring region, dummy wirings unconnected to any of the connecting portions d02 to d32 may be disposed as the hook-up wirings W0 to W3.

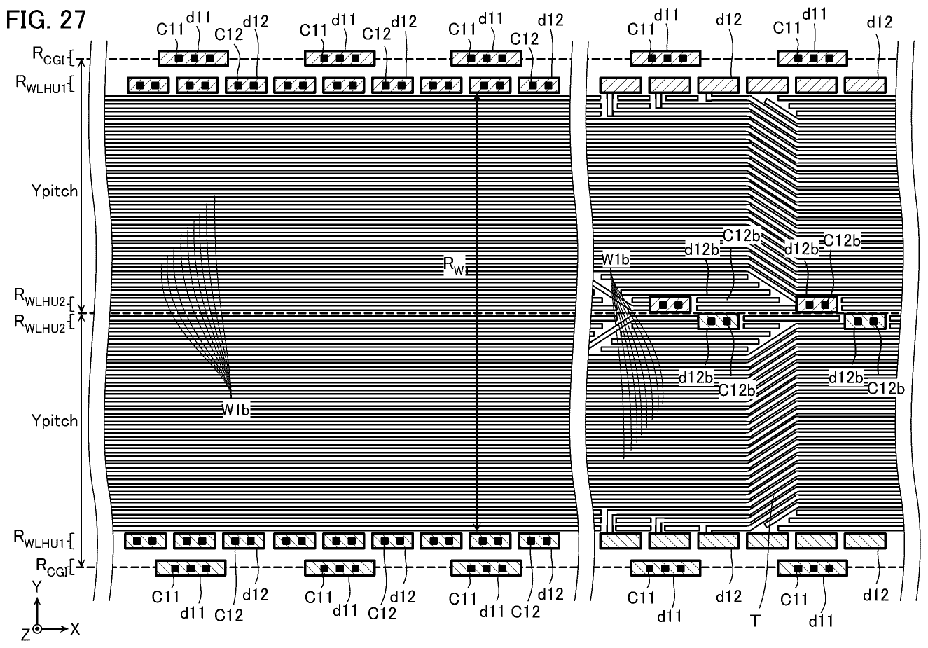

FIG. 27 is a plan view illustrating still another example of the wiring layer D1. The difference from the wiring layer D1 of FIG. 26 is that a hook-up wiring W1b partially includes an inclined portion T inclined at predetermined angles with respect to the X-direction and the Y-direction. Since other configurations are similar to the other configurations of the first embodiment, the detailed description is omitted.

### Effects of First Embodiment

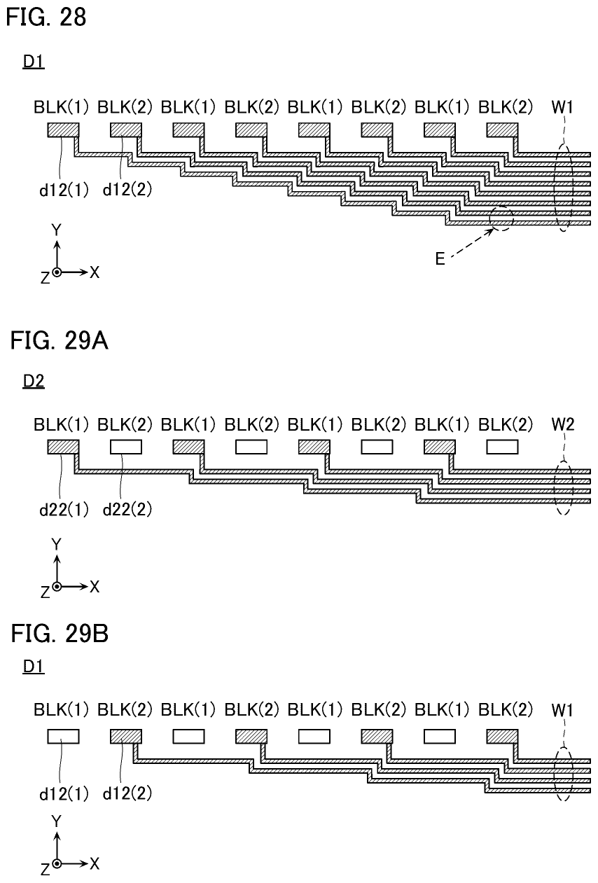

FIG. 28, FIG. 29A, and FIG. 29B are schematic plan views of the hook-up wirings W1 and W2 disposed at the first row RO1 of the wiring layers D1 and D2. FIG. 28 is a schematic plan view illustrating hook-up wirings W1 of a comparative example. FIG. 29A and FIG. 29B are schematic plan views of the hook-up wirings W1 and W2 of this embodiment.

In the comparative example illustrated in FIG. 28, the hook-up wirings W1 connected to a connecting portion d12 (1) connected to a word line WL (1) of the memory block BLK (1) and a connecting portion d12 (2) connected to a word line WL (2) of the memory block BLK (2) are wired in the same wiring layer D1. In this case, the hook-up wirings W1 of the different memory blocks BLK (1), BLK (2) are adjacent to one another. Usually, a high voltage, such as a read pass voltage V_{READ} and a write voltage V_{PGM}, is applied to the hook-up wiring W1 connected to the word line WL of the selected memory block BLK at the read operation and the write operation. On the other hand, since the hook-up wiring W1 connected to the word line WL of the unselected memory block BLK is in a floating state, an undefined low voltage is applied. At the erase operation, a low voltage about a ground voltage V_{SS} is applied to the hook-up wiring W1 connected to the word line WL of the selected memory block BLK, and a high erase voltage Vₑᵣₐ is applied to the source line SL and the bit line BL. Therefore, a high voltage, such as an erase voltage Vₑᵣₐ, is applied to the hook-up wiring W1 connected to the word line WL of the unselected memory block BLK. Thus, when the hook-up wiring W1 applied with a high voltage is adjacent to the hook-up wiring W1 with a low voltage, for example, a problem of Time Dependent Dielectric Breakdown (TDDB) or the like arises. Therefore, the disposition pitch of the hook-up wiring W1 cannot be decreased so much, and the number of the hook-up wirings W1 near the boundary between the hook-up region R_{HU} and the row control circuit region R_{RC} cannot be increased. As a result, there is a problem that the number of the word line switches WLSW below the memory hole region R_{MH} cannot be increased.

Additionally, when a short circuit occurs between the adjacent hook-up wirings W1 due to the influence of dust and the like, the two memory blocks BLK (1), BLK (2) possibly break down.

In contrast, in the first embodiment, as illustrated in FIG. 29A, FIG. 29B, the wiring layer D2 (and D0) in which the memory block BLK (1) is wired is different from the wiring layer D1 in which the memory block BLK (2) is wired. Therefore, in the same wiring layer D1 or D2 (and D0), the adjacent hook-up wirings W1 or W2 are connected to the word lines WL of the same memory block BLK (1) or BLK (2), and this avoids the occurrence of high voltage difference between the adjacent hook-up wirings W1 or W2. Consequently, the disposition pitch of the hook-up wiring W1 or W2 can be decreased, and the number of the hook-up wirings W1 near the boundary between the hook-up region R_{HU} and the row control circuit region R_{RC} can be increased. As a result, the number of the word line switches WLSW below the memory hole region R_{MH} can be further increased. Additionally, even when a short circuit occurs between the hook-up wirings W1 or W2 due to dust and the like, only one memory block BLK is affected thereby, and thus the influence of the short circuit is reduced.

### Second Embodiment

### [Positions of Connecting Portions d32 to d02 of Wiring Layers D3 to D0]

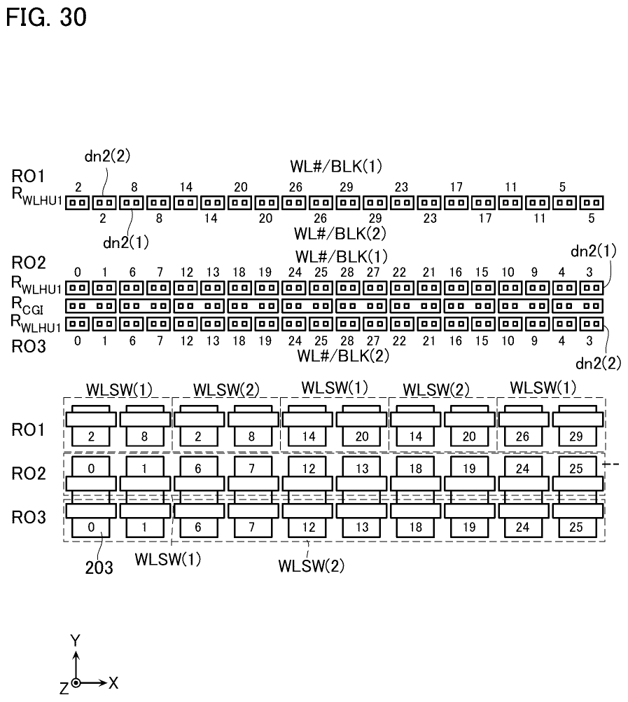

FIG. 30 is a schematic plan view illustrating positions of connecting portions d32 to d02 of wiring layers D3 to D0 according to a second embodiment. FIG. 30 illustrates the connecting portions d32, d22, d12, d02 of the wiring layers D3 to D0 illustrated in FIG. 20 to FIG. 24 generically as connecting portions dn2. Other configurations are similar to those of the first embodiment, and the explanation of the overlapping part is omitted.

In this embodiment, the order of the numbers of the word lines connected to connecting portions dn2 (1) of the second row RO2 of the wiring layers D3 to D0 is same as the order of the numbers of the word lines connected to connecting portions dn2 (2) of the third row RO3 of the wiring layers D3 to D0. In other words, the order of the numbers of the conductive layers 110 of the memory block BLK (1) connected to the connecting portions dn2 (1) of the second row RO2 of the wiring layers D3 to D0 is same as the order of the numbers of the conductive layers 110 of the memory block BLK (2) connected to the connecting portions dn2 (2) of the third row RO3 of the wiring layers D3 to D0.

In the example of FIG. 30, the numbers of the word lines WL connected to the connecting portions dn2 (1) disposed at the second row RO2 are set to 0, 1, 6, 7, 12, 13, 18, 19, 24, 25, . . . in the order from the X-direction negative side. On the other hand, the numbers of the word lines WL connected to the connecting portions dn2 (2) disposed at the third row RO3 are set to 0, 1, 6, 7, 12, 13, 18, 19, 24, 25, . . . in the order from the X-direction negative side as well. The number of the word line WL corresponds to the physical position in the Z-direction of the conductive layer 110, and may be counted from the bit line BL side, or may be counted from the source line SL side.

### Effect of Second Embodiment

With such an arrangement, the numbers of the word lines WL connected to the drain regions R_{DR} of the word line switches WLSW (1), WLSW (2) having the semiconductor region 203 in common become the same. Therefore, there is an advantage in that it is not necessary to provide a switch circuit or the like between the wiring CGI connected to the source region R_{SO} and the control circuit that applies a voltage to the wiring CGI, and the circuit configuration is simplified.

### First Modification of Second Embodiment

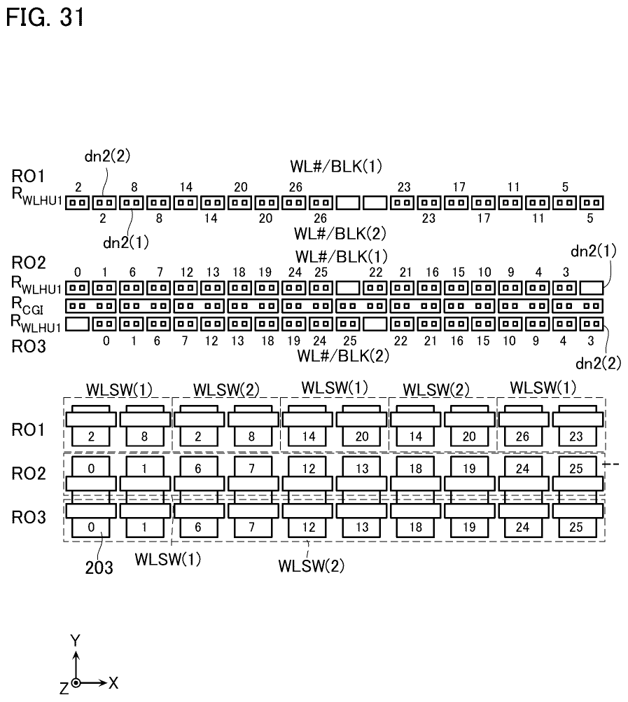

FIG. 31 is a schematic plan view illustrating positions of connecting portions d32 to d02 of wiring layers D3 to D0 according to a first modification of the second embodiment.

In the first modification, among the plurality of connecting portions dn2 (1) arranged in the second row RO2 of the wiring layers D3 to D0, the 11-th and 20-th connecting portions dn2 (1) counted from the X-direction negative side are dummies not connected anywhere. Among the plurality of connecting portions dn2 (2) arranged in the third row RO3 of the wiring layers D3 to D0, the 1st and 12-th connecting portions dn2 (2) counted from the X-direction negative side are dummies not connected anywhere.

As a result, the numbers of the word lines WL connected to the connecting portions dn2 (1) of the second row RO2 and the numbers of the word lines WL connected to the connecting portions dn2 (2) of the third row RO3 are shifted by one in the X-direction. However, the order of the numbers of the word lines WL connected to the connecting portions dn2 (1) of the second row RO2 is same as the order of the numbers of the word lines WL connected to the connecting portions dn2 (2) of the third row RO3. Therefore, the orders of the numbers of the word lines WL connected to the word line switches WLSW (1), WLSW (2) are similar to those of the second embodiment. Accordingly, as described above, even when the numbers of the word lines WL are shifted in the X-direction between those connected to the connecting portions dn2 (1) of the second row R02 and those connected to the connecting portions dn2 (2) of the third row RO3, the effect of the second embodiment can be provided.

### Second Modification of Second Embodiment

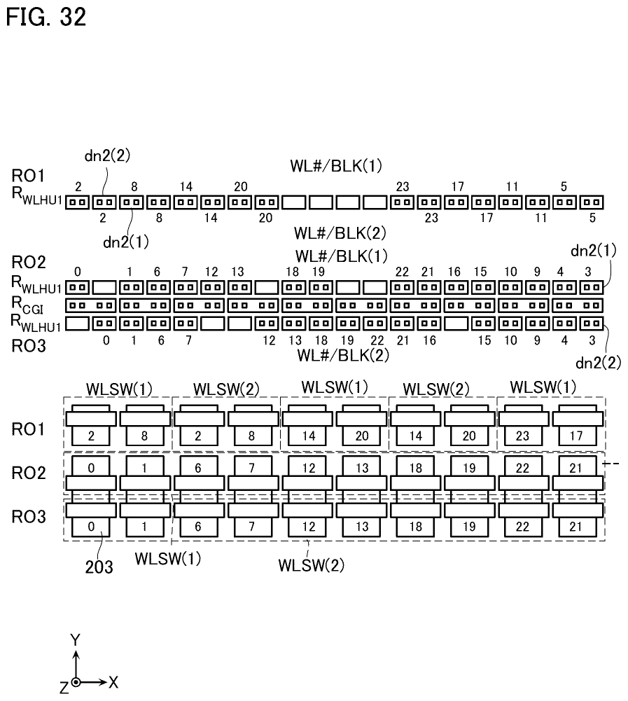

FIG. 32 is a schematic plan view illustrating positions of connecting portions d32 to d02 of wiring layers D3 to D0 according to a second modification of the second embodiment.

In the second modification, among the plurality of connecting portions dn2 (1) arranged in the second row RO2 of the wiring layers D3 to D0, the 2nd, 8-th, 11-th, and 12-th connecting portions dn2 (1) counted from the X-direction negative side are dummies not connected anywhere. Among the plurality of connecting portions dn2 (2) arranged in the third row RO3 of the wiring layers D3 to D0, the 1st, 6-th, 7-th, and 15-th connecting portions dn2 (2) counted from the X-direction negative side are dummies not connected anywhere.

This causes the numbers of the word lines WL connected to the connecting portions dn2 (1) of the second row RO2 and the numbers of the word lines WL connected to the connecting portions dn2 (2) of the third row RO3 to be partially differed in the X-direction and to be partially matched. However, the order of the numbers of the word lines WL connected to the connecting portions dn2 (1) of the second row RO2 is same as the order of the numbers of the word lines WL connected to the connecting portions dn2 (2) of the third row RO3. Therefore, the orders of the numbers of the word lines WL connected to the word line switches WLSW (1), WLSW (2) are similar to those of the second embodiment. Accordingly, as described above, even when the numbers of the word lines WL are shifted or matched in the X-direction between those connected to the connecting portions dn2 (1) of the second row RO2 and those connected to the connecting portions dn2 (2) of the third row RO3, the effect of the second embodiment can be provided.

### Third Embodiment

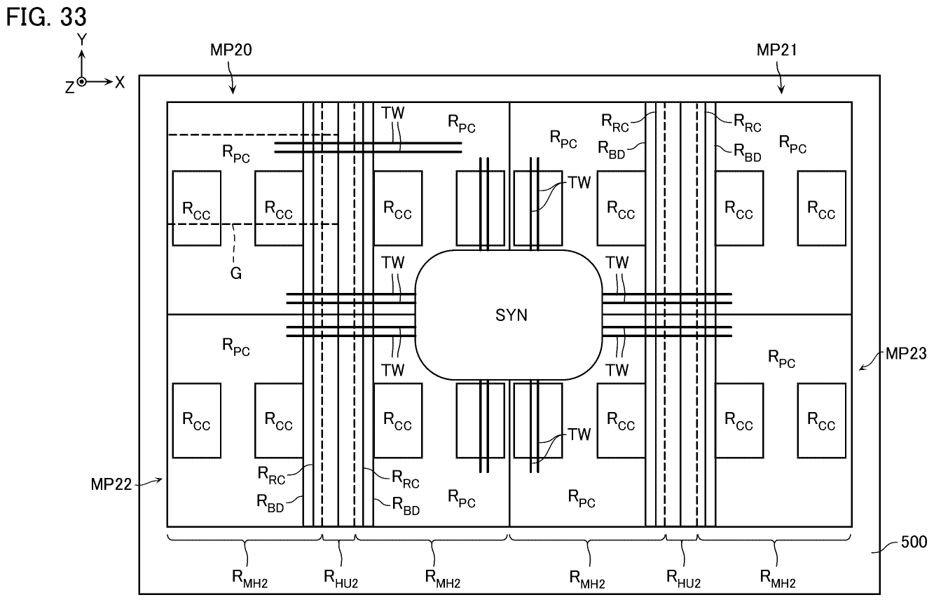

FIG. 33 is a schematic plan view illustrating an exemplary configuration of a semiconductor substrate 500 according to a third embodiment. In the third embodiment, for the configurations similar to those of the first embodiment, the explanation is omitted.

As illustrated in FIG. 33, the semiconductor substrate 500 includes four memory planes MP20 to MP23 arranged in the X-direction and the Y-direction. At the center portion of each of these four memory planes MP20 to MP23, two row control circuit region R_{RC} arranged in the X-direction are disposed. At the X-direction negative side and positive side of these two row control circuit regions R_{RC}, two block decoder regions R_{BD} are disposed. At the X-direction negative side and positive side of these two the block decoder regions R_{BD}, two peripheral circuit regions R_{PC} are disposed. In each of the two peripheral circuit regions R_{PC}, two column control circuit regions R_{CC} arranged in the X-direction are disposed.

In the example of FIG. 33, at a part of the inside of the two row control circuit regions R_{RC} disposed at the center in the X-direction of each of the memory planes MP20 to MP23, a hook-up region R_{HU2} is disposed. An end portion at the inside of a memory hole region R_{MH2} overlaps with the row control circuit region R_{RC} and the block decoder region R_{BD}. The peripheral circuit region R_{PC} is disposed in the memory hole region R_{MH2}. A control circuit SYN is disposed at the center portion of a region in which the four memory planes MP20 to MP23 are arranged. In the control circuit SYN, a plurality of passing wirings TW connect between peripheral circuits PC inside the memory plane MP, and connect between peripheral circuits PC of the plurality of memory planes MP.

Also in this embodiment, with the arrangement pattern of the word line switch WLSW in the row control circuit region R_{RC} disposed at the center portion of each of the memory planes MP20 to MP23, and the arrangement patterns of connecting portions d31 to d01, d32 to d02, hook-up wirings W2 to W0, and the like disposed in the hook-up region R_{HU2} similar to those of the first embodiment, the effects similar to those of the first embodiment can be provided.

### Fourth Embodiment

### [Structures of Word Line Switch WLSW and Select Gate Line Switch SGSW]

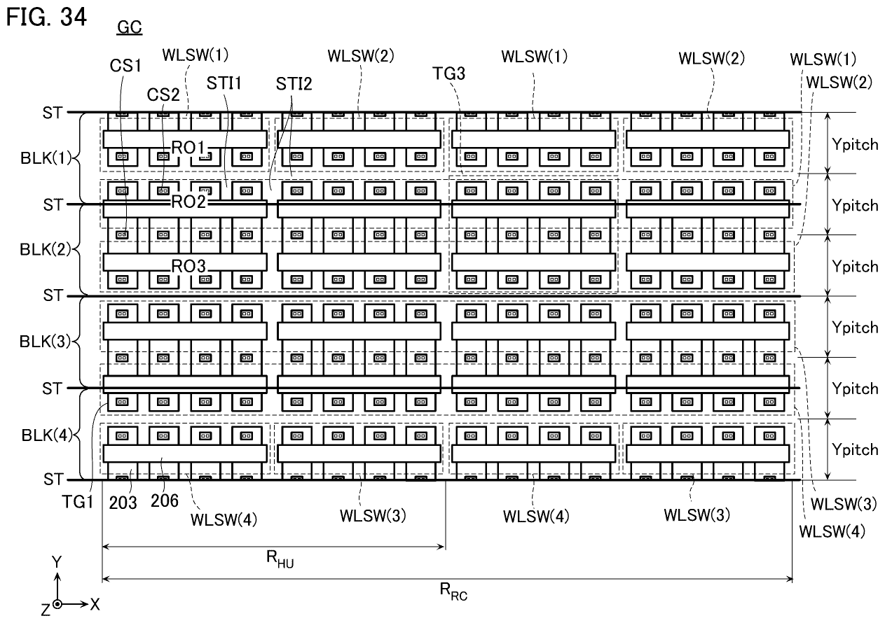

FIG. 34 is a schematic plan view illustrating an exemplary configuration of a word line switch WLSW according to a fourth embodiment. FIG. 34, for example, corresponds to the part indicated by B in FIG. 14. For ease of explanation, FIG. 34 illustrates an example in which the number of the word line switches WLSW (that is, the number of the word lines WL) in one memory block BLK is 24. However, the number of the word line switches WLSW is not limited to this number.

In the first embodiment illustrated in FIG. 15, two word line switches WLSW adjacent in the X-direction are connected by a common gate electrode 206, thereby constituting one transistor group TG2. In contrast, in the fourth embodiment, four word line switches WLSW adjacent in the X-direction are connected by a common gate electrode 206, thereby constituting one transistor group TG3.

In the first row RO1, four word line switches WLSW (1) adjacent in the X-direction are connected by a common gate electrode 206, thereby constituting one transistor group TG3. Further, in the first row RO1, four word line switches WLSW (2) adjacent in the X-direction are connected by a common gate electrode 206, thereby constituting one transistor group TG3. Then, the transistor group TG3 including the word line switches WLSW (1) and the transistor group TG3 including the word line switches WLSW (2) are alternately arranged in the X-direction. Also in the second row RO2 and the third row RO3, for the consistency of the pattern with the first row RO1, the arrangement patterns of the four word line switches WLSW (1) in the second row RO2 and the four word line switches WLSW (2) in the third row RO3 are same as the arrangement pattern in the first row RO1. The four word line switches WLSW (1) and the four word line switches WLSW (2) are each connected by a common gate electrode 206, thus constituting one transistor group TG3. Note that all of the word line switches WLSW (1) in the second row RO2 and all of the word line switches WLSW (2) in the third row RO3 may be each connected by a single gate electrode 206 extending in the X-direction.

Between the semiconductor regions 203 constituting the word line switches WLSW included in the same transistor group TG3, an insulating region STI that insulates the semiconductor regions 203 from one another is disposed. Between the semiconductor regions 203 constituting the word line switches WLSW included in the different transistor groups TG3, an insulating region STI2 that insulates the semiconductor regions 203 of the different memory blocks BLK from one another is disposed. A width in the X-direction of the insulating region STI2 is larger than a width in the X-direction of the insulating region STI1. A width in the Y-direction of the insulating region STI2 is larger than a width in the X-direction of the insulating region STI1.

In the fourth embodiment, since the number of the insulating regions STI2 is smaller than that of the first embodiment, a length in the X-direction of the row control circuit region R_{RC} can be smaller than that of the first embodiment.

[Positions of Connecting Portions d21, d22 of Wiring Layer D2 and Wiring Pattern in Wiring Layer D2]

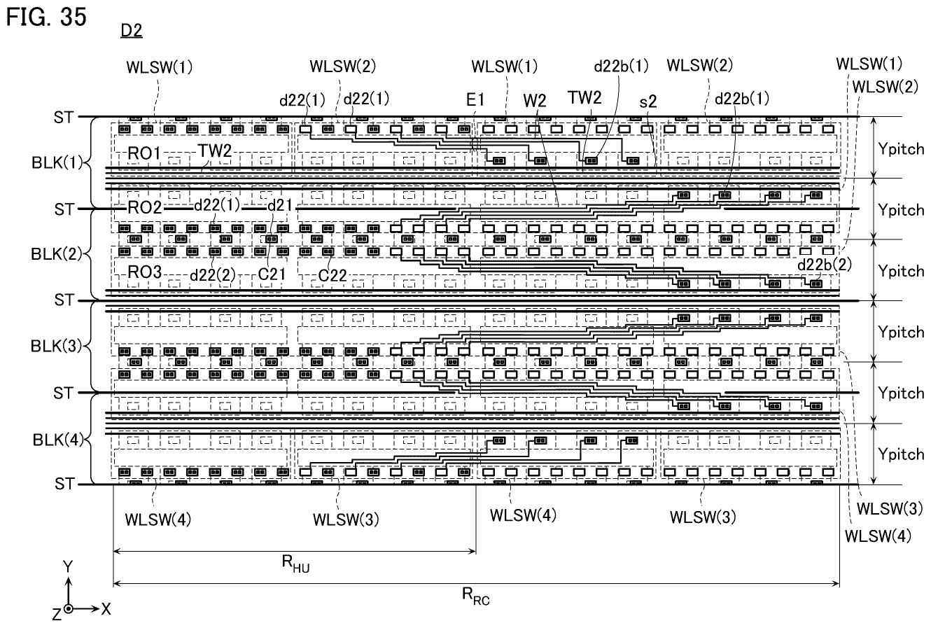

FIG. 35 is a schematic plan view illustrating an example of a wiring pattern in the wiring layer D2. The difference from the wiring pattern of the first embodiment illustrated in FIG. 21 is only the connection position of the hook-up wiring W2 at the word line switch WLSW side, and other configurations are similar to those of the first embodiment. Therefore, the explanation of the overlapping part is omitted, and only the different part is described.

As illustrated in FIG. 35, a part of the 16 connecting portions d22 (1), d22 (2) disposed at the first row RO1 in the region of the memory block BLK (1) in the hook-up region R_{HU}, in this example, the four connecting portions d22 (1) (the 9-th, 11-th, 13-th, and 15-th connecting portions d22 (1)) alternately disposed at the X-direction positive side are connected to one ends of the hook-up wirings W2. The other ends of the hook-up wirings W2 are connected to the connecting portions d22b (1) disposed in the drain regions R_{DR} of the consecutive four word line switches WLSW (1) that are 5-th to 8-th ones counted from the most positive side in the X-direction and disposed at the first row RO1 in the region of the memory block BLK (1).

[Positions of Connecting Portions d11, d12, d12b of Wiring Layer D1 and Wiring Pattern in Wiring Layer D1]

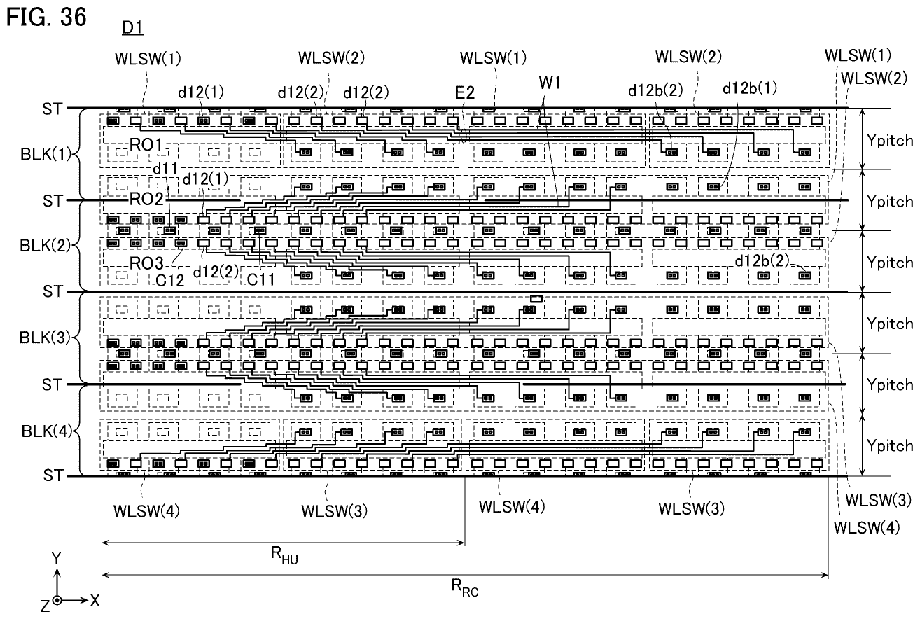

FIG. 36 is a schematic plan view illustrating an exemplary wiring pattern in the wiring layer D1. The difference from the wiring pattern of the first embodiment illustrated in FIG. 22 is only the connection position of the hook-up wiring W1 at the word line switch WLSW side, and other configurations are similar to those of the first embodiment. Therefore, the explanation of the overlapping part is omitted, and only the different part is described.

As illustrated in FIG. 36, among the 32 connecting portions d12 disposed at the first row RO1 in the region of the memory block BLK (1), the 16 connecting portions d12 disposed at the X-direction positive side are dummy connecting portions d12 disposed at the lower side in the Z-direction of the dummy connecting portions d32 (dummy) of the wiring layer D3. Among the other 16 connecting portions d12 (1), d12 (2) disposed in the hook-up region R_{HU}, the even-numbered 8 connecting portions d12 (2), that is, all the connecting portions d12 (2) disposed at this row are connected to one ends of the hook-up wirings W1. The other ends of the hook-up wirings W1 are connected to the connecting portions d12b (2) disposed in the drain regions R_{DR} of all of the 8 word line switches WLSW (2) of 5-th to 8-th and 13-th to 16-th ones counted from the X-direction negative side among the 16 word line switches WLSW (1), WLSW (2) disposed at the first row RO1 in the region of the memory block BLK (1).

[Positions of Connecting Portions d01, d02, d02b of Wiring Layer D0 and Wiring Pattern in Wiring Layer D0]

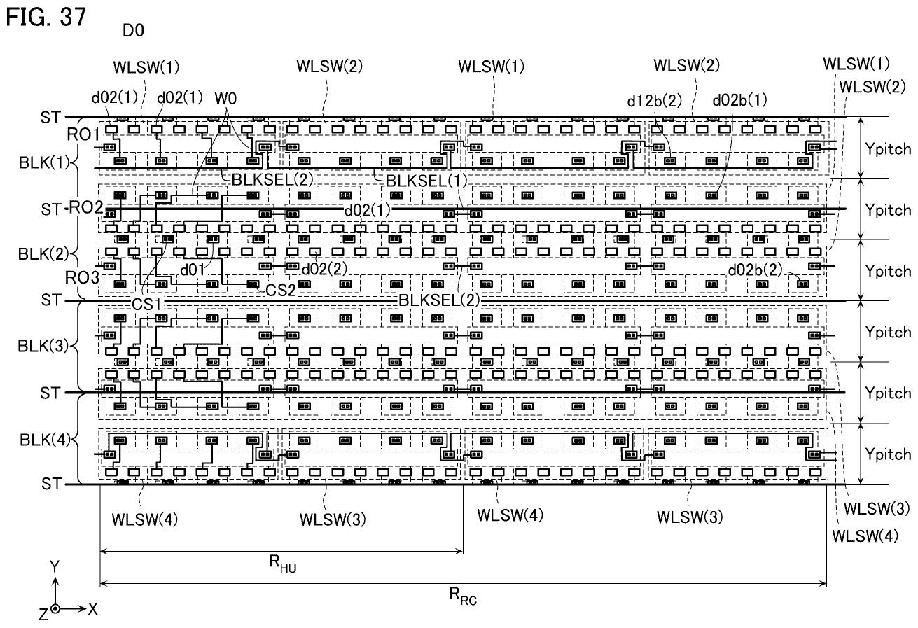

FIG. 37 is a schematic plan view illustrating an exemplary wiring pattern in the wiring layer D0. The difference from the wiring pattern of the first embodiment illustrated in FIG. 23 is only the connection position of the hook-up wiring W0 at the word line switch WLSW side, and other configurations are similar to those of the first embodiment. Therefore, the explanation of the overlapping part is omitted, and only the different part is described.

As illustrated in FIG. 37, among the 32 connecting portions d02 disposed at the first row RO1 in the region of the memory block BLK (1), the 16 connecting portions d02 disposed at the X-direction positive side are dummy connecting portions d02 disposed at the lower side in the Z-direction of the dummy connecting portions d32 (dummy) of the wiring layer D3. Among the other 16 connecting portions d02 (1), d02 (2) disposed in the hook-up region R_{HU}, the four connecting portions d02 (1) of 1st to 4-th ones from the X-direction negative side are connected to one ends of the hook-up wirings W0. The other ends of the hook-up wirings W0 are connected to the connecting portions d02b (1) disposed in the drain regions R_{DR} of the 1st to 4-th word line switches WLSW (1) from the X-direction negative side among the 16 word line switches WLSW (1), WLSW (2) disposed at the first row RO1 in the region of the memory block BLK (1).

According to this embodiment, the connection destinations of the hook-up wirings W2 to W0 at the drain side of the word line switch WLSW can be brought together, the wiring design can be more facilitated.

### Fifth Embodiment

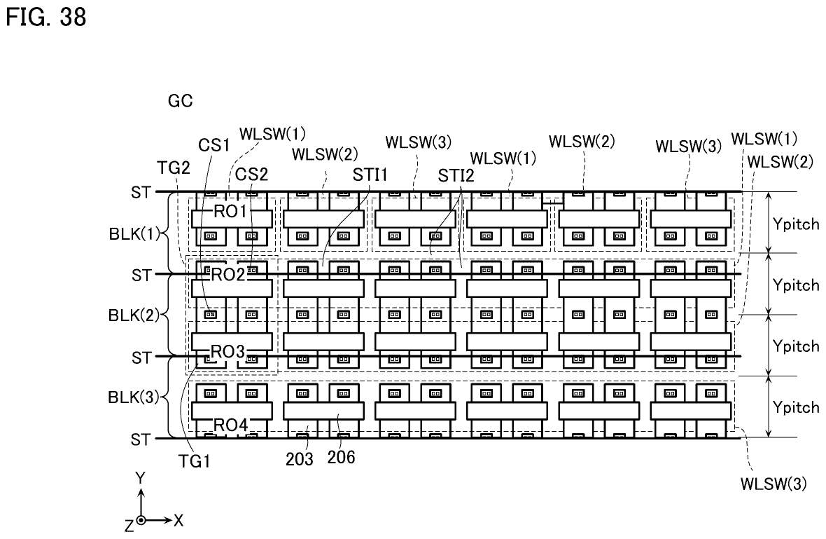

FIG. 38 is a schematic plan view illustrating an exemplary configuration of a word line switch WLSW according to a fifth embodiment. FIG. 38, for example, corresponds to the part indicated by B in FIG. 14. For ease of explanation, FIG. 38 illustrates an example in which the number of the word line switches WLSW (that is, the number of the word lines WL) in one memory block BLK is 16. However, the number of the word line switches WLSW is not limited to this number.

In this embodiment, a ratio of the pitch in the Y-direction between the word line switch WLSW and the memory block BLK is 3:4. That is, a length in the Y-direction of four word line switches WLSW arranged in the Y-direction is equal to a length in the Y-direction of three memory blocks BLK arranged in the Y-direction. Hereinafter, such an arrangement pattern of the word line switch WLSW is denoted as “4Tr/3BLK” in some cases.

As illustrated in FIG. 38, in this embodiment, a plurality of sets of four word line switches WLSW arranged in the Y-direction are arranged in the X-direction corresponding to three memory blocks BLK arranged in the Y-direction. In the plurality of word line switches WLSW arranged in the X-direction, in the first row RO1, a word line switch WLSW (1) connected to the word line WL of the memory block BLK (1), a word line switch WLSW (2) connected to the word line WL of the memory block BLK (2), and a word line switch WLSW (3) connected to the word line WL of the memory block BLK (3) are repeatedly disposed in the X-direction in this order. In the second row RO2, the word line switches WLSW (1) connected to the word lines WL of the memory block BLK (1) are consecutively disposed in the X-direction. In the third row RO3, the word line switches WLSW (2) connected to the word lines WL of the memory block BLK (2) are consecutively disposed in the X-direction. In the fourth row RO4, the word line switches WLSW (3) connected to the word lines WL of the memory block BLK (3) are consecutively disposed in the X-direction.

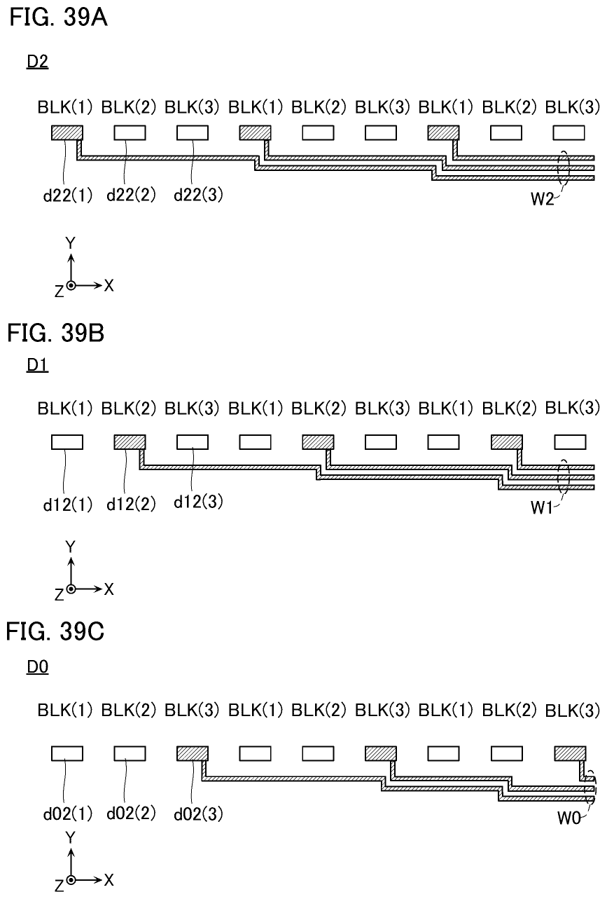

FIG. 39A, FIG. 39B, and FIG. 39C are schematic plan views illustrating wiring patterns of hook-up wirings W2, W1, W0 disposed at the first row RO1. FIG. 39A illustrates the wiring layer D2, FIG. 39B illustrates the wiring layer D1, and FIG. 39C illustrates the wiring layer D0.

As illustrated in FIG. 39A, in the wiring layer D2, only the hook-up wiring W2 that connects the connecting portion d22 (1) connected to the word line WL (1) of the memory block BLK (1) to the word line switch WLSW (1) is disposed.

As illustrated in FIG. 39B, in the wiring layer D1, only the hook-up wiring W1 that connects the connecting portion d12 (2) connected to the word line WL (2) of the memory block BLK (2) to the word line switch WLSW (2) is disposed.

As illustrated in FIG. 39C, in the wiring layer D0, only the hook-up wiring W0 that connects the connecting portion d02 (3) connected to the word line WL (3) of the memory block BLK (3) to the word line switch WLSW (3) is disposed.

Also in this embodiment, the hook-up wirings W2, W1, and W0 connected to the word lines WL of the different memory blocks BLK (1), BLK (2), and BLK (3) are not disposed to be mutually adjacent in the same wiring layer D2, D1, or DO, and thus the effect similar to that of the first embodiment can be provided.

### Sixth Embodiment

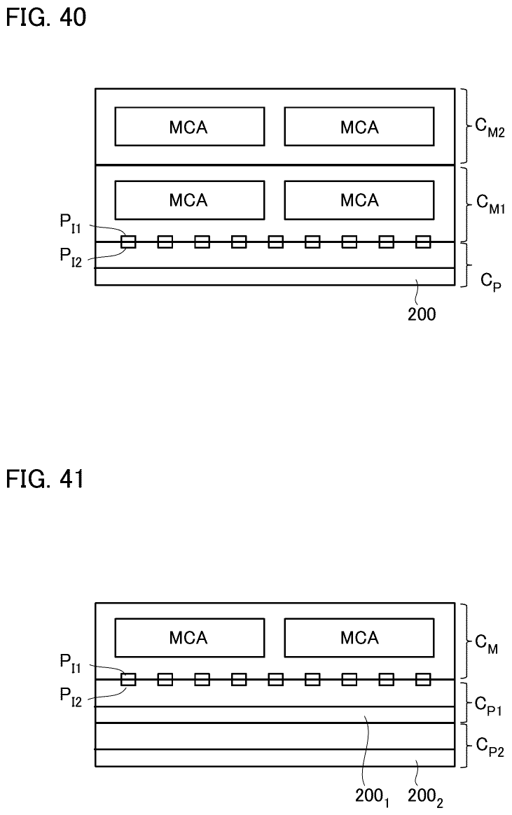

FIG. 40 and FIG. 41 are diagrams illustrating schematic configurations of a semiconductor memory device according to a sixth embodiment. In the sixth embodiment, the above-described first embodiment to fifth embodiment are applied to a semiconductor memory device having a multi-stack array structure.

The semiconductor memory device illustrated in FIG. 40 includes one chip C_{P} and a plurality of chips C_{M1}, C_{M2} mounted on the chip C_{P}. The chip C_{P} includes a semiconductor substrate 200 and various kinds of circuits and wiring layers disposed on this semiconductor substrate 200. Each of the chips C_{M1}, C_{M2} includes a plurality of memory cell arrays MCA. The chip C_{P} is bonded to the plurality of chips C_{M1}, C_{M2} via bonding electrode P_{I1}, P_{I2}. For the configuration of the wiring layer in the chip C_{P}, any one of the first embodiment to the fifth embodiment is applicable.

The semiconductor memory device illustrated in FIG. 41 includes a plurality of chips C_{P1}, C_{P2} and one chip C_{M} mounted on the plurality of chips C_{P1}, C_{P2}. The chip C_{P1} includes various kinds of circuits and wiring layers on a semiconductor substrate 2001. The chip C_{P2} includes various kinds of circuits and wiring layers on a semiconductor substrate 2002. The chip C_{P1} need not include the semiconductor substrate 2001. The chip C_{M} includes a plurality of memory cell arrays MCA. The plurality of chips C_{P1}, C_{P2} are bonded to the chip C_{M} via bonding electrodes P_{I1}, P_{I2}. For the configuration of the wiring layer in the chip C_{P1} or the chip C_{P2}, any one of the first embodiment to the fifth embodiment is applicable.

### Seventh Embodiment

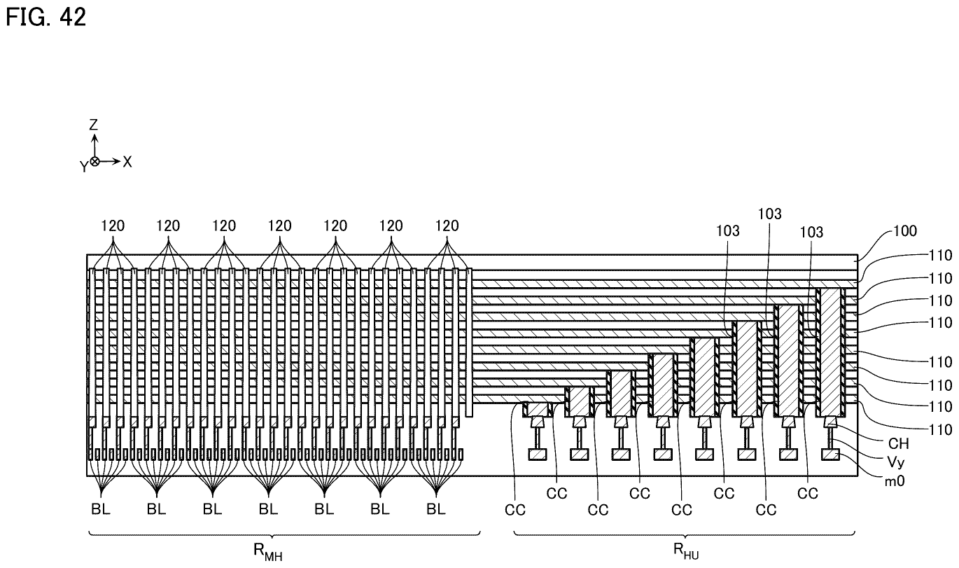

FIG. 42 is a schematic cross-sectional view illustrating a configuration of a part of a semiconductor memory device according to a seventh embodiment. FIG. 42 illustrates only a configuration of a chip C_{M}. Since the chip C_{P} is similar to that of the first embodiment to sixth embodiment, the detailed description is omitted.

In the first embodiment to sixth embodiment, in the hook-up region R_{HU}, the conductive layers 110 (word line WL and select gate line SG) of each of the layers are formed in a staircase pattern, and one ends of the via-contact electrodes CC are connected to the conductive layers 110 formed in a staircase pattern of each of the layers. In contrast, in the seventh embodiment, in the hook-up region R_{HU}, the conductive layers 110 are not formed in a staircase pattern. A plurality of via-contact electrodes CC extend in the Z-direction, and are directly connected to the conductive layers 110 or penetrate one or a plurality of the conductive layers 110 in the Z-direction. The via-contact electrode CC has one end connected to the conductive layer 110, and an insulating layer 103 is disposed between the conductive layers 110 that the via-contact electrode CC penetrates and a side surface of the via-contact electrode CC.

The structure of the seventh embodiment can be manufactured by a process below. For example, a plurality of contact holes that reach the conductive layers 110 of the respective layers are formed. To differentiate depths of the contact holes, the formation time is controlled for each contact hole. The insulating layer 103 of silicon oxide (SiO₂) or the like is formed on outer peripheral surfaces of the plurality of contact holes. Subsequently, the insulating layer 103 formed on a bottom surface of the contact hole is removed, and via-contact electrodes CC including, for example, a stacked film of a barrier conductive film of titanium nitride (TiN) or the like and a metal film of tungsten (W) or the like are formed inside the insulating layer 103.

Also, in the semiconductor memory device provided with the via-contact electrode CC as described above, the wiring structure similar to that of the first embodiment to sixth embodiment is applicable.

### Eighth Embodiment

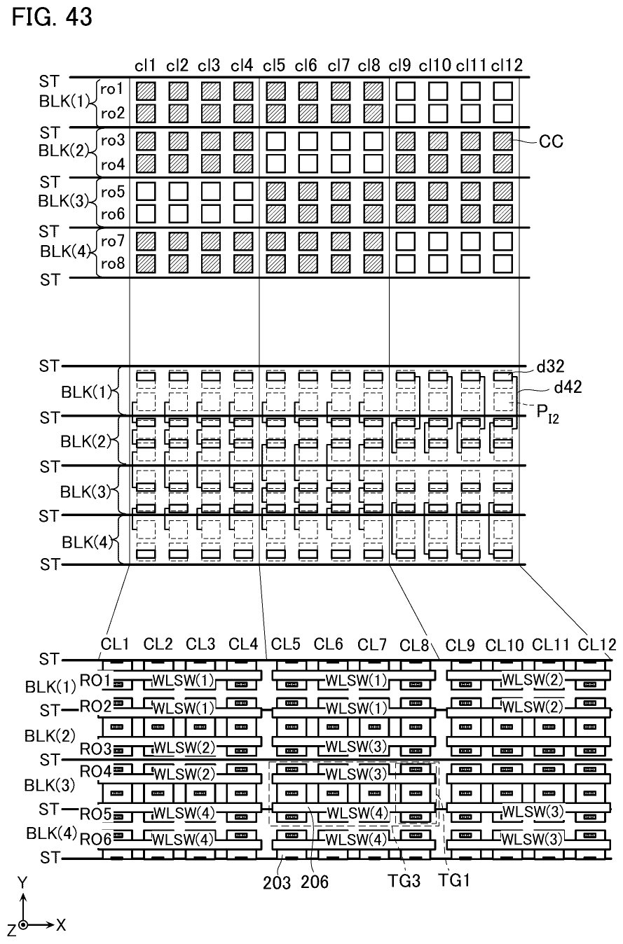

FIG. 43 is a schematic plan view illustrating an exemplary arrangement of via-contact electrodes CC and an exemplary arrangement of connecting portions dn2 and word line switches WLSW in a wiring layer corresponding thereto in a semiconductor memory device according to an eighth embodiment. For the configurations similar to those of the first embodiment to the seventh embodiment, the same reference numerals are attached and the detailed explanation is omitted.

In the eighth embodiment, a relation between the word line switch WLSW and the memory block BLK is a relation of 3Tr/2BLK. This example illustrates a relation in the arrangement pattern of the word line switch WLSW and the via-contact electrode CC at 6Tr/4BLK (M=6, N=4) in a unit of four memory blocks BLK.

The eight word line switches WLSW in total of four columns in the X-direction and two rows in the Y-direction constitute a transistor group TG3. The transistor group TG3 includes four transistor groups TG1 having a gate electrode 206 in common and arranged in the X-direction. In this example, three transistor groups TG3 are arranged in the X-direction, and one and a half of the transistor groups TG3 are arranged on both sides from the center in the Y-direction. In a unit of the transistor group TG3 divided into two in the Y-direction, in the first row RO1 and the second row RO2, the word line switches WLSW (1), WLSW (1), WLSW (2) are disposed in the order from the X-direction negative side. In the third row RO3 and the fourth row RO4, the word line switches WLSW (2), WLSW (3) are disposed in the order. In the fifth row RO5 and the sixth row RO6, the word line switches WLSW (4), WLSW (4), WLSW (3) are disposed in the order.

The order in the Y-direction of the word line switch WLSW is the word line switches WLSW (1), WLSW (1), WLSW (2), WLSW (2), WLSW (4), WLSW (4) in the order from the Y-direction positive side in a first column CL1 to a fourth column CL4. In a fifth column CL5 to an eighth column CL8, the order is the word line switches WLSW (1), WLSW (1), WLSW (3), WLSW (3), WLSW (4), WLSW (4) from the Y-direction positive side. In a ninth column CL9 to a twelfth column CL12, the order is the word line switches WLSW (2), WLSW (2), WLSW (3), WLSW (3) from the Y-direction positive side. The word line switches WLSW of the ninth column CL9 to the twelfth column CL12 in the third row RO3 and the fourth row RO4 are dummies not used.

On the other hand, the 24 via-contact electrodes CC in total of 2 rows×12 columns are disposed for each memory block BLK, and among them, the 8 via-contact electrodes CC in total of 2 rows×4 columns are dummies. Therefore, the number of the active via-contact electrodes CC is 16 for each memory block BLK. Here, the “dummy via-contact electrode CC” is an electrode not connected to any drain region R_{DR} of the word line switch WLSW. For example, when a via-contact electrode Vy that connects an electrode of a via-contact electrode layer CH to a wiring m0 illustrated in FIG. 42 is not disposed, the via-contact electrode CC unconnected to the wiring m0 is dummy. It is not required to dispose such a dummy via-contact electrode CC in this embodiment. The effect of this embodiment can be provided even without providing the dummy via-contact electrode CC.

In the memory block BLK (1) (first row ro1, second row ro2), the via-contact electrodes CC are active in a first column cl1 to an eighth column cl8, and dummies in a ninth column cl9 to a twelfth column cl12.

In the memory block BLK (2) (third row ro3, fourth row ro4), the via-contact electrodes CC are active in the first column cl1 to a fourth column cl4 and the ninth column cl9 to the twelfth column cl12, and dummies in a fifth column cl5 to the eighth column cl8.

In the memory block BLK (3) (fifth row ro5, sixth row ro6), the via-contact electrodes CC are active in the fifth column cl5 to the twelfth column cl12, and dummies in the first column cl1 to the fourth column cl4.

In the memory block BLK (4) (seventh row ro7, eighth row ro8), the via-contact electrodes CC are active in the first column cl1 to the eighth column cl8, and dummies in the ninth column cl9 to the twelfth column cl12.

Thus, since the dummy via-contact electrodes CC are distributed in the X-direction and the Y-direction, the active via-contact electrodes CC are arranged by 12 in the X-direction and six in the Y-direction by shifting the via-contact electrodes CC excluding the dummies in the Y-direction (however, the numbers of the active via-contact electrodes CC arranged in the Y-direction in the ninth column cl9 to the twelfth column cl12 is four). Accordingly, the numbers of the via-contact electrodes CC in the X and Y-directions match the numbers of the word line switches WLSW in the X and Y-directions.

The order in the Y-direction of the memory block BLK including the active via-contact electrode CC is the memory blocks BLK (1), BLK (1), BLK (2), BLK (2), BLK (4), BLK (4) from the Y-direction positive side in the first column cl1 to the fourth column cl4. In the fifth column cl5 to the eighth column cl8, the order is the memory blocks BLK (1), BLK (1), BLK (3), BLK (3), BLK (4), BLK (4) from the Y-direction positive side. In the ninth column cl9 to the twelfth column cl12, the order is the memory blocks BLK (2), BLK (2), BLK (3), BLK (3) from the Y-direction positive side.

Thus, in this embodiment, the order in the Y-direction of the plurality of word line switches WLSW matches the order in the Y-direction of the plurality of via-contact electrodes CC connected to the plurality of word line switches WLSW at respective positions in the X-direction. In the structure illustrated in FIG. 42, since the arrangement of the via-contact electrode CC can be relatively freely selected, such a pattern in which the dummies are disposed at any positions can be employed.

### [Effect]

According to this embodiment, as illustrated in FIG. 43, with the dummy via-contact electrodes CC disposed in the arrangement pattern of the via-contact electrode CC, the active via-contact electrodes CC match the word line switches WLSW in the positional relation. This allows aligning the positional relation of the via-contact electrodes CC, the bonding electrodes P_{I2}, and the connecting portions d32 connected to the hook-up wirings W2 to W0. Accordingly, the pattern of the wiring from the via-contact electrode CC or the bonding electrode P_{I2} to the connecting portion d32 passing through the connecting portion d42, and further the pattern of the hook-up wirings W2 to W0 from the connecting portions d32 to the word line switches WLSW can be simplified, and the wiring paths can be shortened.

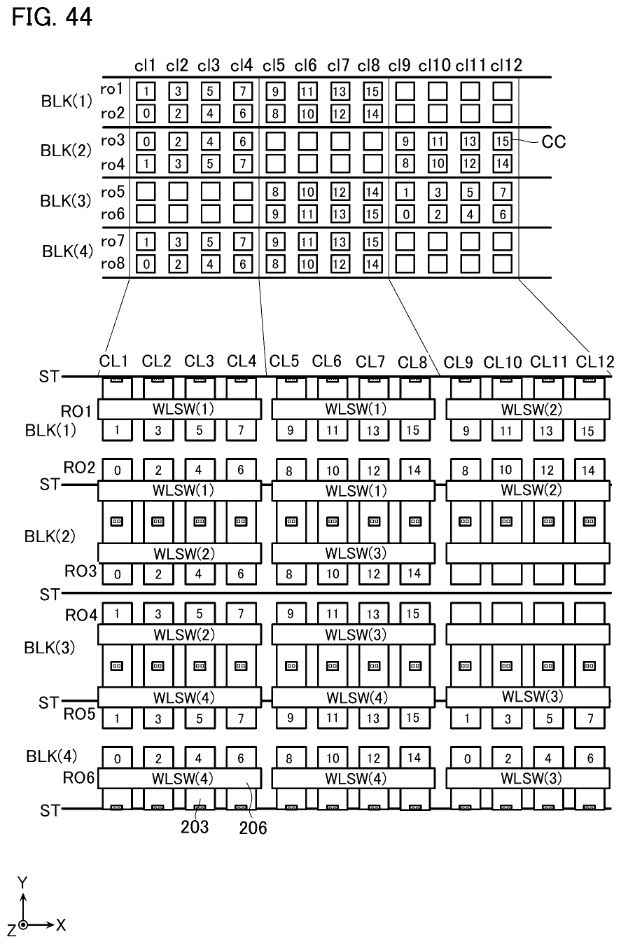

FIG. 44 is a schematic plan view illustrating an exemplary assignment of word line WL numbers to the via-contact electrodes CC and the word line switches WLSW. In the memory block BLK (1), in the first column cl1 to the eighth column cl8 of the first row ro1, the word line numbers of 1, 3, 5, 7, 9, 11, 13, and 15 are assigned. In the first column cl1 to the eighth column cl8 of the second row ro2, the word line numbers of 0, 2, 4, 6, 8, 10, 12, and 14 are assigned. For the memory blocks BLK (2), BLK (3), and BLK (4), the word line numbers are assigned as illustrated in FIG. 44.

The order in the Y-direction of the assignment pattern of the word line WL number to the via-contact electrode CC is same as the order in the Y-direction of the assignment pattern to the drain region of the word line switch WLSW. The word line numbers of the word line switches WLSW having the semiconductor region 203 in common are same. This facilitates the arrangement of the wiring CGI. Note that in this embodiment, the assignment pattern of the word line number to the via-contact electrode CC completely matches the assignment pattern of the word line number to the drain region of the word line switch WLSW. However, insofar as the order in the Y-direction is same, the assignment pattern to the via-contact electrode CC may be different from the assignment pattern to the word line switch WLSW within the range of the four word line switches WLSW having the gate electrode 206 in common.

### Ninth Embodiment

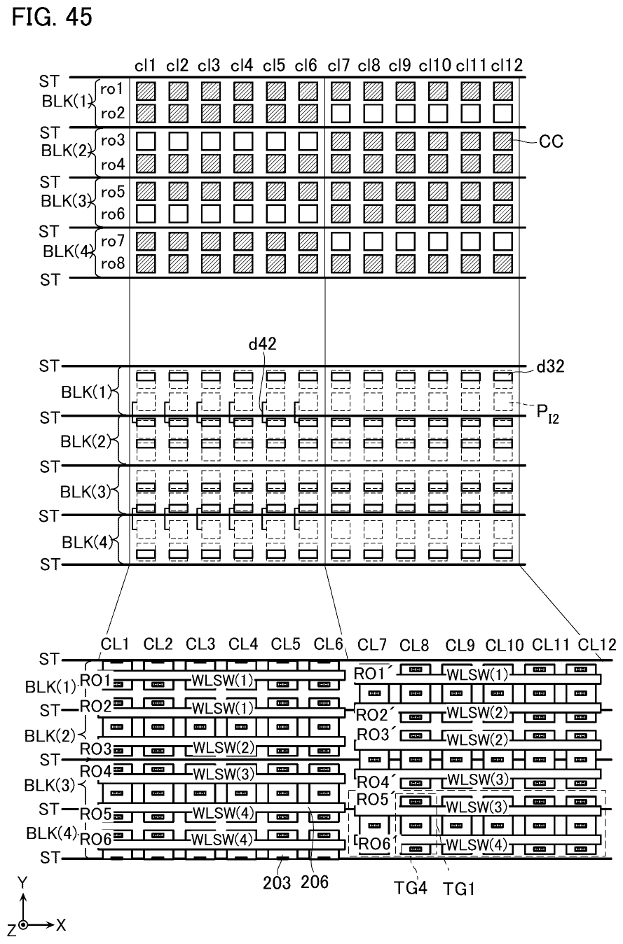

FIG. 45 is a schematic plan view illustrating an exemplary arrangement of via-contact electrodes CC and an exemplary arrangement of connecting portions dn2 and word line switches WLSW in a wiring layer corresponding thereto in a semiconductor memory device according to a ninth embodiment. For the configurations similar to those of the first embodiment to the eighth embodiment, the same reference numerals are attached and the detailed explanation is omitted.

In the ninth embodiment, a relation between the word line switch WLSW and the memory block BLK is a relation of 3Tr/2BLK. This example illustrates a relation in the arrangement pattern of the word line switch WLSW and the via-contact electrode CC at 6Tr/4BLK (M=6, N=4) in a unit of four memory blocks BLK.

In the ninth embodiment, the 12 word line switches WLSW in total of six columns in the X-direction and two rows in the Y-direction constitute a transistor group TG4. The transistor group TG4 includes six transistor groups TG1 having a gate electrode 206 in common and arranged in the X-direction. In this example, two transistor groups TG4 are arranged in the X-direction. The transistor groups TG4 arranged in the X-direction are mutually shifted in the Y-direction by one transistor Tr. Therefore, in the left side of the drawing, one and a half of the transistor groups TG4 are arranged at both sides from the center in the Y-direction, and in the right side of the drawing, three transistor groups TG4 are arranged in the Y-direction.

The order in the Y-direction of the word line switch WLSW is the word line switches WLSW (1), WLSW (1), WLSW (2), WLSW (3), WLSW (4), WLSW (4) in the order from the Y-direction positive side in a first column CL1 to a sixth column CL6. In a seventh column CL7 to a twelfth column CL12, the order is the word line switches WLSW (1), WLSW (2), WLSW (2), WLSW (3), WLSW (3), WLSW (4) from the Y-direction positive side.

On the other hand, the 24 via-contact electrodes CC in total of 2 rows×12 columns are disposed for each memory block BLK, and among them, the 6 via-contact electrodes CC in total of 1 row×6 columns are dummies. Therefore, the number of the active via-contact electrodes CC is 18 for each memory block BLK.

In a first row ro1 of the memory block BLK (1), the via-contact electrodes CC are active in a first column cl1 to a twelfth column cl12. In a second row ro2, the via-contact electrodes CC are active in the first column cl1 to a sixth column cl6, and dummies in a seventh column cl7 to the twelfth column cl12.

In a third row ro3 of the memory block BLK (2), the via-contact electrodes CC are dummies in the first column cl1 to the sixth column cl6, and active in the seventh column cl7 to the twelfth column cl12. In a fourth row ro4, the via-contact electrodes CC are active in the first column cl1 to the twelfth column cl12.

In a fifth row ro5 of the memory block BLK (3), the via-contact electrodes CC are active in the first column cl1 to the twelfth column cl12. In a sixth row ro6, the via-contact electrodes CC are dummies in the first column cl1 to the sixth column cl6, and active in the seventh column cl7 to the twelfth column cl12.

In a seventh row ro7 of the memory block BLK (4), the via-contact electrodes CC are active in the first column cl1 to the sixth column cl6, and dummies in the seventh column cl7 to the twelfth column cl12. In an eighth row ro8, the via-contact electrodes CC are active in the first column cl1 to the twelfth column cl12.

Thus, since the dummy via-contact electrodes CC are distributed in the X-direction and the Y-direction, the active via-contact electrodes CC are arranged by 12 in the X-direction and six in the Y-direction by shifting the via-contact electrodes CC excluding the dummies in the Y-direction. Accordingly, the numbers of the via-contact electrodes CC in the X and Y-directions match the numbers of the word line switches WLSW in the X and Y-directions. The order in the Y-direction of the memory block BLK including the active via-contact electrode CC is the memory blocks BLK (1), BLK (1), BLK (2), BLK (3), BLK (4), BLK (4) from the Y-direction positive side in the first column cl1 to the sixth column cl6. In the seventh column cl7 to the twelfth column cl12, the order is the memory blocks BLK (1), BLK (2), BLK (2), BLK (3), BLK (3), BLK (4) from the Y-direction positive side.

Also in this embodiment, with the dummy via-contact electrodes CC disposed in the arrangement pattern of the via-contact electrode CC, the active via-contact electrodes CC match the word line switches WLSW in the positional relation. This allows aligning the positional relation between the via-contact electrodes CC and the bonding electrodes P_{I2}, and the positional relation between the connecting portions d32 connected to the hook-up wirings W2 to W0. Accordingly, the pattern of the wiring from the via-contact electrode CC or the bonding electrode P_{I2} to the connecting portion d32 passing through the connecting portion d42, and further the pattern of the hook-up wirings W2 to W0 from the connecting portions d32 to the word line switches WLSW can be simplified, and the wiring paths can be shortened.

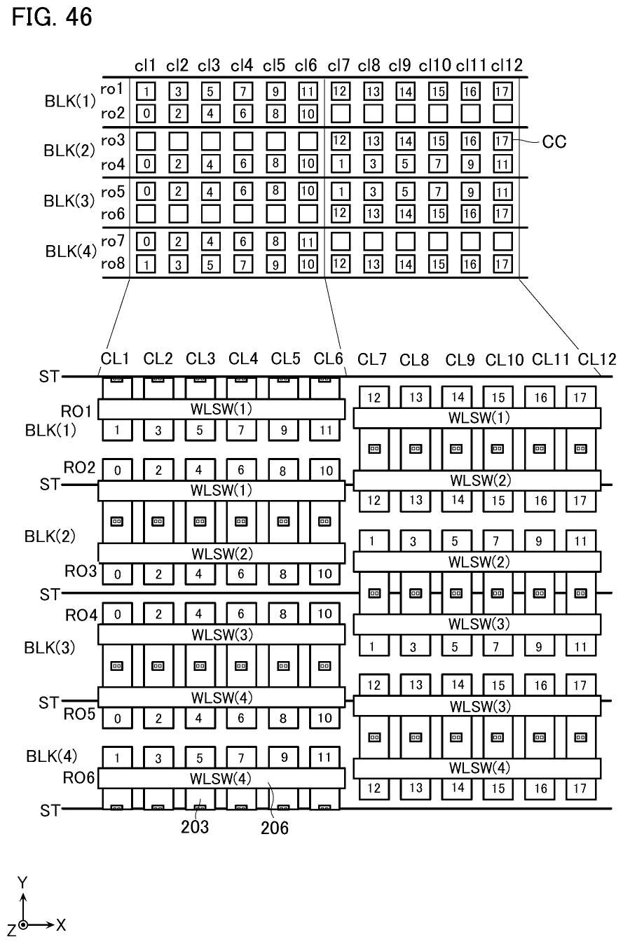

FIG. 46 is a schematic plan view illustrating an exemplary assignment of word line WL numbers to the via-contact electrodes CC and the word line switches WLSW. In the memory block BLK (1), in the first column cl1 to the twelfth column cl12 of the first row ro1, the word line numbers of 1, 3, 5, 7, 9, 11, 12, 13, 14, 15, 16, and 17 are assigned. In the first column cl1 to the sixth column cl6 of the second row ro2, the word line numbers of 0, 2, 4, 6, 8, and 10 are assigned. For the memory blocks BLK (2), BLK (3), and BLK (4), the word line numbers are assigned as illustrated in FIG. 46.

The order in the Y-direction of the assignment pattern of the word line WL number to the via-contact electrode CC is same as the order in the Y-direction of the assignment pattern to the drain region of the word line switch WLSW. The word line numbers of the word line switches WLSW having the semiconductor region 203 in common are same. This facilitates the arrangement of the wiring CGI.

### Tenth Embodiment

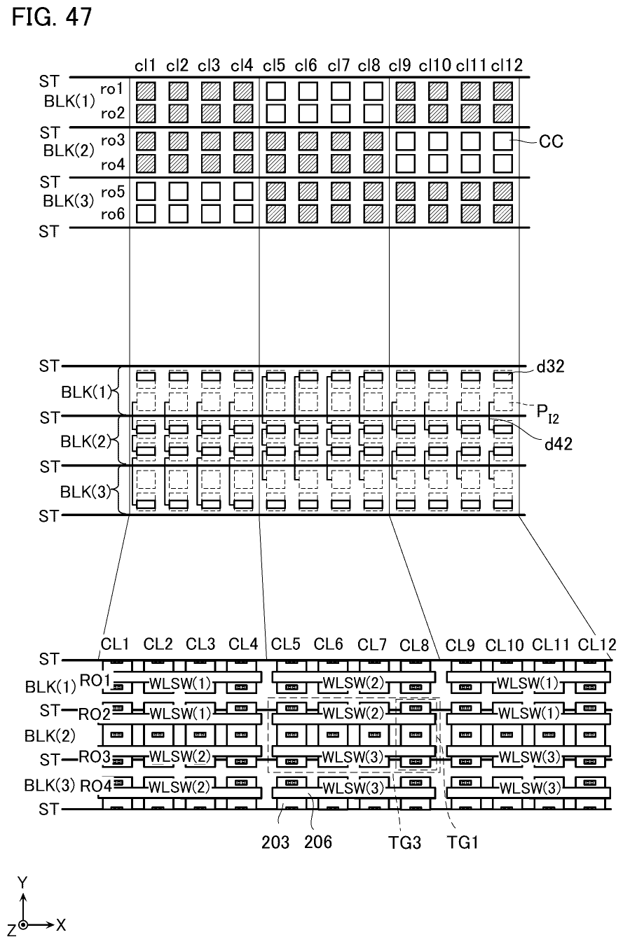

FIG. 47 is a schematic plan view illustrating an exemplary arrangement of via-contact electrodes CC and an exemplary arrangement of connecting portions dn2 and word line switches WLSW in a wiring layer corresponding thereto in a semiconductor memory device according to a tenth embodiment. For the configurations similar to those of the first embodiment to the ninth embodiment, the same reference numerals are attached and the detailed explanation is omitted.

In the tenth embodiment, a relation between the word line switch WLSW and the memory block BLK is a relation of 4Tr/3BLK (M=4, N=3). In the tenth embodiment, the 8 word line switches WLSW in total of four columns in the X-direction and two rows in the Y-direction constitute a transistor group TG3. The transistor group TG3 includes four transistor groups TG1 having a gate electrode 206 in common and arranged in the X-direction. In this example, three transistor groups TG3 are arranged in the X-direction, and one transistor group TG3 and a half thereof at each of both sides are arranged in the Y-direction.

The order in the Y-direction of the word line switch WLSW is the word line switches WLSW (1), WLSW (1), WLSW (2), WLSW (2) in the order from the Y-direction positive side in a first column CL1 to a fourth column CL4. In a fifth column CL5 to an eighth column CL8, the order is the word line switches WLSW (2), WLSW (2), WLSW (3), WLSW (3) from the Y-direction positive side. In a ninth column CL9 to a twelfth column CL12, the order is the word line switches WLSW (1), WLSW (1), WLSW (3), WLSW (3) from the Y-direction positive side.

On the other hand, the 24 via-contact electrodes CC in total of 2 rows×12 columns are disposed for each memory block BLK, and among them, the 8 via-contact electrodes CC in total of 2 rows×4 columns are dummies. Therefore, the number of the active via-contact electrodes CC is 16 for each memory block BLK.

In the memory block BLK (1) (first row ro1, second row ro2), the via-contact electrodes CC are active in a first column cl1 to a fourth column cl4 and a ninth column c19 to a twelfth column cl12, and dummies in a fifth column c15 to an eighth column cl8.

In the memory block BLK (2) (third row ro3, fourth row ro4), the via-contact electrodes CC are active in the first column cl1 to the eighth column cl8, and dummies in the ninth column cl9 to the twelfth column cl12.

In the memory block BLK (3) (fifth row ro5, sixth row ro6), the via-contact electrode CC are active in the fifth column cl5 to the twelfth column cl12, and dummies in the first column cl1 to the fourth column cl4.

Thus, since the dummy via-contact electrodes CC are distributed in the X-direction and the Y-direction, the active via-contact electrodes CC are arranged by 12 in the X-direction and four in the Y-direction by shifting the via-contact electrodes CC excluding the dummies in the Y-direction. Accordingly, the numbers of the via-contact electrodes CC in the X and Y-directions match the numbers of the word line switches WLSW in the X and Y-directions.

The order in the Y-direction of the memory block BLK including the active via-contact electrode CC is the memory blocks BLK (1), BLK (1), BLK (2), BLK (2) from the Y-direction positive side in the first column cl1 to the fourth column cl4. In the fifth column cl5 to the eighth column cl8, the order is the memory blocks BLK (2), BLK (2), BLK (3), BLK (3) from the Y-direction positive side. In the ninth column cl9 to the twelfth column cl12, the order is the memory blocks BLK (1), BLK (1), BLK (3), BLK (3) from the Y-direction positive side.

Also in this embodiment, with the dummy via-contact electrodes CC disposed in the arrangement pattern of the via-contact electrode CC, the active via-contact electrodes CC match the word line switches WLSW in the positional relation. This allows aligning the positional relation between the via-contact electrodes CC and the bonding electrodes P_{I2}, and the positional relation between the connecting portions d32 connected to the hook-up wirings W2 to W0. Accordingly, the pattern of the wiring from the via-contact electrode CC or the bonding electrode P_{I2} to the connecting portion d32 passing through the connecting portion d42, and further the pattern of the hook-up wirings W2 to W0 from the connecting portions d32 to the word line switches WLSW can be simplified, and the wiring paths can be shortened.

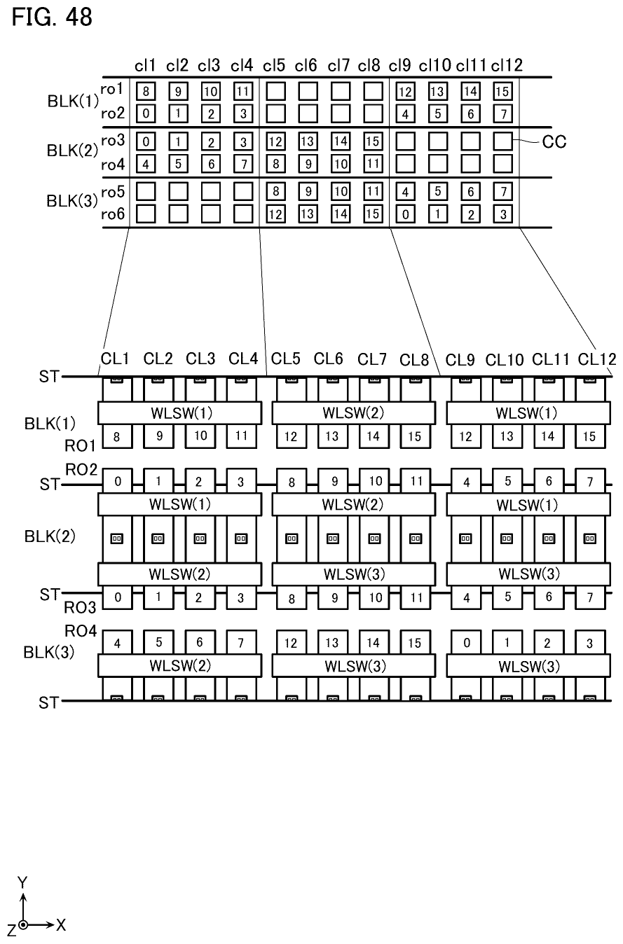

FIG. 48 is a schematic plan view illustrating an exemplary assignment of word line WL numbers to the via-contact electrodes CC and the word line switches WLSW. In the memory block BLK (1), in the first column cl1 to the twelfth column cl12 of the first row ro1, the word line numbers of 8, 9, 10, 11, dummy, dummy, dummy, dummy, 12, 13, 14, and 15 are assigned. In the first column cl1 to the twelfth column cl12 of the second row ro2, the word line numbers of 0, 1, 2, 3, dummy, dummy, dummy, dummy, 4, 5, 6, and 7 are assigned. For the memory blocks BLK (2) and BLK (3), the word line numbers are assigned as illustrated in FIG. 48.

The order in the Y-direction of the assignment pattern of the word line WL number to the via-contact electrode CC is same as the order in the Y-direction of the assignment pattern to the drain region of the word line switch WLSW. The word line numbers of the word line switches WLSW having the semiconductor region 203 in common are same. This facilitates the arrangement of the wiring CGI.

### Eleventh Embodiment

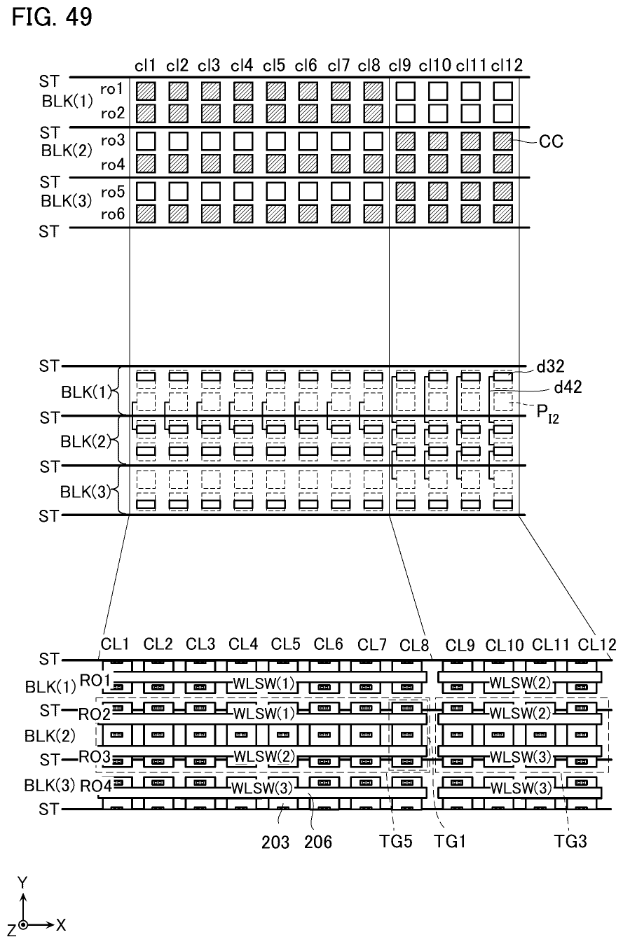

FIG. 49 is a schematic plan view illustrating an exemplary arrangement of via-contact electrodes CC and an exemplary arrangement of connecting portions dn2 and word line switches WLSW in a wiring layer corresponding thereto in a semiconductor memory device according to an eleventh embodiment. For the configurations similar to those of the first embodiment to the tenth embodiment, the same reference numerals are attached and the detailed explanation is omitted.

In the eleventh embodiment, a relation between the word line switch WLSW and the memory block BLK is a relation of 4Tr/3BLK (M=4, N=3). In the eleventh embodiment, the word line switch WLSW includes a transistor group TG5 including 8 transistor groups TG1 having a gate electrode 206 in common and arranged in the X-direction, and a transistor group TG3 including four transistor groups TG1 having a gate electrode 206 in common. In this example, the transistor groups TG5, TG3 are arranged in the X-direction.

The order in the Y-direction of the word line switch WLSW is the word line switches WLSW (1), WLSW (1), WLSW (2), WLSW (3) in the order from the Y-direction positive side in a first column CL1 to an eighth column CL8. In a ninth column CL9 to a twelfth column CL12, the order is the word line switches WLSW (2), WLSW (2), WLSW (3), WLSW (3) from the Y-direction positive side.

On the other hand, the 24 via-contact electrodes CC in total of 2 rows×12 columns are disposed for each memory block BLK, and among them, the 8 via-contact electrodes CC in total of 2 rows×4 columns or 8 via-contact electrodes CC in total of one row×eight columns are dummies. Therefore, the number of the active via-contact electrodes CC is 16 for each memory block BLK.

In the memory block BLK (1) (first row ro1, second row ro2), the via-contact electrodes CC are active in a first column cl1 to an eighth column cl8, and dummies in a ninth column cl9 to a twelfth column cl12.

In the third row ro3 of the memory block BLK (2), the via-contact electrodes CC are dummies in the first column cl1 to the eighth column cl8, and active in the ninth column cl9 to the twelfth column cl12. In the fourth row ro4 of the memory block BLK (2), the via-contact electrodes

CC are active in the first column cl1 to the twelfth column cl12.

The memory block BLK (3) is similar to the memory block BLK (2).

Thus, since the dummy via-contact electrodes CC are distributed in the X-direction and the Y-direction, the active via-contact electrodes CC are arranged by 12 in the X-direction and four in the Y-direction by shifting the via-contact electrodes CC excluding the dummies in the Y-direction. Accordingly, the numbers of the via-contact electrodes CC in the X and Y-directions match the numbers of the word line switches WLSW in the X and Y-directions.

The order in the Y-direction of the memory block BLK including the active via-contact electrode CC is the memory blocks BLK (1), BLK (1), BLK (2), BLK (3) from the Y-direction positive side in the first column cl1 to the eighth column cl8. In the ninth column cl9 to the twelfth column cl12, the order is the memory blocks BLK (2), BLK (2), BLK (3), BLK (3) from the Y-direction positive side.

Also in this embodiment, with the dummy via-contact electrodes CC disposed in the arrangement pattern of the via-contact electrode CC, the active via-contact electrodes CC match the word line switches WLSW in the positional relation. This allows aligning the positional relation between the via-contact electrodes CC and the bonding electrodes P_{I2}, and the positional relation between the connecting portions d32 connected to the hook-up wirings W2 to W0. Accordingly, the pattern of the wiring from the via-contact electrode CC or the bonding electrode P_{I2} to the connecting portion d32 passing through the connecting portion d42, and further the pattern of the hook-up wirings W2 to W0 from the connecting portions d32 to the word line switches WLSW can be simplified, and the wiring paths can be shortened.

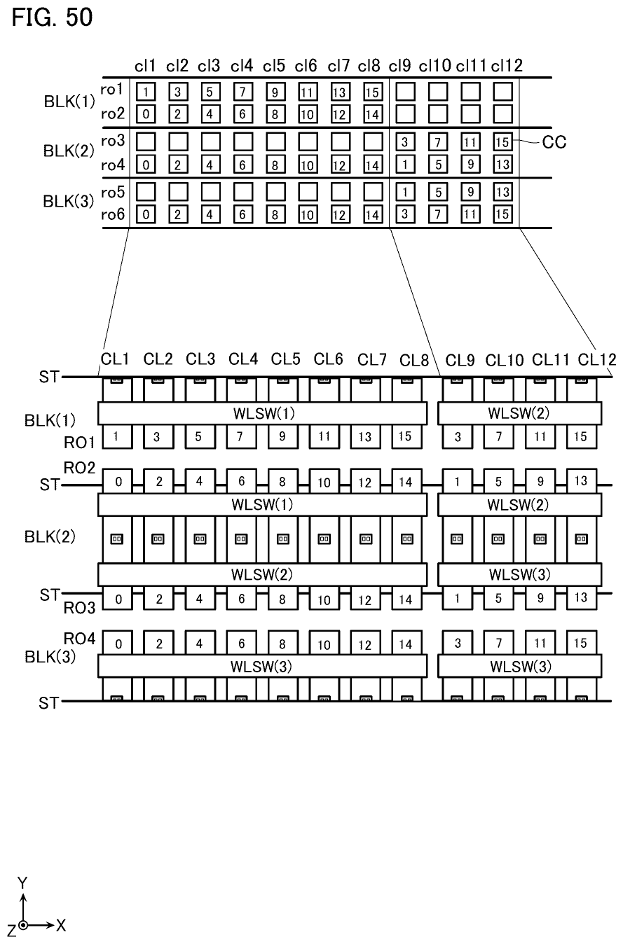

FIG. 50 is a schematic plan view illustrating an exemplary assignment of word line WL numbers to the via-contact electrodes CC and the word line switches WLSW. In the memory block BLK (1), in the first column cl1 to the twelfth column cl12 of the first row ro1, the word line numbers of 1, 3, 5, 7, 9, 11, 13, 15, dummy, dummy, dummy, dummy are assigned. In the first column cl1 to the twelfth column cl12 of the second row ro2, the word line numbers of 0, 2, 4, 6, 8, 10, 12, 14, dummy, dummy, dummy, dummy are assigned. For the memory blocks BLK (2) and BLK (3), the word line numbers are assigned as illustrated in FIG. 50.

The order in the Y-direction of the assignment pattern of the word line WL number to the via-contact electrode CC is same as the order in the Y-direction of the assignment pattern to the drain region of the word line switch WLSW. The word line numbers of the word line switches WLSW having the semiconductor region 203 in common are same. This facilitates the arrangement of the wiring CGI.

As described above, in the eighth embodiment to the eleventh embodiment, the configurations are as described below. That is, each of the plurality of memory blocks BLK (stacked structures) is assigned a number indicating a position in the Y-direction (the second direction). Each of the plurality of word line switches WLSW (transistors) is assigned the number of the memory blocks BLK to which the word line switches WLSW is connected. And each of the plurality of via-contact electrodes CC is assigned the number of the memory blocks BLK in which the via-contact electrode CC is included. In this case, the order in the Y-direction of the numbers assigned to the plurality of word line switches WLSW matches the order in the X-direction of the numbers assigned to the plurality of via-contact electrodes CC in the Y-direction at respective positions.

In other words, in arrangement pattern of the plurality of word line switches WLSW (transistors), an order in the Y-direction (the second direction) of the plurality of memory blocks BLK (stacked structures) connected to the plurality of word line switches WLSW and in an arrangement pattern of the plurality of via-contact electrodes CC, an order in the Y-direction of the plurality of memory blocks BLK including the plurality of via-contact electrodes CC connected to the plurality of word line switches WLSW match at respective positions in the X-direction.

### [Others]

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor memory device comprising:
a semiconductor substrate;
a plurality of transistors disposed on a surface on one side of the semiconductor substrate and arranged in a first direction and a second direction intersecting with the first direction;
a stacked body disposed at the one side in a third direction intersecting with the first direction and the second direction with respect to the semiconductor substrate and including a plurality of conductive layers arranged in the third direction; and
a plurality of wiring layers disposed between the semiconductor substrate and the stacked body and connecting the plurality of conductive layers to the plurality of transistors, wherein
the semiconductor memory device includes a first circuit region in which the plurality of transistors are arranged when viewed in the third direction and a hook-up region overlapping with the first circuit region when viewed in the third direction and being smaller than the first circuit region in width in the first direction,
the stacked body includes a first stacked structure and a second stacked structure arranged in the second direction, the first stacked structure includes a plurality of first conductive layers arranged in the third direction, and the second stacked structure includes a plurality of second conductive layers arranged in the third direction,
the plurality of transistors include a plurality of first transistors and a plurality of second transistors arranged in the first direction,
the plurality of wiring layers include a plurality of first wirings that connect the plurality of first conductive layers to the plurality of first transistors, and a plurality of second wirings that connect the plurality of second conductive layers to the plurality of second transistors, and
a first part of the plurality of first wirings extending in the first direction from the hook-up region to a region outside the hook-up region in the first circuit region and a second part of the plurality of second wirings extending in the first direction from the hook-up region to the region outside the hook-up region in the first circuit region are provided at positions different in the third direction.

2. The semiconductor memory device according to claim 1, wherein
the first part of the plurality of first wirings and the second part of the plurality of second wirings are provided in wiring regions overlapping in the third direction.

3. The semiconductor memory device according to claim 1, wherein
the stacked body includes:
a plurality of semiconductor layers extending in the third direction and opposed to the plurality of conductive layers; and
a plurality of via-contact electrodes having one ends connected to the plurality of conductive layers in the hook-up region and the other ends extending in the third direction toward the plurality of wiring layers.

4. The semiconductor memory device according to claim 1, wherein
each of the plurality of transistors includes a source region and a drain region arranged in the second direction,
the plurality of wiring layers include:
a plurality of first connecting portions, in the first circuit region, disposed in a first region corresponding to a plurality of source regions of the plurality of transistors, arranged in the first direction, and arranged in the third direction;
a plurality of second connecting portions, in the hook-up region, disposed in a second region adjacent to the first region in the second direction, arranged in the first direction at a pitch smaller than an arrangement pitch in the first direction of the plurality of transistors, and arranged in the third direction;
a plurality of third connecting portions, in the first circuit region, disposed in a third region corresponding to a plurality of drain regions of the plurality of transistors, arranged in the first direction, and arranged in the third direction;
a first via that connects a part of the plurality of first connecting portions arranged in the third direction and the source region of the transistor and extends in the third direction;
a second via that connects a part of the plurality of second connecting portions arranged in the third direction and extends in the third direction; and
a third via that connects a part of the plurality of third connecting portions arranged in the third direction and the drain region of the transistor and extends in the third direction.

5. The semiconductor memory device according to claim 4, wherein
the second connecting portions include a plurality of fourth connecting portions connected to the plurality of first conductive layers and a plurality of fifth connecting portions connected to the plurality of second conductive layers,
the first wirings connect the fourth connecting portions to the third connecting portions corresponding to a plurality of drain regions of the first transistors, and
the second wirings connect the fifth connecting portions to the third connecting portions corresponding to a plurality of drain regions of the second transistors.

6. The semiconductor memory device according to claim 1, wherein
the plurality of transistors further include:
a plurality of third transistors disposed in a second row adjacent in the second direction to a first row in which the first transistors and the second transistors are arranged in the first direction, the plurality of third transistors being arranged in the first direction; and
a plurality of fourth transistors disposed in a third row adjacent to the second row in the second direction at an opposite side of the first row, the plurality of fourth transistors having a semiconductor region in common with the third transistors and being arranged in the first direction,
the plurality of wiring layers further include:
a plurality of third wirings that connect the plurality of first conductive layers to the plurality of third transistors; and
a plurality of fourth wirings that connect the plurality of second conductive layers to the plurality of fourth transistors, and
a width in the second direction of a region in which the first transistors, the second transistors, the third transistors, and the fourth transistors are disposed is equal to a width in the second direction of a region in which the first stacked structure and the second stacked structure are disposed.

7. The semiconductor memory device according to claim 6, wherein
the second connecting portions include a plurality of sixth connecting portions connected to the plurality of first conductive layers and a plurality of seventh connecting portions connected to the plurality of second conductive layers, the sixth connecting portions are arranged in the first direction, and the seventh connecting portions are arranged in the first direction at positions different from the sixth connecting portions in the second direction,
the third wirings connect the sixth connecting portions to the third connecting portions corresponding to a plurality of drain regions of the third transistors, and
the fourth wirings connect the seventh connecting portions to the third connecting portions corresponding to a plurality of drain regions of the fourth transistors.

8. The semiconductor memory device according to claim 7, wherein
an order of numbers of positions in the third direction of the first conductive layers connected to the sixth connecting portions is equal to an order of numbers of positions in the third direction of the second conductive layers connected to the seventh connecting portions.

9. The semiconductor memory device according to claim 7, wherein
numbers of positions in the third direction of the first conductive layers connected to ones of pairs of the second connecting portions adjacent in the first direction are equal to numbers of positions in the third direction of the second conductive layers connected the others.

10. The semiconductor memory device according to claim 1, wherein
the stacked body further includes a third stacked structure arranged across the second stacked structure in the second direction from the first stacked structure, and the third stacked structure includes a plurality of third conductive layers arranged in the third direction,
the plurality of transistors further include:
a fifth transistor disposed in a first row in which the first transistor and the second transistor are arranged in the first direction, and arranged together with the first transistor and the second transistor in the first direction;
a plurality of sixth transistors disposed in a second row adjacent to the first row in the second direction and arranged in the first direction;
a plurality of seventh transistors disposed in a third row across the second row from the first row, the plurality of seventh transistors having a semiconductor region in common with the sixth transistors and being arranged in the first direction; and
a plurality of eighth transistors disposed in a fourth row across the third row from the second row and arranged in the first direction,
the plurality of wiring layers include:
a plurality of fifth wirings that connect the plurality of third conductive layers to the plurality of fifth transistors;
a plurality of sixth wirings that connect the plurality first conductive layers to the plurality of sixth transistors;
a plurality of seventh wirings that connect the plurality of second conductive layers to the plurality of seventh transistors; and
a plurality of eighth wirings that connect the plurality of third conductive layers to the plurality of eighth transistors,
a width in the second direction of a region in which the first transistors, the second transistors, the fifth transistors, the sixth transistors, the seventh transistors, and the eighth transistors are disposed is equal to a width in the second direction of a region in which the first stacked structure, the second stacked structure, and the third stacked structure are disposed, and
a third part of the plurality of fifth wirings extending in the first direction from the hook-up region toward the first circuit region is disposed at a position different from the first part of the first wiring and the second part of the second wiring in the third direction.

11. The semiconductor memory device according to claim 10, wherein
the first part of the plurality of first wirings, the second part of the plurality of second wirings, and the third part of the plurality of fifth wirings are disposed in wiring regions overlapping in the third direction.

12. The semiconductor memory device according to claim 1, wherein
each of the plurality of first transistors includes a first gate electrode,
each of the plurality of second transistors includes a second gate electrode,
the first gate electrode and the second gate electrode are arranged in the first direction, and
the plurality of wiring layers include:
a ninth wiring that mutually connects a plurality of the first gate electrodes arranged in the first direction; and
a tenth wiring that mutually connects a plurality of the second gate electrodes arranged in the first direction.

13. The semiconductor memory device according to claim 3, wherein
the stacked body includes a plurality of eleventh wirings that are connected to end portions at a wiring layer side of the semiconductor layers, extend in the second direction, and are arranged in the first direction, and
the plurality of eleventh wirings overlap with a part of the first circuit region when viewed in the third direction.

14. A semiconductor memory device comprising:
a semiconductor substrate;
a plurality of transistors disposed on a surface on one side of the semiconductor substrate and arranged in a first direction and a second direction intersecting with the first direction;
a stacked body disposed at the one side in a third direction intersecting with the first direction and the second direction of the semiconductor substrate and including a plurality of conductive layers arranged in the third direction; and
a plurality of wiring layers disposed between the semiconductor substrate and the stacked body and connecting the plurality of conductive layers to the plurality of transistors, wherein
the semiconductor memory device includes a first circuit region in which the plurality of transistors are arranged when viewed in the third direction and a hook-up region overlapping with the first circuit region when viewed in the third direction and being smaller than the first circuit region in width in the first direction,
the stacked body includes a first stacked structure and a second stacked structure arranged in the second direction, the first stacked structure includes a plurality of first conductive layers arranged in the third direction, and the second stacked structure includes a plurality of second conductive layers arranged in the third direction,
the plurality of transistors include a plurality of first transistors and a plurality of second transistors arranged in the first direction,
the plurality of wiring layers include:
a first wiring layer;
a second wiring layer different from the first wiring layer in position in the third direction;
a plurality of first wirings that connect the plurality of first conductive layers to the plurality of first transistors; and
a plurality of second wirings that connect the plurality of second conductive layers to the plurality of second transistors,
all of wirings passing through a boundary portion between the hook-up region and a region outside the hook-up region in the first circuit region in the first wiring layer are the first wirings, and
all of wirings passing through a boundary portion between the hook-up region and a region outside the hook-up region in the first circuit region in the second wiring layer are the second wirings.

15. A semiconductor memory device comprising:
a semiconductor substrate;
a plurality of transistors disposed on a surface on one side of the semiconductor substrate and arranged in a first direction and a second direction intersecting with the first direction;
a plurality of stacked structures disposed at the one side in a third direction intersecting with the first direction and the second direction of the semiconductor substrate, and each including a plurality of conductive layers arranged in the third direction; and
a wiring layer disposed between the semiconductor substrate and the plurality of stacked structures, and connecting the plurality of conductive layers to the plurality of transistors, wherein
the semiconductor memory device includes a first circuit region in which the plurality of transistors are arranged when viewed in the third direction and a hook-up region overlapping with the first circuit region when viewed in the third direction,
each of the plurality of stacked structures includes a plurality of via-contact electrodes having one ends connected to the plurality of conductive layers, the other ends extending in the third direction toward the wiring layer, and side surfaces opposed to one or more of the plurality of conductive layers via insulators in the hook-up region,
assuming that each of the plurality of stacked structures is assigned a number indicating a position in the second direction,
each of the plurality of transistors is assigned the number of the stacked structure to which the transistor is connected, and
each of the plurality of via-contact electrodes is assigned the number of the stacked structure in which the via-contact electrode is included,
an order in the second direction of the numbers assigned to the plurality of transistors matches an order in the second direction of the numbers assigned to the plurality of via-contact electrodes at respective positions in the first direction.

16. The semiconductor memory device according to claim 15, wherein
the plurality of stacked structures include a memory region at a position arranged in the first direction with respect to the hook-up region, and include a plurality of semiconductor layers extending in the third direction and opposed to the plurality of conductive layers in the memory region.

17. The semiconductor memory device according to claim 15, wherein
a total width in the second direction of the N (N is a natural number) stacked structures is equal to a total width in the second direction of the M (M>N, M is a natural number) transistors.

18. The semiconductor memory device according to claim 17, further comprising
a plurality of dummy via-contact electrodes not connected to the plurality of transistors in the hook-up region of each of the stacked structures, wherein
the plurality of via-contact electrodes and the plurality of dummy via-contact electrodes are arranged in the first direction and the second direction in the hook-up regions of the N stacked structures,
the dummy via-contact electrodes are provided in all of rows of the via-contact electrodes and the dummy via-contact electrodes arranged in the second direction of the N stacked structures,
a number of the plurality of via-contact electrodes in the second direction is M, and
respective numbers of the via-contact electrodes of the plurality of stacked structures are same.

19. The semiconductor memory device according to claim 15, wherein
the plurality of transistors include source regions and drain regions arranged in the second direction respectively, and
an order in the second direction of numbers of positions in the third direction of the conductive layers connected to the plurality of via-contact electrodes matches an order in the second direction of numbers of positions in the third direction of the conductive layers connected to the drain regions of the plurality of transistors at respective positions in the first direction.

20. The semiconductor memory device according to claim 19, wherein
a pair of transistors adjacent in the second direction have a semiconductor region in common, and
the number of the conductive layer connected to a drain of one transistor having the semiconductor region in common is equal to the number of the conductive layer connected to a drain of the other transistor having the semiconductor region in common.
